(19) United States
(12) Patent Application Publication
(10) Pub. No.: US 2015/0262703 A1
(43) Pub. Date: Sep. 17, 2015

(54) SHIFT REGISTER, DISPLAY DEVICE PROVIDED THEREWITH, AND SHIFT-REGISTER DRIVING METHOD

(71) Applicant: SHARP KABUSHIKI KAISHA, Osaka-shi, Osaka (JP)

(72) Inventors: Yuhichiroh Murakami, Osaka (JP); Yasushi Sasaki, Osaka (JP); Shuji Nishi, Osaka (JP)

(73) Assignee: Sharp Kabushiki Kaisha, Osaka (JP)

(21) Appl. No.: 14/432,577

(22) PCT Filed: Sep. 27, 2013
(86) PCT No.: PCT/JP2013/076214

§ 371 Date: Mar. 31, 2015

(30) Foreign Application Priority Data
Oct. 5, 2012 (JP) 2012-222907

(51) Int. Cl. G11C 19/28; G09G 3/36

(52) U.S. Cl. CPC G11C 19/28; G09G 3/3685; G09G 2310/0286; G09G 2310/0205; G09G 2310/0281

(57) ABSTRACT

Provided is a shift register capable of being driven using various clock signals, with low power consumption. A bistable circuit of a shift register is provided with first to third transistors, first to third input terminals, and an output terminal. In the first transistor, a gate terminal thereof and a first conduction terminal thereof are connected to the first input terminal. In the second transistor, a gate terminal thereof is connected to the third input terminal, and a first conduction terminal thereof is connected to the first input terminal. In the third transistor, a gate terminal thereof is connected respectively to second conduction terminals of the first and second transistors, a first conduction terminal thereof is connected to the second input terminal, and a second conduction terminal thereof is connected to the output terminal.

### TECHNICAL FIELD

The present invention relates to a shift register, and particularly relates to a shift register including a plurality of bistable circuits, a display device including the shift register, and a driving method for the shift register.

### BACKGROUND ART

A shift register is used in display devices and the like to drive a plurality of scanning lines provided in a display panel. The shift register is generally constituted of a plurality of bistable circuits that are cascade-connected to each other. FIG. 38 is a circuit diagram illustrating a configuration of a shift register 900 disclosed in Patent Document 1. The shift register 900 includes a plurality of bistable circuits SR. In the present specification, a bistable circuit SR in an ith stage is indicated by a reference numeral SRi (where i is a natural number). The bistable circuit SRi in the ith stage may also be called simply an “ith stage”. FIG. 38 illustrates first to fourth stages SR1 to SR4 for the sake of simplicity.

The bistable circuits have the same configuration in each stage. For example, the first stage SR1 includes first to third transistors T1 to T3 and a first capacitor C1. The first to third transistors are a set transistor, a reset transistor, and an output transistor, respectively. In the first transistor T1, a drain terminal and a gate terminal are connected to each other, or in other words, the transistor is diode-connected. In the second transistor T2, a drain terminal is connected to a source terminal of the first transistor T1 and a source terminal is grounded. In the third transistor T3, a gate terminal is connected to the source terminal of the first transistor and the drain terminal of the second transistor, and a source terminal is connected to a next stage SR2. One end of the first capacitor C1 is connected to the gate terminal of the third transistor, and another end is grounded. C100 indicates a capacity load connected to an output end of the bistable circuit SR1 in the first stage. G1 indicates a gate node (a first gate node) that is a connection point between the source terminal of the first transistor, the drain terminal of the second transistor, and the gate terminal of the third transistor. Q1 indicates an output node (a first output node) that is a connection point between the source terminal of the third transistor and the next stage SR2. Note that the first to third transistors T1 to T3, the first capacitor C1, the capacity load C100, the first gate node G1, and the first output node Q1 in the first stage SR1 respectively correspond to fourth to sixth transistors T4 to T6, a second capacitor C2, a capacity load C101, a second gate node G2, and a second output node Q2 in the second stage SR2, seventh to ninth transistors T7 to T9, a third capacitor C3, a capacity load C102, a third gate node G3, and a third output node Q3 in the third stage SR3, and tenth to twelfth transistors T10 to T12, a fourth capacitor C4, a capacity load C103, a fourth gate node G4, and a fourth output node Q4 in the fourth stage SR4. Conductivity types of the transistors in each bistable circuit SR are all n-channel types.

A start pulse signal SI is supplied to the drain terminal and the gate terminal of the first transistor T1. Of four-phase clock signals φ1 to φ4 that cyclically repeat an on level and an off level (these will be called “first to fourth clock signals” hereinafter in descriptions related to Patent Document 1), third and first clock signals φ3 and φ1 are supplied to the gate terminal of the second transistor T2 and the drain terminal of the third transistor T3, respectively. Because the conductivity types of the transistors in each bistable circuit SR are n-channel, the on level and off level are high level and low level, respectively. The fourth and second clock signals φ4 and φ2 are supplied to a gate terminal of the fifth transistor T5 and a drain terminal of the sixth transistor T6, respectively. The first and third clock signals φ1 and φ3 are supplied to a gate terminal of the eighth transistor T8 and a drain terminal of the ninth transistor T9, respectively. The second and fourth clock signals φ2 and φ4 are supplied to a gate terminal of the eleventh transistor and a drain terminal of the twelfth transistor T12, respectively. An output signal from a previous stage is supplied to each stage SR as a set signal (in FIG. 38, a signal supplied to the drain terminal and the gate terminal of the set transistor). The start pulse signal SI is supplied to the first stage SR1 as the set signal, however. The third, fourth, first, and second clock signals φ3, φ4, φ1, and φ2 are supplied to the first to fourth stages SR1 to SR4, respectively, as reset signals (in FIG. 38, signals supplied to the gate terminals of the reset transistors).

FIG. 39 is a timing chart (times t1 to t11) illustrating operations of the shift register 900 illustrated in FIG. 38. The phases of the four-phase first to fourth clock signals φ1 to φ4 are shifted every one horizontal period, and all are at high level for one horizontal period every four horizontal periods. The start pulse signal SI contains a pulse that rises to high level for a single horizontal period. In FIG. 39, a span between two times corresponds to a single horizontal period. Hereinafter, a period in which the output signal in each stage rises to high level will be called a “selection period”. A period in which a capacitance (including parasitic capacitance; the same applies hereinafter) connected to a gate terminal of an output transistor, or in other words, a period in which a gate potential of the output transistor changes toward high level, will be called a “set period”. A period in which the capacitance connected to the gate terminal of the output transistor is discharged after the selection period, or in other words, a period in which the gate potential of the output transistor changes toward low level, will be called a “reset period”. In the following, charging a capacitance connected to a terminal or a node may be referred to as “charging the terminal or node” for the sake of simplicity. Likewise, discharging a capacitance connected to a terminal or a node may be referred to as “discharging the terminal or node” for the sake of simplicity. Note that the set period and the selection period may overlap. Here, the descriptions will focus on the first stage SR1 for the sake of simplicity. Time t1 to t2, time t2 to t3, and time t4 to t5 are the set period, the selection period, and the reset period, respectively, for the first stage SR1.

In the set period (time t1 to t2), the start pulse signal SI rises to high level and the first transistor T1 turns on. Accordingly, the first gate node G1 is charged (precharged, here). As a result, a potential at the first gate node G1 changes from low level toward high level and the third transistor T3 turns on. However, in the set period, the first clock signal φ1 is at low level, and thus an output signal (a potential at the first output node Q1) is held at low level.

In the selection period (time t2 to t3), the start pulse signal SI falls to low level and the first transistor T1 turns off. At this time, the first gate node G1 is in a floating state. In addition, the first clock signal φ1 rises to high level, and thus the presence of a capacitance between the gate and channel of the third transistor T3 (called a “gate capacitance” hereinafter) results in the potential at the first gate node G1 being pushed up in response to a rise in a drain potential of the third transistor T3. In other words, a bootstrapping operation is performed at the first gate node G1. For this reason, the gate potential of the third transistor T3 becomes sufficiently high, which in turn makes it possible for the third transistor T3 to output a high-level output signal at low impedance.

The first clock signal φ1 falls to low level in a period from time t3 to t4. As such, the output signal changes to low level. Meanwhile, due to the presence of the aforementioned gate capacitance, the potential at the first gate node G1 drops in response to a drop in the drain potential of the third transistor T3.

In the reset period (time t4 to t5), the third clock signal φ3 rises to high level and the second transistor T2 turns on. As such, the first gate node G1 falls to low level (this is assumed here to correspond to a ground level). Note that after the reset period, the third clock signal φ3 falls to low level and the second transistor T2 turns off. In this manner, the shift register 900 illustrated in FIG. 38 sequentially transfers the start pulse signal SI. According to the shift register 900 illustrated in FIG. 38, of the four-phase first to fourth clock signals φ1 to φ4, two clock signals whose phases are shifted from each other by two horizontal periods are inputted into each stage SR, and thus the set transistor and reset transistor in each stage SR do not turn on at the same time.

### RELATED ART DOCUMENTS

### Patent Documents

Patent Document 1: Japanese Patent Application Laid-Open Publication No. 2002-8388

Patent Document 2: Japanese Patent Application Laid-Open Publication No. 2009-77415

### SUMMARY OF THE INVENTION

### Problems to be Solved by the Invention

Here, consider a case where the shift register 900 is, for example, driven by two-phase first and second clock signals φ1 and φ2, as indicated in FIG. 40. The second and first clock signals φ2 and φ1 are supplied to the gate terminal of the second transistor and the drain terminal of the third transistor T3, respectively. The first and second clock signals φ1 and φ2 are supplied to the gate terminal of the fifth transistor T5 and the drain terminal of the sixth transistor T6, respectively. The second and first clock signals φ2 and φ1 are supplied to the gate terminal of the eighth transistor T8 and the drain terminal of the ninth transistor T9, respectively. The first and second clock signals φ1 and φ2 are supplied to the gate terminal of the eleventh transistor T11 and the drain terminal of the twelfth transistor 12, respectively.

FIG. 41 is a timing chart (times t1 to t5) illustrating operations of the shift register 900 illustrated in FIG. 40. The phases of the two-phase first and second clock signals φ1 and φ2 are shifted every one horizontal period, and both rise to high level for one horizontal period every two horizontal periods. Time t1 to t2, time t2 to t3, and time t3 to t4 are the set period, the selection period, and the reset period, respectively, for the first stage SR1. Descriptions of operations in the selection period and the reset period will be omitted for the sake of simplicity.

In the set period (time t1 to t2), the start pulse signal SI rises to high level and the first transistor T1 turns on, and the second clock signal φ2 rises to high level and the second transistor T2 turns on. The first and second transistors T1 and T2 being on at the same time in this manner produces a feedthrough current in the first and second transistors T1 and T2. As such, the potential at the first gate node G1 does not rise to a level that turns the third transistor T3 on, which can result in malfunctions. Even if the potential at the first gate node G1 is enabled to rise to a sufficient level by increasing the driving performance of the first transistor T1 and reducing the driving performance of the second transistor T2, the feedthrough current will cause an increase in power consumption. The driving performance of the first transistor T1 can be increased by increasing a gate width and reducing a gate length, for example. Meanwhile, the driving performance of the second transistor T2 can be reduced by providing an internal resistance, or by reducing a gate width and increasing a gate length, for example.

Next, consider a case where the shift register 900 is, for example, driven by four-phase first to fourth clock signals φ1 to φ4 whose phases are shifted by one horizontal period each and that all rise to high level for two horizontal periods among the four horizontal periods, as indicated in FIG. 42 (time t1 to t11). The types of clock signals supplied to the gate terminals of the respective reset transistors and the drain terminals of the respective output transistors are the same as those shown in FIG. 39. The start pulse signal SI contains a pulse that rises to high level for two horizontal periods. Time t2 to t4, time t3 to t5, and time t5 to t6 are the set period, the selection period, and the reset period, respectively, for the first stage SR1. In this example, the set period and the selection period overlap for one horizontal period. Descriptions of operations in the selection period and the reset period will be omitted for the sake of simplicity.

In the former half of the set period (time t2 to t3), the start pulse signal SI rises to high level and the first transistor T1 turns on. At this time, the third clock signal φ3 is at high level, and thus the second transistor T2 is on. The first and second transistors T1 and T2 being on at the same time in this manner produces a feedthrough current in the first and second transistors T1 and T2. As a result, the same problem arises as when driving the shift register 900 with the two-phase first and second clock signals φ1 and φ2.

As described above, with the shift register 900 configured as disclosed in Patent Document 1, the clock signals for driving the shift register 900 are limited in order to avoid increased power consumption.

Accordingly, it is an object of the present invention to provide a shift register capable of being driven using various clock signals, with low power consumption, as well as a display device including the shift register and a driving method for the shift register.

### Means for Solving the Problems

A first aspect of the present invention is a shift register, including a plurality of bistable circuits cascade-connected to each other and constituted by transistors having the same conductivity type, the shift register sequentially changing levels of output signals from the plurality of bistable circuits in accordance with clock signals received from outside, the clock signals cyclically repeating an ON level and an OFF level and having a plurality of mutually differing phases,

wherein each of the bistable circuits includes:
an output terminal for outputting the output signal;
an output circuit, connected to the output terminal, that generates the output signal in accordance with a first clock signal that is one of the clock signals having a plurality of phases; and
a control circuit that changes a control potential for controlling the output circuit in accordance with a set signal that is an output signal from a previous-stage bistable circuit or in accordance with a second clock signal that is another of the clock signals having a plurality of mutually differing phases excluding the first clock signal,

wherein the control circuit includes:
a first control transistor that changes the control potential toward an ON level when the set signal is at an ON level; and
a second control transistor that changes the control potential toward a potential of the set signal when the second clock signal is at an ON level.

A second aspect of the present invention is the first aspect of the present invention, wherein the second clock signal rises to an ON level when the set signal is at an ON level.

A third aspect of the present invention is the first aspect of the present invention,

wherein the output circuit has an output transistor in which the first clock input signal is supplied to a first conduction terminal and a second conduction terminal is connected to the output terminal, and

wherein the control potential is a potential at a control terminal of the output transistor.

A fourth aspect of the present invention is the third aspect of the present invention, wherein the output circuit further includes a capacitance element provided between the control terminal of the output transistor and the output terminal.

A fifth aspect of the present invention is the third aspect of the present invention, wherein each of the bistable circuits further includes a connection circuit that electrically connects the control terminal of the output transistor and the output terminal to each other when the first clock signal is at an ON level.

A sixth aspect of the present invention is the first aspect of the present invention, wherein each of the bistable circuits further includes an initializing circuit for initializing a potential related to the output signal in accordance with an initializing signal that rises to an ON level at a prescribed timing.

A seventh aspect of the present invention is the first aspect of the present invention, wherein each of the bistable circuits further includes an output potential holding circuit that changes a potential at the output terminal toward an OFF level when the second clock signal is at an ON level.

An eighth aspect of the present invention is the first aspect of the present invention, wherein each of the bistable circuits further includes a breakdown voltage circuit, provided between the output circuit and the control circuit, that electrically disconnects the output circuit from the control circuit when the control potential reaches a prescribed value.

A ninth aspect of the present invention is the first aspect of the present invention,

wherein each of the bistable circuits further includes:
a first switching transistor that, when a first switching signal that rises to an ON level in a case that the levels of the output signals from the plurality of bistable circuits are sequentially driven in a first direction and that falls to an OFF level in a case that the levels of the output signals from the plurality of bistable circuits are sequentially driven in a second direction is at an ON level, supplies the output signal from the previous-stage bistable circuit in a case that the levels of the output signals from the plurality of bistable circuits are sequentially changed in the first direction to the first control transistor and the second control transistor as the set signal; and
a second switching transistor that, when a second switching signal having a potential inverted relative to the first switching signal is at an ON level, supplies the output signal from the previous-stage bistable circuit in a case that the levels of the output signals from the plurality of bistable circuits are sequentially driven in the second direction to the first control transistor and the second control transistor as the set signal.

A tenth aspect of the present invention is the ninth aspect of the present invention,

wherein each of the bistable circuits further includes:
a first switching control circuit that supplies an ON level potential to a control terminal of the first switching transistor via a first rectifier circuit when the first switching signal is at an ON level; and
a second switching control circuit that supplies an ON level potential to a control terminal of the second switching transistor via a second rectifier circuit when the second switching signal is at an ON level.

An eleventh aspect of the present invention is the first aspect of the present invention,

wherein the set signal has a first set signal that is the output signal from the previous-stage bistable circuit in a case that the levels of the output signals from the plurality of bistable circuits are sequentially driven in a first direction, and a second set signal that is the output signal from a previous-stage bistable circuit in a case that the levels of the output signals from the plurality of bistable circuits are sequentially driven in a second direction, wherein the second clock signal has a first second clock signal and a second second clock signal that are mutually differing clock signals,

wherein the first control transistor has at least one of a first first control transistor that changes the control potential toward an ON level when the first set signal is at an ON level and a second first control transistor that changes the control potential toward an ON level when the second set signal is at an ON level, and

wherein the second control transistor includes: a first second control transistor that changes the control potential toward a potential of the first set signal when the first second clock signal is at an ON level; and a second second control transistor that changes the control potential toward a potential of the second set signal when the second second clock signal is at an ON level.

A twelfth aspect of the present invention is the first aspect of the present invention, wherein the clock signals having a plurality of phases are clock signals having four phases that are different from one another.

A thirteenth aspect of the present invention is the first aspect of the present invention, wherein a duty ratio of each of the clock signals having a plurality of phases is less than an inverse of a number of clock signals received by each bistable circuit.

A fourteenth aspect of the present invention is a display device, including:

a display unit including a plurality of data lines, a plurality of scanning lines, and a plurality of pixel forming units provided so as to correspond with the plurality of data lines and the plurality of scanning lines;

a data line driving circuit that drives the plurality of data lines; and

the shift register according to any one of claims 1 to 13, the output terminals of the plurality of bistable circuits being respectively connected to the plurality of scanning lines.

A fifteenth aspect of the present invention is a display device having a display unit including a plurality of data lines, a plurality of scanning lines, and a plurality of pixel forming units provided so as to correspond with the plurality of data lines and the plurality of scanning lines, and a data line driving circuit that drives the plurality of data lines, the display device including:
two of the shift registers according to any one of claims 1 to 13,

wherein one of the two shift registers is provided at one end of the display unit, the output terminals of the plurality of bistable circuits in the shift register being respectively connected to odd-numbered scanning lines of the plurality of scanning lines, and

wherein another of the two shift registers is provided at another end of the display unit, the output terminals of the plurality of bistable circuits in the shift register being respectively connected to even-numbered scanning lines of the plurality of scanning lines.

A method of driving a shift register that has a plurality of bistable circuits cascade-connected to each other and constituted by transistors having the same conductivity type, the shift register sequentially changing levels of output signals from the plurality of bistable circuits in accordance with clock signals received from outside, the clock signals cyclically repeating an ON level and an OFF level and having a plurality of mutually differing phases, the method including:

generating and outputting the output signal in accordance with a first clock signal that is one of the clock signals having a plurality of phases; and

changing a control potential for controlling the output circuit in accordance with a set signal that is an output signal from a previous-stage bistable circuit or a second clock signal that is another of the clock signals having a plurality of phases excluding the first clock signal,

wherein the step of changing the control potential includes:
changing the control potential toward an ON level when the set signal is at an ON level; and
changing the control potential toward a potential of the set signal when the second clock signal is at an ON level.

### Effects of the Invention

In the following descriptions of the effects of the invention, it is assumed that the on level and the off level are a high level and a low level, respectively. In the case where the on level and the off level are the low level and the high level, respectively, it should be noted that descriptions regarding the levels of potentials are reversed in the following descriptions of the effects of the invention.

According to the first aspect of the present invention, the second control transistor changes the control potential toward the potential of the set signal when the second clock signal is at the on level. Accordingly, even if the first and second control transistors turn on at the same time, potentials at a conduction terminal of the first control transistor on the side opposite from the output circuit and a conduction terminal of the second control transistor on the side opposite from the output circuit are both at the on level at this time. As a result, no feedthrough current arises in the first and second control transistors. Accordingly, it is possible to realize driving using various clock signals, with low power consumption. In addition, the second control transistor periodically changes the control potential toward the potential of the set signal in response to the second clock signal, and thus malfunctions caused by fluctuations in the control potential can be prevented.

According to a second aspect of the present invention, the first and second control transistors turn on at the same time, and thus the control potential is changed toward the on level at the same time by the first and second control transistors. Accordingly, the change of the control potential to the on level can be accelerated.

According to the third aspect of the present invention, the output signal can be generated using the output transistor.

According to the fourth aspect of the present invention, a capacitance element is provided, and thus when a potential at a conduction terminal of the output transistor on the output terminal side changes to the on level, a potential at the control terminal of the output transistor is pushed up in response to the rise in the potential at the stated conduction terminal. Accordingly, a bootstrapping operation is performed not only using a capacitance provided in the output transistor, but also using the capacitance element. Through this, the rise in potential produced by the bootstrapping operation can be increased. Accordingly, the potential at the control terminal of the output transistor becomes sufficiently high, and thus the output transistor can output the output signal at low impedance.

According to the fifth aspect of the present invention, the control terminal of the output transistor and the output terminal are electrically connected to each other by the connection circuit when the first clock signal is at the on level. Generally, a large capacity load is connected to the output terminal, and thus electrically connecting the control terminal of the output transistor to the output terminal reduces the influence of fluctuations in the potential of the first clock signal that are transmitted to the control terminal of the output transistor due to parasitic capacitance present between the first conduction terminal and the control terminal of the output transistor. Accordingly, malfunctions caused by fluctuations in the control potential can be prevented.

According to the sixth aspect of the present invention, a potential related to an output potential (the control potential or the potential at the output terminal, for example) can be initialized in response to the initializing signal.

According to the seventh aspect of the present invention, the potential at the output terminal periodically changes toward the off level in response to the second clock signal, and thus the potential at the output terminal is stabilized. Accordingly, a drop in an operating margin, malfunctions, and so on can be prevented.

According to the eighth aspect of the present invention, the output circuit and the control circuit are electrically disconnected by the breakdown voltage circuit when the control potential reaches the required value. Accordingly, when the first clock signal changes from the off level to the on level, a potential at a terminal of the control circuit on the output circuit side will not rise even if the control potential rises (the bootstrapping operation) due to the presence of the capacitance present in the output transistor. Through this, a voltage applied between the terminals of the first control transistor and between the terminals of the second control transistor when the respective potentials at the control terminal and the conduction terminal of the first control transistor on the side opposite from the output circuit and the respective potentials at the control terminal and the conduction terminal of the second control transistor on the side opposite from the output circuit are at the off level is reduced. Accordingly, the reliability of the first and second control transistors can be improved.

According to the ninth aspect of the present invention, the output signal of the previous-stage bistable circuit in the case where the levels of the output signals from the plurality of bistable circuits are sequentially changed in the first direction is supplied to the first and second control transistors as the set signal when the first switching signal is at the on level, and the output signal of the previous-stage bistable circuit in the case where the levels of the output signals from the plurality of bistable circuits are sequentially changed in the second direction is supplied to the first and second control transistors as the set signal when the second switching signal is at the on level. Accordingly, the direction in which the levels of the output signals are sequentially changed (called a “shift direction” hereinafter in the descriptions of the effects of the invention) can be switched between the first direction and the second direction.

According to the tenth aspect of the present invention, the control terminal of the first switching transistor is in a floating state when the first switching signal is at the on level. At this time, when the set signal changes from the off level to the on level, a potential at the control terminal of the first switching transistor is pushed up due to the presence of a gate capacitance in the first switching transistor. In other words, a bootstrapping operation is performed at the control terminal of the first switching transistor. Accordingly, a drop in the potential of the set signal equivalent to a threshold voltage of the first switching transistor can be prevented, and the set signal can be supplied to the first and second control transistors. Likewise, the control terminal of the second switching transistor is in a floating state when the second switching signal is at the on level. At this time, when the set signal changes from the off level to the on level, a potential at the control terminal of the second switching transistor is pushed up due to the presence of a gate capacitance in the second switching transistor. In other words, a bootstrapping operation is performed at the control terminal of the second switching transistor. Accordingly, a drop in the potential of the set signal equivalent to a threshold voltage of the second switching transistor can be prevented, and the set signal can be supplied to the first and second control transistors.

According to the eleventh aspect of the present invention, the control potential is controlled by at least one of the first control transistor that changes the control potential toward the on level when the first set signal is at the on level and the second control transistor that changes the control potential toward the potential of the first set signal when the first second clock signal is at the on level. Meanwhile, the control potential is controlled by a second control circuit using the first control transistor that changes the control potential toward the on level when the second set signal is at the on level and the second control transistor that changes the control potential toward the potential of the second set signal when the second second clock signal is at the on level. In such a configuration, by varying fluctuations in the potential of the clock signals applied to the respective bistable circuits between when the shift direction is the first direction and when the shift direction is the second direction, the shift direction can be switched between the first direction and the second direction without using a switching signal for switching the shift direction (the first and second switching signals according to the ninth aspect of the present invention, for example).

According to the twelfth aspect of the present invention, the same effects as in the first aspect of the present invention can be achieved using four-phase clock signals. Furthermore, by setting a frequency of the four-phase clock signals to half a frequency occurring in the case where two-phase clock signals are used, a sufficient period in which the first control transistor changes the control potential to the on level is ensured. Accordingly, the size of the first control transistor can be reduced. Furthermore, a sufficient period in which the output transistor changes the potential at the output terminal toward the on level, or in other words, a sufficient period in which a capacitance load connected to the output terminal is charged, is ensured as well, and thus the size of the output transistor can be reduced as well. In this manner, the circuit scale of the shift register can be reduced.

According to the thirteenth aspect of the present invention, the duty cycle of each of the clock signals having a plurality of phases is less than an inverse of the number of clock signals received by each bistable circuit. Accordingly, malfunctions that can occur in the case where the clock signals, of the clock signals having a plurality of phases, that are received by the respective bistable circuits rise to the on level at the same time due to rounding or the like can be prevented.

According to the fourteenth aspect of the present invention, a display device that drives a plurality of scanning lines using the shift register according to any one of the first aspect to the thirteenth aspect of the present invention can be realized.

According to the fifteenth aspect of the present invention, in a display device that uses two of the shift register according to any one of the first aspect to the thirteenth aspect of the present invention, the two shift registers are provided on one end and another end of the display unit and connect the scanning lines in an alternating manner, and thus the circuit scale of the shift register can be reduced on each side of the display unit.

According to the sixteenth aspect of the present invention, the same effects as in the first aspect of the present invention can be achieved in a driving method of a shift register.

### BRIEF DESCRIPTION OF THE DRAWINGS

FIG. 1 is a block diagram illustrating a configuration of a shift register according to Embodiment 1 of the present invention.

FIG. 2 is a circuit diagram illustrating a configuration of a bistable circuit illustrated in FIG. 1.

FIG. 3 is a timing chart illustrating operations of the shift register illustrated in FIG. 1.

FIG. 4 is a circuit diagram illustrating a configuration of a bistable circuit according to Modification Example 1 of Embodiment 1.

FIG. 5 is a timing chart illustrating operations of a shift register according to Modification Example 2 of Embodiment 1.

FIG. 6 is a circuit diagram illustrating a configuration of a bistable circuit according to Modification Example 3 of Embodiment 1.

FIG. 7 is a circuit diagram illustrating a configuration of a bistable circuit according to Modification Example 4 of Embodiment 1.

FIG. 8 is a circuit diagram illustrating a configuration of a bistable circuit according to Modification Example 5 of Embodiment 1.

FIG. 9 is a timing chart illustrating a potential change at a first node in a bistable circuit illustrated in FIG. 2.

FIG. 10 is a circuit diagram illustrating a configuration of a bistable circuit according to Modification Example 6 of Embodiment 1.

FIG. 11 is a timing chart illustrating a potential change at a first node in a bistable circuit illustrated in FIG. 10.

FIG. 12 is a circuit diagram illustrating a configuration of a bistable circuit according to Modification Example 7 of Embodiment 1.

FIG. 13 is a block diagram illustrating a configuration of a shift register according to Modification Example 8 of Embodiment 1.

FIG. 14 is a timing chart illustrating operations of the shift register illustrated in FIG. 13.

FIG. 15 is a timing chart illustrating operations of a shift register according to a Modification Example 9 of Embodiment 1.

FIG. 16 is a block diagram illustrating a configuration of a shift register according to Modification Example 10 of Embodiment 1.

FIG. 17 is a circuit diagram illustrating a configuration of a bistable circuit illustrated in FIG. 16.

FIG. 18 is a timing chart illustrating operations of the shift register illustrated in FIG. 16 during forward shifting.

FIG. 19 is a timing chart illustrating operations of the shift register illustrated in FIG. 16 during reverse shifting.

FIG. 20 is a circuit diagram illustrating a configuration of a bistable circuit according to Modification Example 11 of Embodiment 1.

FIG. 21 is a circuit diagram illustrating a configuration of a bistable circuit according to Modification Example 12 of Embodiment 1.

FIG. 22 is a circuit diagram illustrating a configuration of a bistable circuit according to Modification Example 13 of Embodiment 1.

FIG. 23 is a circuit diagram illustrating a configuration of a bistable circuit according to Modification Example 14 of Embodiment 1.

FIG. 24 is a circuit diagram illustrating a configuration of a bistable circuit according to Modification Example 15 of Embodiment 1.

FIG. 25 is a timing chart illustrating operations of the shift register according to Modification Example 15 of Embodiment 1.

FIG. 26 is a block diagram illustrating a configuration of a shift register according to Modification Example 16 of Embodiment 1.

FIG. 27 is a circuit diagram illustrating a configuration of a bistable circuit illustrated in FIG. 26.

FIG. 28 is a timing chart illustrating operations of the shift register illustrated in FIG. 26 during forward shifting.

FIG. 29 is a timing chart illustrating operations of the shift register illustrated in FIG. 26 during reverse shifting.

FIG. 30 is a block diagram illustrating a configuration of a shift register according to Modification Example 17 of Embodiment 1.

FIG. 31 is a timing chart illustrating operations of the shift register illustrated in FIG. 30 during forward shifting.

FIG. 32 is a timing chart illustrating operations of the shift register illustrated in FIG. 30 during reverse shifting.

FIG. 33 is a circuit diagram illustrating a configuration of a first stage illustrated in FIG. 30.

FIG. 34 is a circuit diagram illustrating a configuration of an nth stage illustrated in FIG. 30.

FIG. 35 is a block diagram illustrating a configuration of a display device according to Embodiment 2 of the present invention.

FIG. 36 is a block diagram illustrating a configuration of a display device according to a variation of Embodiment 2.

FIG. 37 is a timing chart illustrating operations of first and second shift registers illustrated in FIG. 36.

FIG. 38 is a circuit diagram illustrating a configuration of a shift register disclosed in Patent Document 1.

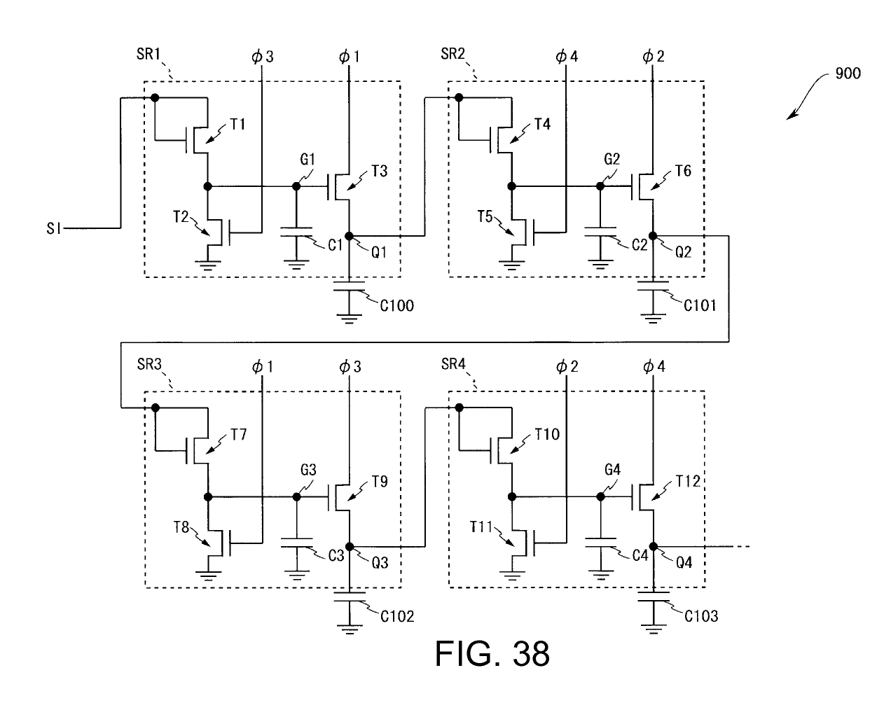

FIG. 39 is a timing chart illustrating operations of the shift register illustrated in FIG. 38.

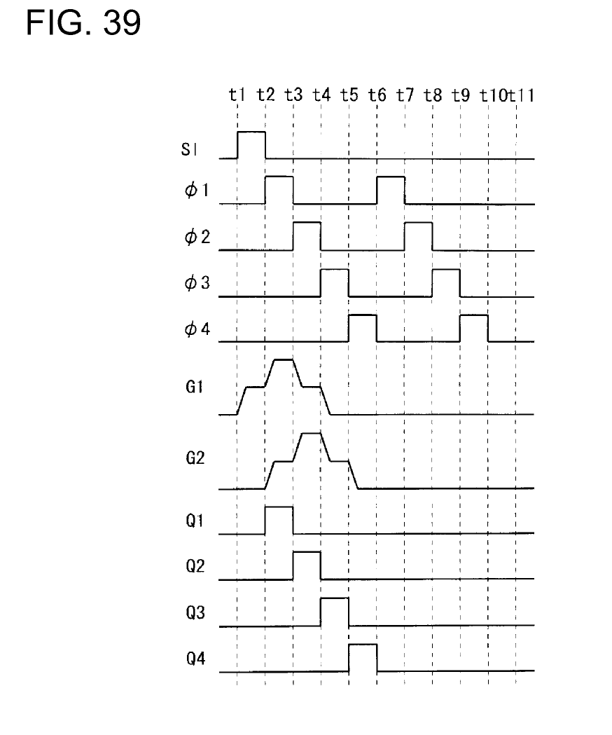

FIG. 40 is a circuit diagram illustrating a case where the shift register disclosed in Patent Document 1 is driven by two-phase clock signals.

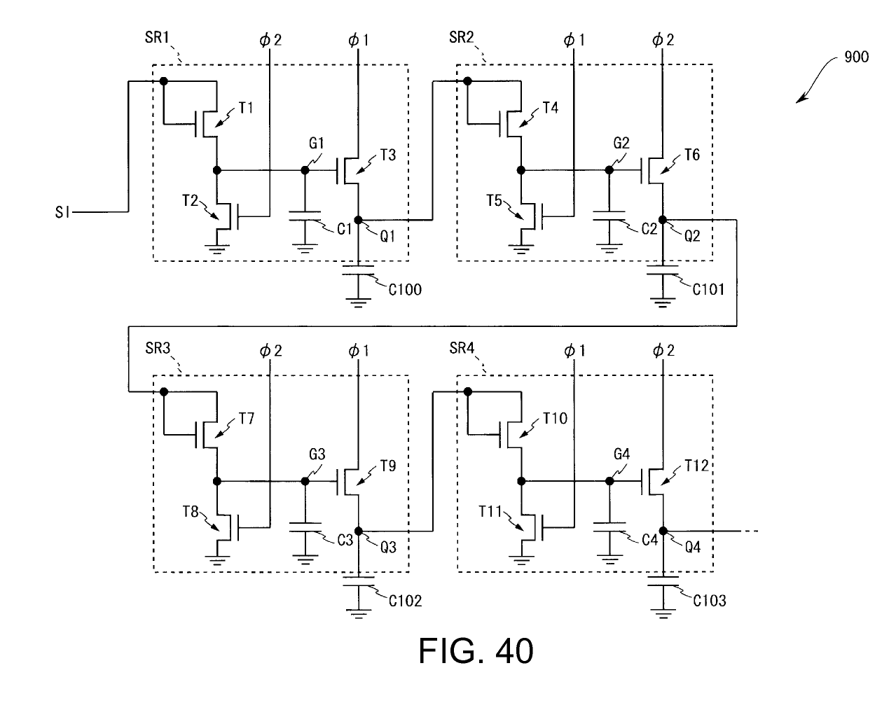

FIG. 41 is a timing chart illustrating operations of the shift register illustrated in FIG. 40.

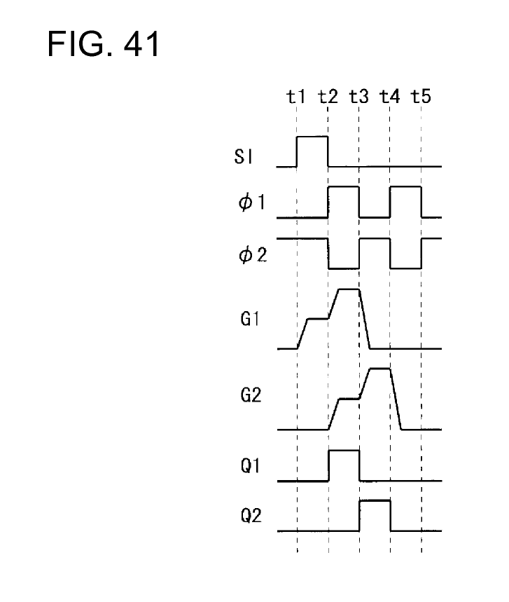

FIG. 42 is a timing chart illustrating other operations of the shift register disclosed in Patent Document 1.

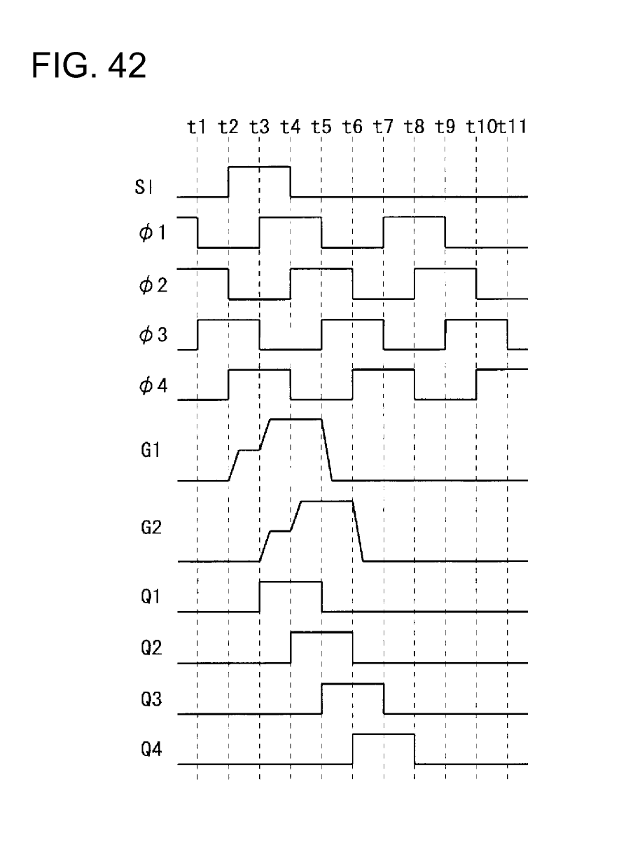

### DETAILED DESCRIPTION OF EMBODIMENTS

Embodiment 1 and 2 of the present invention will be described hereinafter with reference to the appended drawings. The transistors in each embodiment are field effect transistors, and are thin-film transistors, for example. Depending on the levels of potentials thereof, first and second conduction terminals in each transistor may function as a drain terminal and a source terminal, respectively, or may function as a source terminal and a drain terminal, respectively. For the sake of simplicity, it is assumed that a threshold voltage has the same value in each transistor. Furthermore, a bistable circuit SR in Embodiment 1 and variations thereon is constituted of transistors having the same conductivity type. To be more specific, each transistor in the bistable circuit SR is an n-channel type in Embodiment 1 and the variations thereon aside from Modification Example 15, and each transistor in the bistable circuit SR is a p-channel type in Modification Example 15 of Embodiment 1.

In each embodiment, a clock signal supplied to the shift register as a whole is called a “supply clock signal”, whereas a clock signal received by a bistable circuit is called an “input clock signal”. “Duty cycle” in the present specification refers to a percentage of a single clock signal cycle occupied by a period in which an on level is held. Furthermore, in the present specification, “constituent element A being connected to constituent element B” includes a case where constituent element A is physically connected directly to constituent element B as well as a case where constituent element A is connected to constituent element B via another constituent element. Here, “constituent element” refers to a circuit, an element, a terminal, a node, wiring, an electrode, or the like, for example. In addition, m and n are assumed to be integers of 2 or more in the following.

### 1. Embodiment 1

### 1.1 Overall Configuration

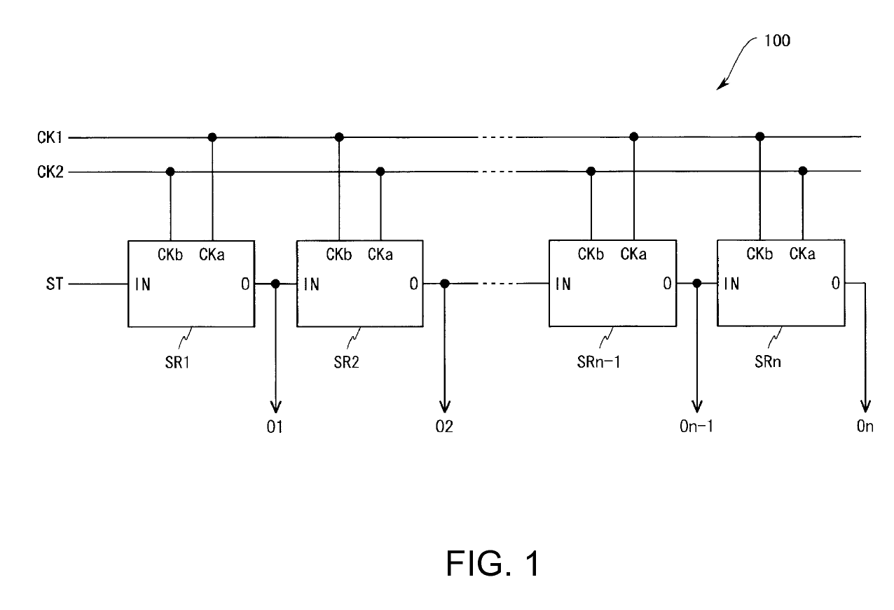

FIG. 1 is a block diagram illustrating a configuration of a shift register 100 according to the present embodiment. The shift register 100 includes n (stages) of bistable circuits SR1 to SRn that are cascade-connected to each other. Each stage has the same configuration (except in Modification Example 17, which will be described later). Note that the shift register 100 may include a dummy stage in a stage before the first stage SR1 and/or in a stage after the nth stage SRn. Based on first and second supply clock signals CK1 and CK2 received from the exterior and having a plurality of phases (two phases, in the present embodiment), the shift register 100 sequentially changes levels of output signals O1 to On from the bistable circuits SR1 to SRn, and specifically, sequentially sets levels of the output signals O1 to On from the bistable circuits SR1 to SRn to high level. High level corresponds to an on level, except in Modification Example 15 on the present embodiment. The phrase “output signal O” will be used when no distinction is to be made between the first to nth stage output signals O1 to On. In the present embodiment, a direction in which the shift register 100 sequentially sets the output signals O1 to On from the first stage SR1 to the nth stage SRn to high level (called a “shift direction” hereinafter) is a forward direction (ascending order). The first and second supply clock signals CK1 and CK2 cyclically repeat the high level and a low level. Low level corresponds to an off level, except in Modification Example 15 on the present embodiment. The phases of the first and second supply clock signals CK1 and CK2 are shifted every one horizontal period, and both rise to high level for one horizontal period every two horizontal periods. As such, a duty cycle of each of the first and second supply clock signals CK1 and CK2 is an inverse of the number of input clock signals received by each bistable circuit SR, or in other words, is ½.

The first stage SR1 takes a start pulse signal ST supplied from the exterior as a set signal IN, and the second stage SR2 to the nth stage SRn each takes the output signal O from the previous stage as the set signal IN. Odd-numbered stages take the first and second supply clock signals CK1 and CK2 as first and second input clock signals CKa and CKb, respectively. Even-numbered stages take the first and second supply clock signals CK1 and CK2 as the second and first input clock signals CKb and CKa, respectively. In the present embodiment, the first and second input clock signals CKa and CKb correspond to first and second clock signals, respectively.

### 1.2 Bistable Circuit

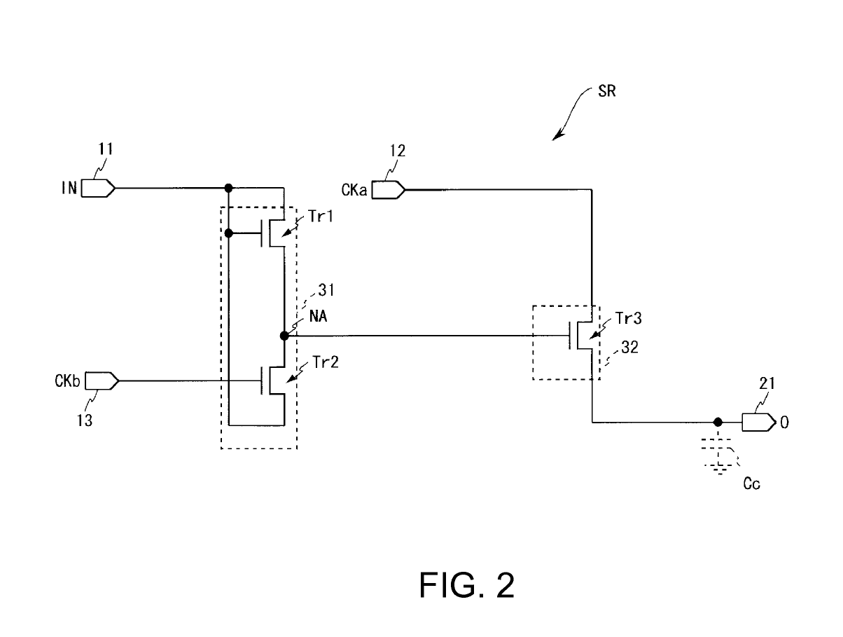

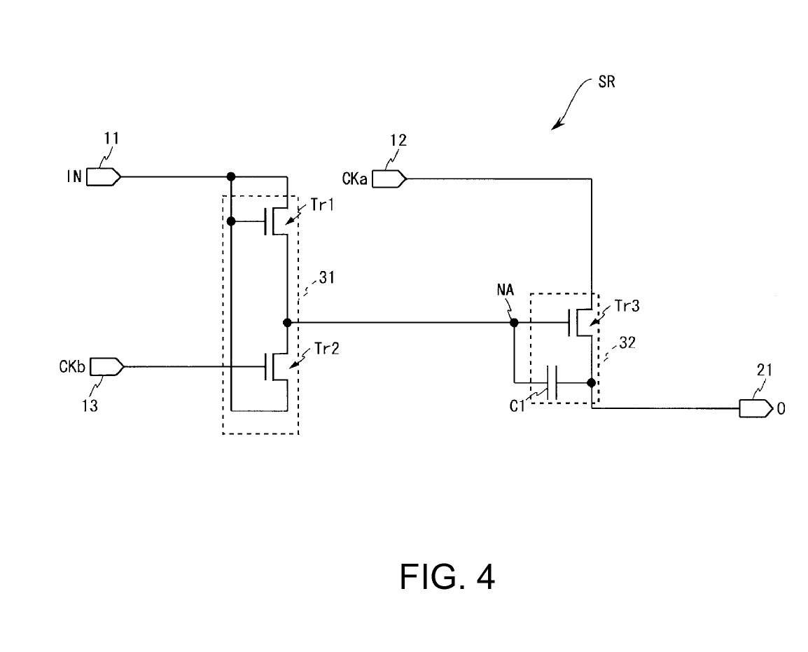

FIG. 2 is a circuit diagram illustrating a configuration of the bistable circuit SR illustrated in FIG. 1. The bistable circuit SR includes a control circuit 31, an output circuit 32, first to third input terminals 11 to 13, and an output terminal 21. The first to third input terminals 11 to 13 correspond to a set input terminal, a first clock input terminal, and a second clock input terminal, respectively. The first input terminal 11 is a terminal for taking the output signal O from the previous stage (the start pulse signal ST, in the case of the first stage SR1) as the set signal IN. The second input terminal 12 is a terminal for taking one of the two-phase first and second supply clock signals CK1 and CK2 as the first input clock signal CKa. The third input terminal 13 is a terminal for taking the one of the two-phase first and second supply clock signals CK1 and CK2 that is not the first input clock signal CKa as the second input clock signal CKb. The output terminal 21 is a terminal for outputting the output signal O. It is assumed that a capacity load Cc, for example a scanning line in a display device, is connected to the output terminal 21, as illustrated in FIG. 2. However, for the sake of simplicity, the capacity load Cc is not shown in the circuit diagrams of the bistable circuit SR aside from in FIG. 4 (described later).

In response to the set signal IN or the second input clock signal CKb, the control circuit 31 changes a potential at a first node NA (described later) for controlling the output circuit 32. Specifically, the control circuit 31 includes first and second transistors Tr1 and Tr2. The first and second transistors Tr1 and Tr2 correspond to first and second control transistors, respectively. In the first transistor Tr1, a gate terminal (corresponding to a control terminal; the same applies to other transistors as well) and a first conduction terminal are connected to the first input terminal 11. As such, the first transistor Tr1 has a diode connection. Accordingly, when the set signal IN is at high level, a high level potential (set signal IN) is applied to the first conduction terminal of the first transistor Tr1. In the second transistor Tr2, a gate terminal is connected to the third input terminal 13, and a first conduction terminal is connected to the first input terminal 11.

The output circuit 32 is connected to the output terminal 21 and generates the output signal O based on the first input clock signal CKa. Specifically, the output circuit 32 includes a third transistor Tr3. The third transistor Tr3 corresponds to an output transistor. In the third transistor Tr3, a first conduction terminal is connected to the second input terminal 12, and a second conduction terminal is connected to the output terminal 21. As such, the first input clock signal CKa is supplied to the first conduction terminal of the third transistor Tr3. Meanwhile, a gate terminal of the third transistor Tr3 is connected to the second conduction terminals of the first and second transistors Tr1 and Tr2, respectively. In the present specification, a connection point between the gate terminal of the third transistor Tr3 and other terminals is called the “first node NA”. In the present embodiment, the connection point between the gate terminal of the third transistor Tr3 and the second conduction terminals of the first and second transistors Tr1 and Tr2, respectively, is the first node NA.

The first transistor Tr1 changes the potential at the first node NA toward high level when the set signal IN is at high level. The first transistor Tr1 functions as a set transistor. The second transistor Tr2 changes the potential at the first node NA toward a potential of the set signal IN when the second clock signal CKb is at high level. The second transistor Tr2 functions as a reset transistor and also functions as a set transistor. The third transistor Tr3 changes the potential at the output terminal 21 (the output signal O) toward a potential of the first clock signal CKa when the potential at the first node NA is at high level.

### 1.3 Operations

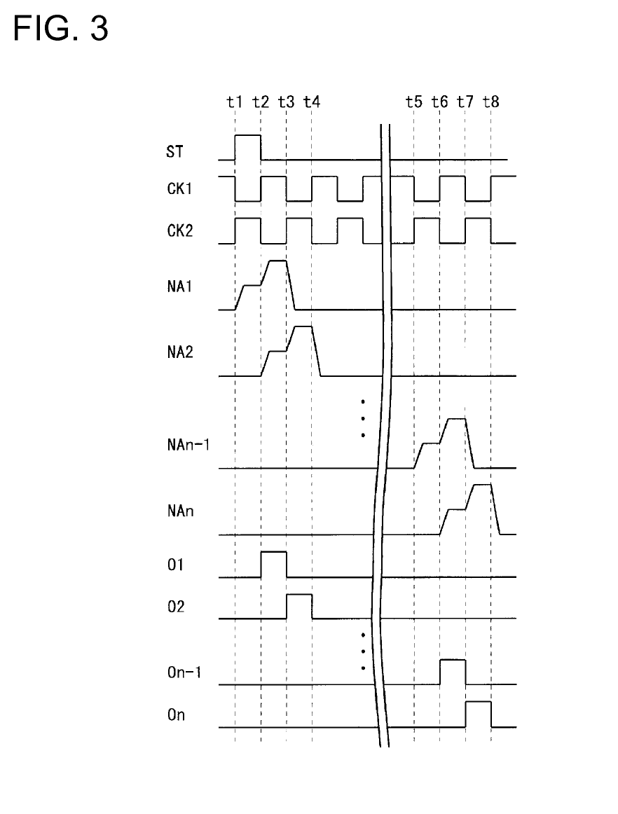

FIG. 3 is a timing chart (times t1 to t8) illustrating operations of the shift register 100 illustrated in FIG. 1. The start pulse signal ST contains a pulse that rises to high level for a single horizontal period. In the present embodiment and in variations described later, the operations of the shift register 100 will be described with a focus on the first stage SR1 for the sake of simplicity. Time t1 to t2, time t2 to t3, and time t3 to t4 are a set period, a selection period, and a reset period, respectively, for the first stage SR1. Note that in the timing charts from FIG. 3 on, the potentials at the first node NA in the first to nth stages SR1 to SRn are indicated by NA1 to NAn, respectively.

In the set period (time t1 to t2), the set signal IN (the start pulse signal ST, in the case of the first stage SR1) rises to high level and the first transistor Tr1 turns on, and the second input clock signal CKb (the second supply clock signal CK2, in the case of the first stage SR1) rises to high level and the second transistor Tr2 turns on. At this time, the high-level set signal IN is supplied to the respective first conduction terminals in the first and second transistors Tr1 and Tr2, and thus the first node NA is charged (precharged, here) by both the first and second transistors Tr1 and Tr2. Note that in actuality, a parasitic capacitance formed between the first node NA and the first conduction terminal of the third transistor Tr3, for example, is connected to the first node NA, and that parasitic capacitance is precharged. As a result, the potential at the first node NA changes from low level toward high level and the third transistor Tr3 turns on. In the set period, the second transistor Tr2 functions as a set transistor. Here, when high level is expressed as Vdd and a threshold voltage of each transistor expressed as Vth, the potential at the first node NA is Vdd−Vth in the set period. In the set period, the first clock signal CKa (the first supply clock signal CK1, in the case of the first stage SR1) is at low level, and thus the output signal O (the potential at the output terminal 21) is held at low level.

Incidentally, in the set period, the first and second transistors Tr1 and Tr2 are on at the same time, and the same set signal IN is supplied to the first conduction terminal of the first transistor Tr1 and the first conduction terminal of the second transistor Tr2. In other words, the potentials at the first conduction terminal of the first transistor Tr1 and the first conduction terminal of the second transistor Tr2 are both at high level. Accordingly, no feedthrough current arises in the first and second transistors Tr1 and Tr2.

In the selection period (time t2 to t3), the set signal IN falls to low level and the first transistor Tr1 turns off, and the second input clock signal CKb falls to low level and the second transistor Tr2 turns off. At this time, the first node NA is in a floating state. The first input clock signal CKa rises to high level, and thus the presence of the gate capacitance in the third transistor Tr3 results in the potential at the first node NA being pushed up in response to a rise in a potential at the first conduction terminal of the third transistor Tr3. In other words, a bootstrapping operation is performed at the first node NA. Note that when the potential rise produced by the bootstrapping is expressed as α, the potential at the first node NA in the selection period is expressed as Vdd−Vth+α. Accordingly, a drop in the potential at the first node NA of an amount equivalent to the threshold voltage Vth is eliminated, and furthermore, the potential at the first node NA (a gate potential of the third transistor) becomes sufficiently high. For this reason, the high-level output signal O can be outputted by the third transistor Tr3 at a low impedance.

In the reset period (time t3 to t4), the first input clock signal CKa falls to low level, and thus the output signal O falls to low level. In addition, the second input clock signal CKb rises to high level and the second transistor Tr2 turns on. At this time, the set signal IN is at low level, and thus the second transistor Tr2 changes the potential at the first node NA toward low level. The potential at the first node NA is thus reset to low level. Accordingly, the third transistor Tr3 turns off. In the reset period, the second transistor Tr2 functions as a reset transistor.

After the reset period, the second transistor Tr2 turns off periodically in response to the second input clock signal CKb, and more specifically, each time the second input clock signal CKb rises to high level. During a period until the next set period is reached, the set signal IN is at low level, and thus the second transistor Tr2 periodically changes the potential at the first node NA toward low level. Accordingly, even if the potential at the first node NA fluctuates due to leakage current flowing or the like, the potential at the first node NA is periodically pulled back to low level.

As described above, the first and second input clock signals CKa are varied between the odd-numbered stages and the even-numbered stages, and thus the same operations as in the first stage SR1 are carried out for the second stage SR2 and on, shifting by one horizontal period each time. In this manner, the shift register 100 sequentially transfers the start pulse signal ST based on the two-phase first and second supply clock signals CK1 and CK2. In other words, the shift register 100 sequentially sets the output signals O1 to On of the n-stage bistable circuits SR1 to SRn to high level based on the two-phase first and second supply clock signals CK1 and CK2.

Incidentally, Patent Document 2 discloses a configuration in which the first transistor Tr1 is omitted from the bistable circuit SR illustrated in FIG. 2. In other words, in terms of the bistable circuit SR illustrated in FIG. 2, the bistable circuit SR disclosed in Patent Document 2 includes a second transistor Tr2 in which a control terminal is connected to a third input terminal 13 and a first conduction terminal is connected to a first input terminal 11, and a third transistor Tr3 in which a control terminal is connected to a second conduction terminal of the second transistor Tr2, a first conduction terminal is connected to a second input terminal 12, and a second conduction terminal is connected to an output terminal 21. Note that in actuality, the bistable circuit SR disclosed in Patent Document 2 further includes a capacitor provided between a gate terminal of the third transistor Tr3 and the second conduction terminal, and a transistor whose gate terminal is connected to the second input terminal 12 and that is provided between the output terminal 21 and a power line that supplies low-level power; however, the capacitor and the transistor will not be described here.

According to the bistable circuit SR disclosed in Patent Document 2, in the set period, the first node NA is charged by the second transistor Tr2 only. It is thus necessary to increase the size of the second transistor Tr2 in order to carry out the charging quickly. However, increasing the size of the second transistor Tr2 increases a load on a clock line (referring to a line that supplies the first supply clock signal CK1 or the second supply clock signal CK2) connected to the gate terminal of the second transistor Tr2 via the third input terminal 13. This increases the power consumption. Alternatively, it becomes necessary to drive at lower speeds in order to suppress such an increase in power consumption.

As opposed to this, in the present embodiment, the first node NA is charged by both the first and second transistors Tr1 and Tr2. Accordingly, the first node NA can be charged quickly while reducing the size of the second transistor Tr2. This makes it possible to reduce a load on a clock line connected to the gate terminal of the second transistor Tr2 via the third input terminal 13, and thus high-speed driving can be carried out while suppressing an increase in power consumption. Furthermore, because the clock line is not connected to the gate terminal of the first transistor Tr1, the first node NA can be charged quickly without a load on the clock line increasing due to an increase in the size of the first transistor Tr1.

### 1.4 Effects

According to the present embodiment, the second transistor Tr2 changes the potential at the first node NA toward the potential of the set signal IN when the second input clock signal CKb is at an on level. Accordingly, even if the first and second transistors Tr1 and Tr2 are on at the same time, potentials at the first conduction terminal of the first transistor Tr1 (a terminal on a side opposite from the gate terminal of the third transistor Tr3) and the first conduction terminal of the second transistor Tr2 (a terminal on the side opposite to the gate terminal of the third transistor Tr3) are both at high level. As a result, no feedthrough current arises in the first and second transistors Tr2. Accordingly, it is possible to realize driving using various clock signals, with low power consumption. In addition, because the second transistor Tr2 periodically changes the potential at the first node NA toward the potential of the set signal IN (low level) in response to the second input clock signal CKb, malfunctions caused by fluctuations in the potential at the first node NA can be prevented.

In addition, according to the present embodiment, the first and second transistors Tr1 and Tr2 are on at the same time in the set period, and thus the first and second transistors Tr1 and Tr2 charge the first node NA at the same time. Accordingly, the first node NA can be charged quickly.

### 1.5 Modification Example 1

FIG. 4 is a circuit diagram illustrating a configuration of a bistable circuit SR according to Modification Example 1 of the aforementioned Embodiment 1. The bistable circuit SR according to the present variation corresponds to the bistable circuit SR in the aforementioned Embodiment 1, with a capacitor C1 being added to the output circuit 32. The capacitor C1 is provided between the gate terminal of the third transistor Tr3 and the output terminal 21. Note that a timing chart is the same as in the aforementioned Embodiment 1.

According to the present variation, when the first input clock signal CKa rises to high level in the aforementioned selection period, not only is the potential at the first node NA pushed up in response to a rise in a potential at the first conduction terminal of the third transistor Tr3 using the gate capacitance in the third transistor Tr3, but the potential at the first node NA is pushed up in response to a rise in a potential at the second conduction terminal of the third transistor Tr3 using the capacitor C1. In other words, the bootstrapping operation is performed using not only the gate capacitance in the third transistor Tr3 but also using the capacitor C1. Accordingly, the rise in potential a produced by the bootstrapping operation can be increased. Through this, the output of the third transistor Tr3 can be given a lower impedance.

### 1.6 Modification Example 2

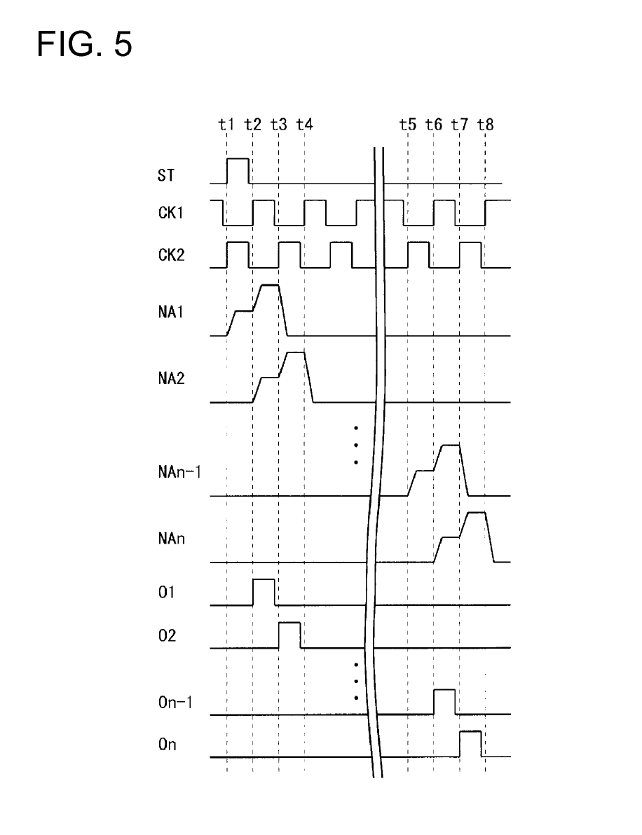

FIG. 5 is a timing chart (times t1 to t8) illustrating operations of a shift register according to Modification Example 2 of the aforementioned Embodiment 1. Note that the configuration of the bistable circuit SR is the same as in the aforementioned Embodiment 1. As illustrated in FIG. 5, the present variation differs from the aforementioned Embodiment 1 in that the duty cycle of each of the first and second supply clock signals CK1 and CK2 is less than an inverse of the number of input clock signals received by each bistable circuit SR, or in other words, is less than ½ (but is not 0). To rephrase, although the phases of the first and second supply clock signals CK1 and CK2 are shifted by one horizontal period each as in the aforementioned Embodiment 1, both signals rise to high level for a period shorter than a single horizontal period (but not 0) every two horizontal periods. Accordingly, malfunctions that can occur in the case where the first and second supply clock signals CK1 and CK2 rise to high level at the same time due to delay or the like can be prevented.

### 1.7 Modification Example 3

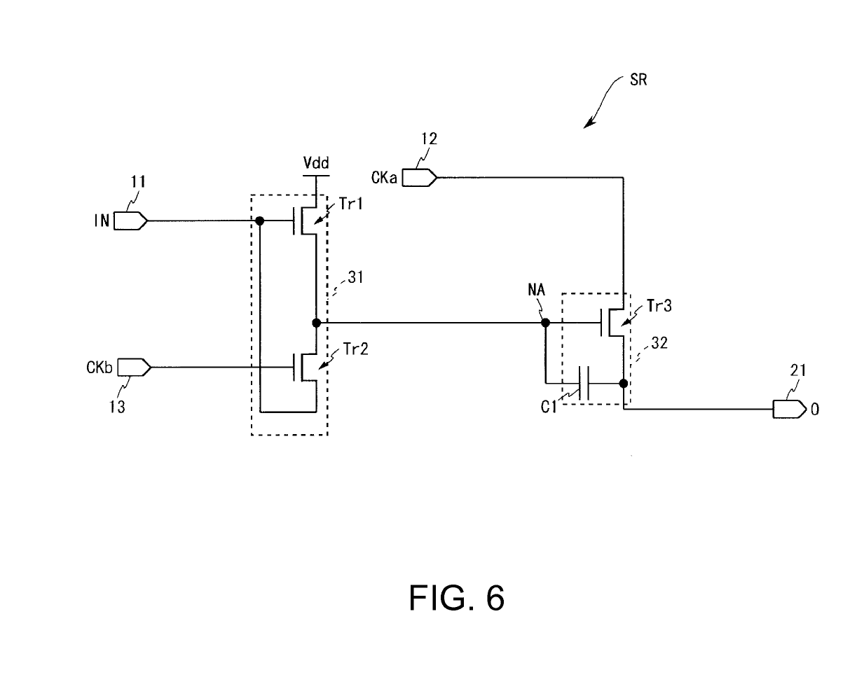

FIG. 6 is a circuit diagram illustrating a configuration of a bistable circuit SR according to Modification Example 3 of the aforementioned Embodiment 1. In the present variation, as illustrated in FIG. 6, the first conduction terminal of the first transistor Tr1 is connected to a power line that supplies high-level (Vdd) power (called a “high-level power line” hereinafter, and indicated by Vdd in the same manner as high level) instead of the first input terminal 11. Even with such a configuration, a high-level potential is applied at the first conduction terminal of the first transistor Tr1, and thus the same effects as in the aforementioned Embodiment 1 are achieved. Note that it is sufficient for the high-level potential to be applied to the first conduction terminal of the first transistor Tr1 at least when the set signal IN is at high level.

### 1.8 Modification Example 4

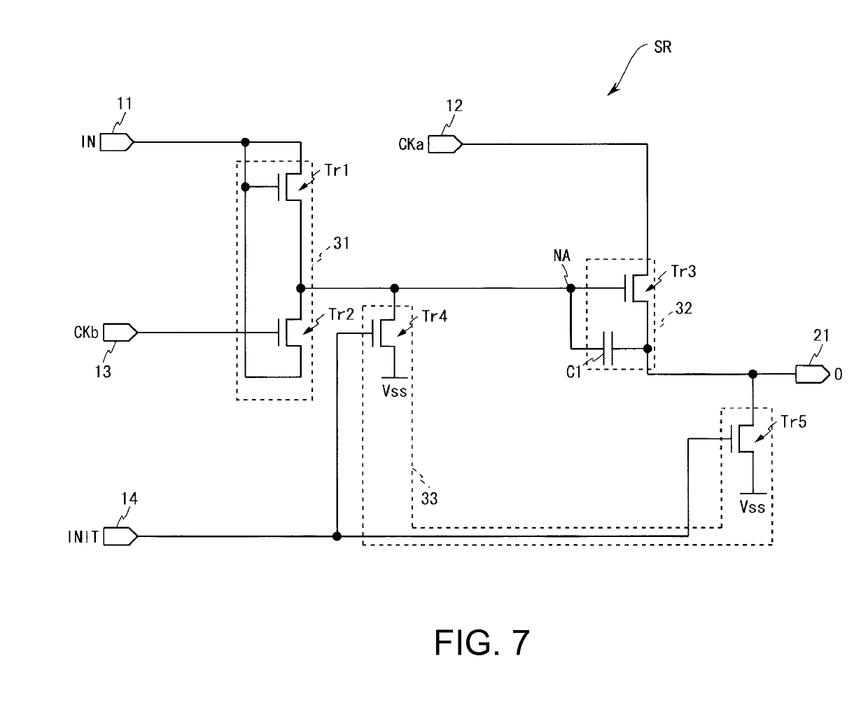

FIG. 7 is a circuit diagram illustrating a configuration of a bistable circuit SR according to Modification Example 4 of the aforementioned Embodiment 1. The bistable circuit SR according to the present variation corresponds to the bistable circuit SR in the aforementioned Modification Example 1 of Embodiment 1, with an initializing circuit 33 and a fourth input terminal 14 being added to the bistable circuit SR. The fourth input terminal 14 corresponds to an initializing input terminal. The fourth input terminal 14 is a terminal for receiving an initializing signal INIT that rises to high level at a required timing. Here, the “required timing” is immediately before the start pulse signal ST rises to high level or immediately after power has been turned on, for example. A timing chart according to the present variation is the same as in the aforementioned Embodiment 1 or Modification Example 2 thereon, with the exception of the initializing signal INIT. Note that the initializing signal INIT is at low level in the periods in which the output signals O1 to On of the first to nth stages SR1 to SRn are sequentially set to high level.

The initializing circuit 33 initializes potentials related to the output signal O in response to the initializing signal INIT. The potentials related to the output signal O specifically refer to the potential at the first node NA and the potential at the output terminal 21. Specifically, the initializing circuit 33 includes fourth and fifth transistors Tr4 and Tr5. The fourth and fifth transistors Tr4 and Tr5 correspond to a control potential initializing transistor and an output potential initializing transistor, respectively. In the fourth transistor Tr4, a gate terminal is connected to the fourth input terminal 14, a first conduction terminal is connected to the first node NA, and a second conduction terminal is connected to a power line that supplies low-level (indicated by Vss in some cases) power (called a “low-level power line” hereinafter, and indicated by Vss in the same manner as low level). In this manner, a low level potential is applied at the second conduction terminal of the fourth transistor Tr4. In the fifth transistor Tr5, a gate terminal is connected to the fourth input terminal 14, a first conduction terminal is connected to the output terminal 21, and a second conduction terminal is connected to the low-level power line Vss. In this manner, a low level potential is applied at the second conduction terminal of the fifth transistor Tr5.

The fourth transistor Tr4 turns on when the initializing signal INIT is at high level, and the potential at the first node NA is initialized to low level. The fifth transistor Tr5 turns on when the initializing signal INIT is at high level, and the potential at the output terminal 21 is initialized to low level. An initializing operation can be carried out by the fourth and fifth transistors Tr4 and Tr5. Note that the initializing operation may be forcefully carried out as necessary aside from immediately before the start pulse signal ST rises to high level or immediately after power has been turned on. In this case, the aforementioned “required timing” is immediately after each supply clock signal has been forcefully set to low level. Note that it is sufficient for the low-level potential to be supplied to the second conduction terminals of the fourth and fifth transistors Tr4 and Tr5, respectively, at least when the initializing signal INIT is at high level.

### 1.9 Modification Example 5

In the bistable circuit SR illustrated in FIG. 2 and the like, the third transistor Tr3 is off in the reset period and thereafter until the next set period, and thus the output terminal 21 maintains a floating state. In this state, when an off-leak current arises in the third transistor Tr3 and the output terminal 21 fluctuates, the potential that has fluctuated cannot be returned to its original state. A drop in an operating margin, malfunctions, or the like occur in the case of large fluctuations in the potential at the output terminal 21.

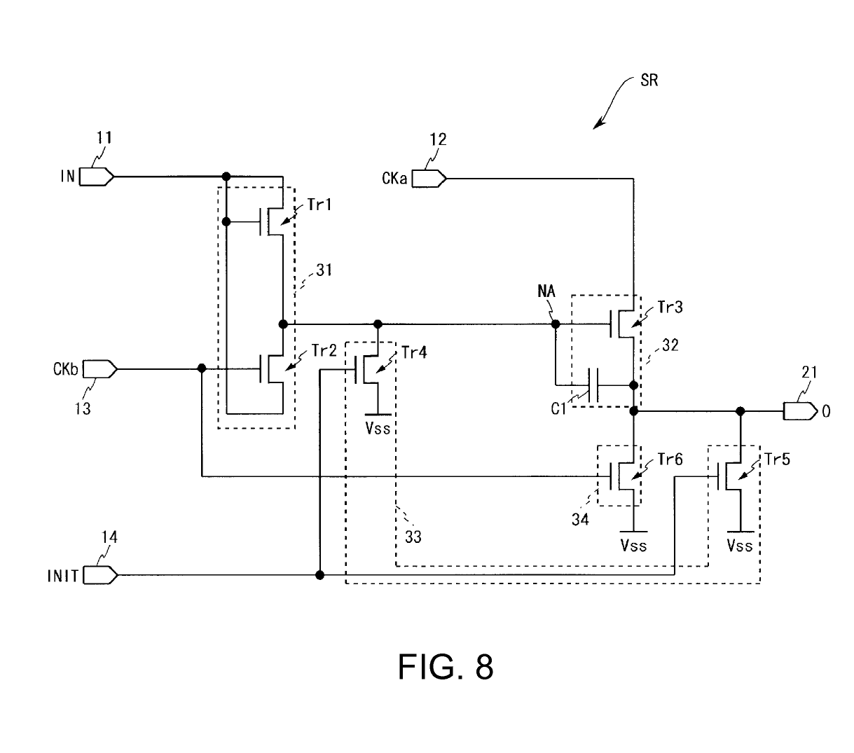

Accordingly, the bistable circuit SR according to Modification Example 5 of the aforementioned Embodiment 1 has the following configuration. FIG. 8 is a circuit diagram illustrating a configuration of the bistable circuit SR according to Modification Example 5 of the aforementioned Embodiment 1. The bistable circuit SR according to the present variation corresponds to the bistable circuit SR in the aforementioned Modification Example 4 of Embodiment 1, with an output potential holding circuit 34 being added to the bistable circuit SR. Note that the output potential holding circuit 34 may be added to the bistable circuit SR according to the aforementioned Embodiment 1 and the like as well. A timing chart according to the present variation is the same as in the aforementioned Embodiment 1 or Modification Example 2 thereon, with the exception of the initializing signal INIT.

When the second input clock signal CKb is at high level, the output potential holding circuit 34 changes the potential at the output terminal 21 toward low level. Specifically, the output potential holding circuit 34 includes a sixth transistor Tr6. The sixth transistor Tr6 corresponds to an output potential holding transistor. In the sixth transistor Tr6, a gate terminal is connected to the third input terminal 13, a first conduction terminal is connected to the output terminal 21, and a second conduction terminal is connected to the low-level power line Vss. In this manner, a low level potential is applied at the second conduction terminal of the sixth transistor Tr6. When the second input clock signal CKb is at high level, the sixth transistor Tr6 turns on and changes the potential at the output terminal 21 toward low level. In other words, in the reset period and thereafter, the sixth transistor Tr6 turns off each time the second input clock signal CKb rises to high level. Accordingly, even if there has been a fluctuation in the potential at the output terminal 21, the potential at the output terminal 21 is periodically pulled back to low level. This stabilizes the potential at the output terminal 21, and it is thus possible to prevent a drop in the operating margin, malfunctions, and so on. Note that it is sufficient for the low-level potential to be applied to the second conduction terminal of the sixth transistor Tr6 at least when the second input clock signal CKb is at high level.

### 1.10 Modification Example 6

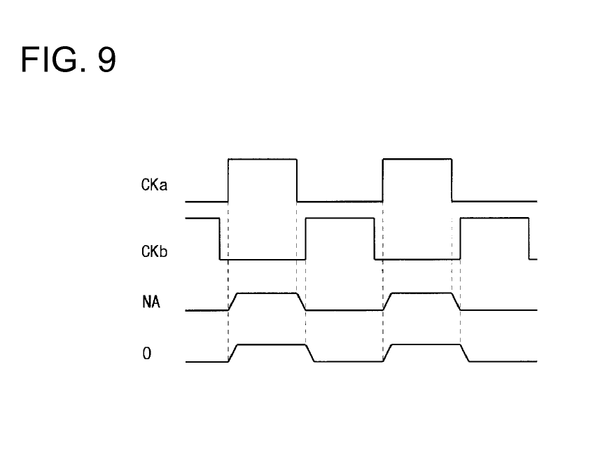

In addition to the aforementioned gate capacitance, the third transistor Tr3 has a parasitic capacitance between the gate terminal and the first conduction terminal. Accordingly, in the bistable circuit SR illustrated in FIG. 2 and so on, when the first input clock signal CKa repeats high level and low level after the reset period, fluctuations in the potential of the first input clock signal CKa are transmitted to the first node NA due to the influence of coupling caused by the parasitic capacitance in the third transistor Tr3, as indicated in FIG. 9. In the case of large potential fluctuations being transmitted to the first node NA, abnormalities will arise in the waveform of the output signal O due to the third transistor Tr3 being slightly on and the potential at the output terminal 21 rising. In the case where there are large fluctuations in the potential at the output terminal 21, it is possible that the first and second transistors Tr1 and Tr2 in the next stage connected to the output terminal 21 (the second stage SR2, here) will turn on and the first node NA in the next stage will be charged to a level that turns the third transistor Tr3 on. In this case, when the first input clock signal CKa in the second stage SR2 rises to high level, an on-level output signal O2 will be outputted from the second stage SR2 at an unintended timing, causing a malfunction.

Here, increasing the capacitance connected to the first node NA can be considered in order to suppress potential fluctuations transmitted to the first node NA. However, in order to suppress potential fluctuations transmitted to the first node NA by increasing the capacitance of, for example, the capacitor C1 connected to the first node NA in the bistable circuit SR illustrated in FIG. 4 and the like, it is necessary to sufficiently increase the size of the first capacitor C1. This will lead to an increase in the circuit scale. Meanwhile, increasing the capacitance connected to the output terminal 21 can be considered in order to suppress fluctuations in the potential at the output terminal 21 when the third transistor Tr3 is slightly on. However, the circuit scale will increase in the same manner if the capacitance connected to the output terminal 21 is increased by, for example, connecting an additional large-size capacitor to the output terminal 21. Meanwhile, with the bistable circuit SR illustrated in FIG. 8, for example, an electric charge with which the output terminal 21 is charged (and more specifically, an electric charge with which the capacitance connected to the output terminal 21 is charged) due to the third transistor Tr3 being slightly on will be discharged by the sixth transistor Tr6, resulting in increased power consumption.

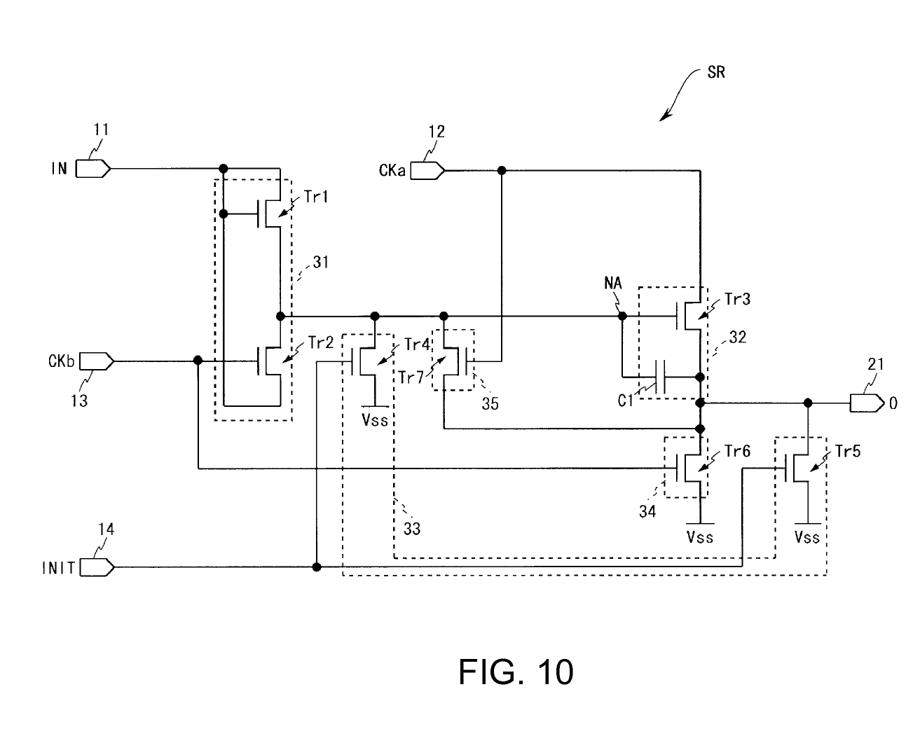

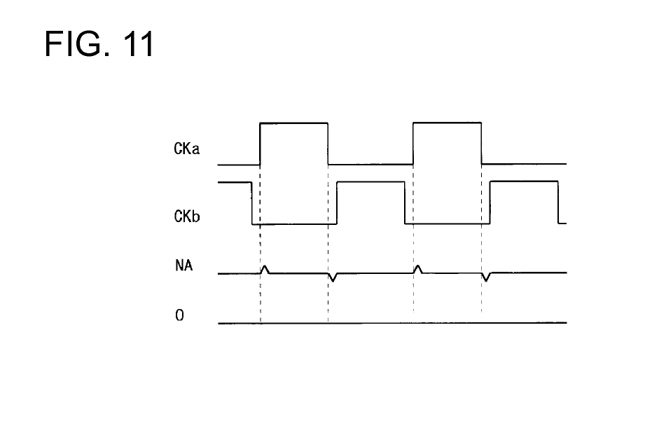

Accordingly, the bistable circuit SR according to Modification Example 6 of the aforementioned Embodiment 1 has the following configuration. FIG. 10 is a circuit diagram illustrating a configuration of the bistable circuit SR according to Modification Example 6 of the aforementioned Embodiment 1. The bistable circuit SR according to the present variation corresponds to the bistable circuit SR in the aforementioned Modification Example 5 of Embodiment 1, with a connection circuit 35 being added to the bistable circuit SR. Note that the connection circuit 35 may be added to the bistable circuit SR according to the aforementioned Embodiment 1 and the like as well. Although not illustrated in FIG. 10, the capacity load Cc, such as a scanning line of a display device, is connected to the output terminal 21 as described above (see FIG. 2). The capacity load Cc is sufficiently greater than the parasitic capacitance of the third transistor Tr3. A timing chart according to the present variation is the same as in the aforementioned Embodiment 1 or Modification Example 2 thereon, with the exception of the initializing signal INIT. However, in FIG. 11 (mentioned later), the duty cycles of the respective clock signals are less than ½, as in the aforementioned Modification Example 2 of Embodiment 1.

The connection circuit 35 electrically connects the first node NA (the gate terminal of the third transistor Tr3) and the output terminal 21 to each other when the first input clock signal CKa is at high level. Specifically, the connection circuit 35 includes a seventh transistor Tr7. The seventh transistor Tr7 corresponds to a connecting transistor. In the seventh transistor Tr7, a gate terminal is connected to the second input terminal 12, a first conduction terminal is connected to the first node NA, and a second conduction terminal is connected to the output terminal 21. The seventh transistor Tr7 is on when the first input clock signal CKa is at high level, and the first node NA and the output terminal 21 are electrically connected to each other.

FIG. 11 is a timing chart illustrating a potential change at the first node NA in the bistable circuit SR illustrated in FIG. 10. When the first input clock signal CKa changes from low level to high level after the reset period, the seventh transistor Tr7 turns on. Accordingly, the first node NA and the output terminal 21, to which the capacity load Cc is connected, are electrically connected to each other. Here, the capacity load Cc is sufficiently greater than the parasitic capacitance of the third transistor Tr3. As such, the capacitance connected to the first node NA increases, and thus the influence of coupling caused by parasitic capacitance in the third transistor Tr3 can be reduced. As a result, as illustrated in FIG. 11, fluctuation in the potential at the first node NA is reduced, and thus the third transistor Tr3 can be held in an off state. Accordingly, the potential at the output terminal 21 is held, and thus malfunctions can be prevented. Furthermore, increasing the size of the capacitor C1 is not necessary, and connecting a separate large-sized capacitor to the output terminal 21 is not necessary either. The size of the seventh transistor Tr7 can be made smaller than a capacitor having a comparatively large capacitance, and thus an increase in the circuit scale can be suppressed. In addition, because the third transistor Tr3 is held in an off state, the output terminal 21 is no longer charged by an electric charge, and thus an increase in power consumption caused by discharges made by the sixth transistor Tr6 can be prevented.

Although the gate terminal of the seventh transistor Tr7 rises to high level in the selection period, the first node NA and the output terminal 21, which are respectively connected to the first and second conduction terminals of the seventh transistor Tr7, are both at high level, and thus the seventh transistor Tr7 is held in an off state. As such, the potential at the first node NA will not be affected in the selection period even if the seventh transistor Tr7 is provided.

### 1.11 Modification Example 7

In the bistable circuit SR illustrated in FIG. 2, FIG. 7, or the like, when the bootstrapping operation is performed, the potential at the first node NA becomes Vdd−Vth+α as described above. At this time, the potentials at the gate terminal and the first conduction terminal of the first transistor Tr1 and at the gate terminal and the first conduction terminal of the second transistor Tr2, respectively, are low level (Vss). Accordingly, in the first transistor Tr1, a high voltage, specifically Vdd−Vth+α−Vss, is applied between the second conduction terminal connected to the first node NA and the gate terminal and first conduction terminal, respectively. Likewise, in the second transistor Tr2, a high voltage, specifically Vdd−Vth+α−Vss, is applied between the second conduction terminal connected to the first node NA and the gate terminal and first conduction terminal, respectively. The reliability of the first transistors Tr1 and Tr2 drop as a result.

Meanwhile, in addition to the first and second transistors Tr1 and Tr2, when the bootstrapping operation is performed in the bistable circuit SR illustrated in FIG. 7 and the like, the respective potentials at the gate terminal and the second conduction terminal are at low level (Vss) in the fourth transistor Tr4 as well. Accordingly, in the fourth transistor Tr4, a high voltage, specifically Vdd−Vth+α−Vss, is applied between the first conduction terminal connected to the first node NA and the gate terminal and first conduction terminal, respectively. The reliability of the fourth transistor Tr4 also drops as a result.

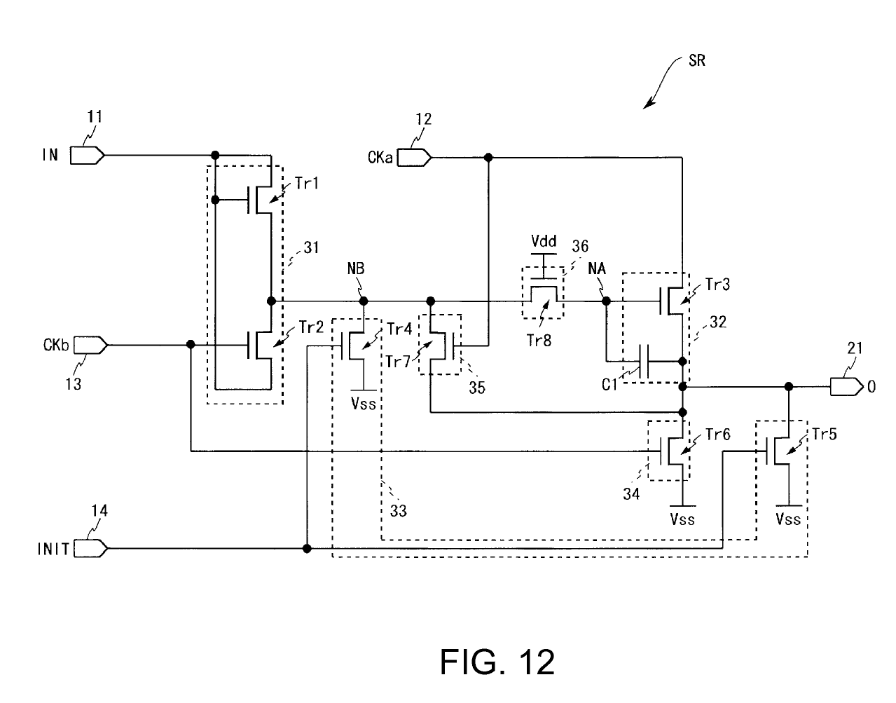

Accordingly, the bistable circuit SR according to Modification Example 7 of the aforementioned Embodiment 1 has the following configuration. FIG. 12 is a circuit diagram illustrating a configuration of the bistable circuit SR according to Modification Example 7 of the aforementioned Embodiment 1. The bistable circuit SR according to the present variation corresponds to the bistable circuit SR in the aforementioned Modification Example 6 of Embodiment 1, with a breakdown voltage circuit 36 being added to the bistable circuit SR. Note that the breakdown voltage circuit 36 may be added to the bistable circuit SR according to the aforementioned Embodiment 1 and the like as well. A timing chart according to the present variation is the same as in the aforementioned Embodiment 1 or Modification Example 2 thereon, with the exception of the initializing signal INIT.

The breakdown voltage circuit 36 is provided between the output circuit 32 and the control circuit 31, and based on a high-level potential, produces a potential difference between the gate terminal of the third transistor Tr3 and a terminal on the output circuit 32 side of the control circuit 31. Specifically, the breakdown voltage circuit 36 includes an eighth transistor Tr8. The eighth transistor Tr8 corresponds to a breakdown voltage transistor. In the eighth transistor Tr8, a gate terminal is connected to the high-level power line Vdd, a first conduction terminal is connected to the gate terminal of the third transistor Tr3, and a second conduction terminal is connected to the respective second conduction terminals of the first and second transistors Tr1 and Tr2.

In the present variation, the first node NA is a connection point between the gate terminal of the third transistor Tr3, one end of the capacitor C1, and the first conduction terminal of the eighth transistor Tr8. In this manner, in the present embodiment, the respective second conduction terminals of the first and second transistors Tr1 and Tr2, the first conduction terminal of the fourth transistor Tr4, and the first conduction terminal of the seventh transistor Tr7 are connected to the first node NA via the eighth transistor Tr8 rather than being directly connected to the first node NA. In the present variation, a connection point between the respective second conduction terminals of the first and second transistors Tr1 and Tr2, the first conduction terminal of the fourth transistor Tr4, and the first conduction terminal of the seventh transistor Tr7 will be called a “second node NB”.

When the set period starts, the eighth transistor Tr8 is in an on state. In the set period, the potentials at the first and second nodes NA and NB rise until a potential difference between the gate terminal and the second conduction terminal of the eighth transistor Tr8 reaches Vth, and the eighth transistor Tr8 turns off. In this manner, the eighth transistor Tr8 electrically disconnects the first node NA and the second node NB when the potential at the first node NA reaches a required value of Vdd−Vth. To rephrase, the eighth transistor Tr8 electrically disconnects the output circuit 32 and the control circuit 31 when the potential at the first node NA reaches the required value of Vdd−Vth.

Thereafter, in the selection period, the potential at the first node NA is Vdd−Vth+α due to the bootstrapping operation, as in the aforementioned Embodiment 1. At this time, the potentials at the gate terminal and the first conduction terminal of the first transistor Tr1 and at the gate terminal and the first conduction terminal of the second transistor Tr2, respectively, are low level (Vss), as mentioned above. Likewise, the potentials at the gate terminal and the second conduction terminal of the fourth transistor Tr4, respectively, are low level (Vss). Unlike the case where the eighth transistor Tr8 is not provided, the second node NB is electrically disconnected from the first node NA, and thus the second node NB is not affected by the rise in potential caused by the bootstrapping operation. As such, in the first and second transistors Tr1 and Tr2, a lower voltage than in the case where the eighth transistor Tr8 is not provided, specifically Vdd−Vth−Vss, is applied between the second conduction terminal and the gate terminal and first conduction terminal, respectively. Likewise, in the fourth transistor Tr4, a lower voltage than in the case where the eighth transistor Tr8 is not provided, specifically Vdd−Vth−Vss, is applied between the first conduction terminal and the gate terminal and second conduction terminal, respectively.

When the reset period arrives, the potential at the second node NB is reset to low level by the second transistor Tr2. Accordingly, the potential difference between the gate terminal and the second conduction terminal in the eighth transistor Tr8 rises above Vth, and the eighth transistor Tr8 turns on. The potential at the first node NA is thus reset to low level in the same manner as the second node NB.

In this manner, with respect to the first and second transistors Tr1 and Tr2, the voltage applied between the second conduction terminal and the gate terminal and first conduction terminal, respectively, is reduced. A drop in the reliabilities of the first and second transistors Tr1 and Tr2 can thus be suppressed. With respect to the fourth transistor Tr4, the voltage applied between the first conduction terminal and the gate terminal and second conduction terminal, respectively, is reduced. A drop in the reliability of the fourth transistor Tr4 can thus be suppressed.

### 1.12 Modification Example 8

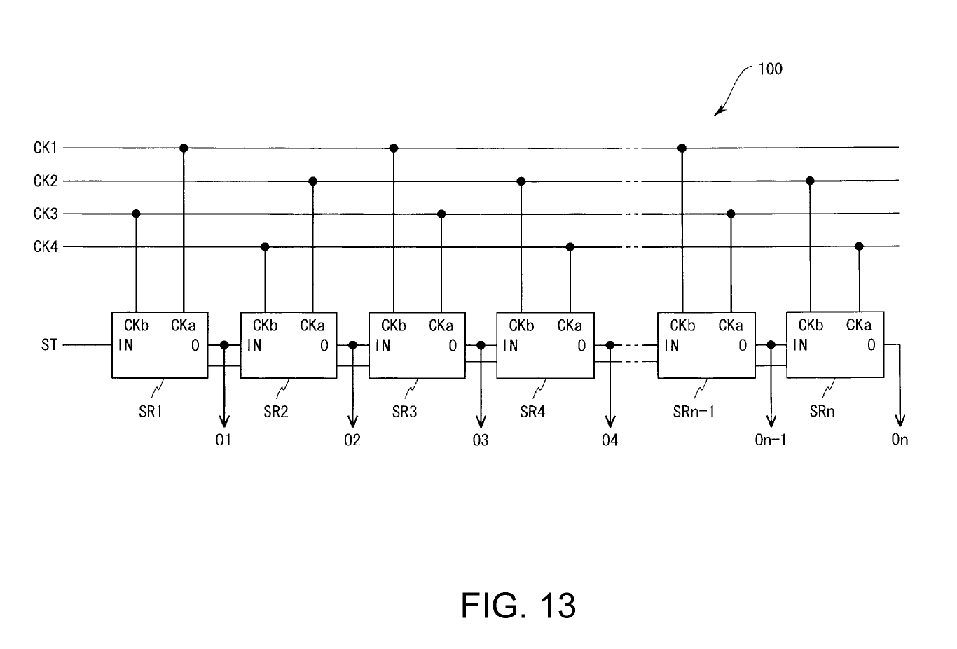

FIG. 13 is a block diagram illustrating a configuration of a shift register 100 according to Modification Example 8 of the present invention. The shift register 100 according to the present variation sequentially sets the output signals O1 to On of the n-stage bistable circuits SR1 to SRn to high level based on four-phase first to fourth supply clock signals CK1 to CK4 that cyclically repeat high level and low level. The configuration of the bistable circuit SR is the same as in the aforementioned Embodiment 1 and so on. The first stage SR1, a fifth stage SR5, a ninth stage SR9, and so on take the first and third supply clock signals CK1 and CK3 as the first and second input clock signals CKa and CKb, respectively. The second stage SR2, a sixth stage SR6, a tenth stage SR10, and so on take the second and fourth supply clock signals CK2 and CK4 as the first and second input clock signals CKa and CKb, respectively. A third stage SR3, a seventh stage SR7, an eleventh stage SR11, and so on take the third and first supply clock signals CK3 and CK1 as the first and second input clock signals CKa and CKb, respectively. A fourth stage SR4, an eighth stage SR8, a twelfth stage SR12, and so on take the fourth and second supply clock signals CK4 and CK2 as the first and second input clock signals CKa and CKb, respectively.

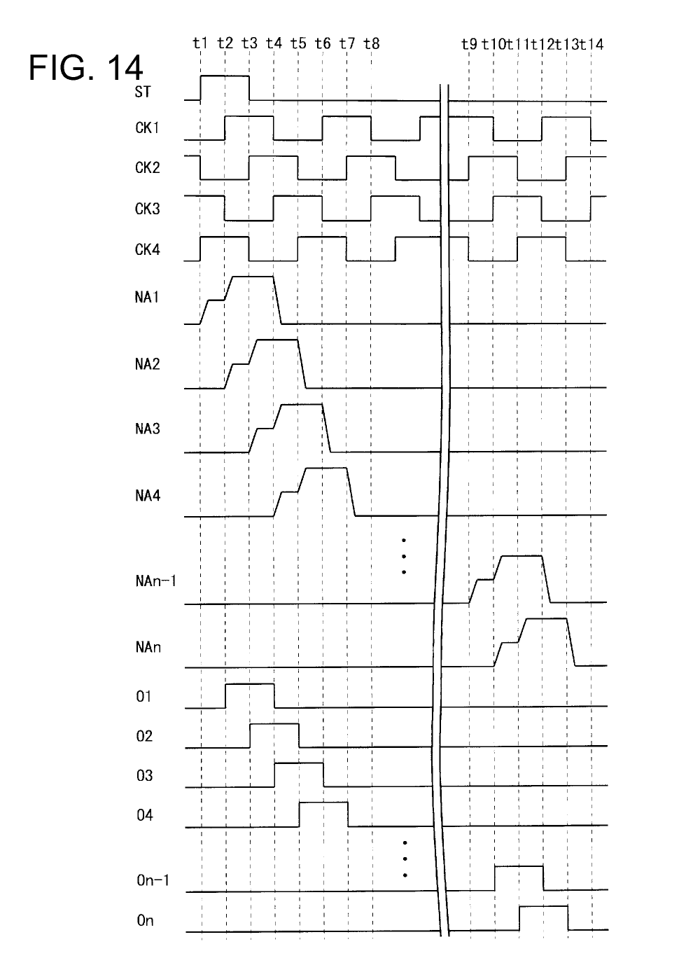

FIG. 14 is a timing chart (times t1 to t14) illustrating operations of the shift register 100 illustrated in FIG. 13. The phases of the first to fourth supply clock signals CK1 to CK4 are shifted every one horizontal period, and all rise to high level for two horizontal periods every four horizontal periods. As such, the duty cycle of each of the first to fourth supply clock signals CK1 to CK4 is an inverse of the number of input clock signals received by each bistable circuit SR, or in other words, is ½. The start pulse signal ST contains a pulse that rises to high level for two horizontal periods. Time t1 to t3, time t2 to t4, and time t4 to t6 are the set period, the selection period, and the reset period, respectively, for the first stage SR1. In the present variation, the set period and the selection period overlap for one horizontal period. In the descriptions of operations of the shift register 100 that follow, it is assumed that the configuration of the bistable circuit SR is the same as in the aforementioned Embodiment 1. However, the same descriptions hold true with respect to the respective variations of the aforementioned Embodiment 1.

In the former half of the set period (time t1 to t2), the set signal IN rises to high level and the first transistor Tr1 turns on, and the second input clock signal CKb (the second supply clock signal CK3, in the case of the first stage SR1) rises to high level and the second transistor Tr2 turns on. Accordingly, the same operations are carried out as in the set period in the aforementioned Embodiment 1.

In the latter half of the set period and the former half of the selection period (time t2 to t3), the second input clock signal CKb falls to low level and the second transistor Tr2 turns off. Meanwhile, the set signal IN is held at high level, and thus the first node NA continues to be charged by the first transistor Tr1. In addition, the first input clock signal CKa rises to high level, and thus the bootstrapping operation is performed at the first node NA as described above. For this reason, the potential at the first node NA becomes sufficiently high, which in turn makes it possible for the third transistor Tr3 to output a high-level output signal at low impedance. Note that when the potential at the first node NA increases due to the bootstrapping operation (and more specifically, rises above Vdd−Vth), the first transistor Tr1 turns off.

In the latter half of the selection period (time t3 to t4), the start pulse signal ST falls to low level, and the third transistor Tr3 continues to output the high-level output signal O. In the reset period (time t4 to t6), the same operations as in the aforementioned Embodiment 1 are carried out, and the potential at the first node NA is reset to low level.

According to the present variation, by setting a frequency of the four-phase first to fourth supply clock signals CK1 to CK4 to half of a frequency of the two-phase first and second supply clock signals CK1 and CK2 according to the aforementioned Embodiment 1, a sufficient period in which the first transistor Tr1 changes the potential at the first node NA toward high level, or in other words, a period in which the first node NA is charged, can be ensured. Accordingly, the size of the first transistor Tr1 can be reduced. In addition, a sufficient period in which the third transistor Tr3 changes the potential at the output terminal 21 toward high level, or in other words, a period in which the capacity load Cc is charged, can be ensured, and thus the size of the third transistor Tr3 can be reduced as well. Meanwhile, in a state where the sixth transistor Tr6 is used (see FIG. 8 and so on), sufficient respective periods in which the potential at the output terminal 21 is pulled back to low level can be ensured as well, and thus the size of the sixth transistor Tr6 can be reduced as well. In this manner, the circuit scale of the shift register 100 can be reduced.

### 1.13 Modification Example 9

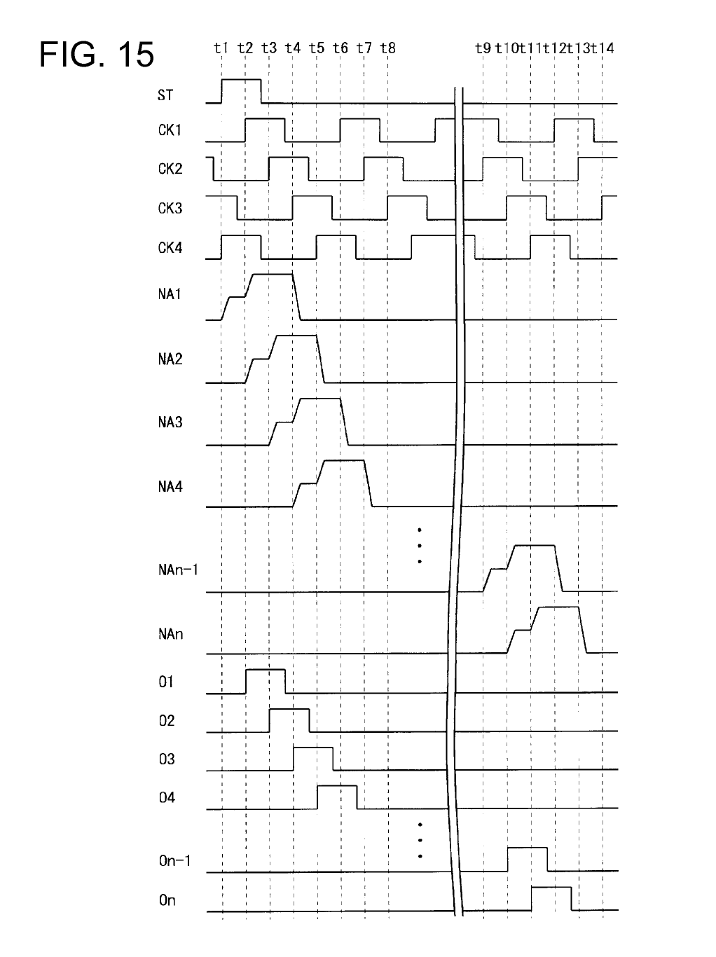

FIG. 15 is a timing chart (times t1 to t14) illustrating operations of a shift register 100 according to Modification Example 9 of the aforementioned Embodiment 1. Note that the configuration and basic operations of the bistable circuit SR are the same as in the aforementioned Modification Example 8 of Embodiment 1. As illustrated in FIG. 15, in the present variation, the duty cycle of each of the first to fourth supply clock signals CK1 to CK4 according to the aforementioned Modification Example 8 of Embodiment 1 is less than an inverse of the number of input clock signals received by each bistable circuit SR, or in other words, is less than ½ (but is not 0). To rephrase, although the phases of the first to fourth supply clock signals CK1 to CK4 are shifted by one horizontal period each as in the aforementioned Modification Example 8 of Embodiment 1, all signals rise to high level for a period longer than a single horizontal period and shorter than two horizontal periods every four horizontal periods. Accordingly, malfunctions that can occur when the first to fourth supply clock signals CK1 to CK4 rise to high level at the same time due to delay or the like can be prevented.

### 1.14 Modification Example 10

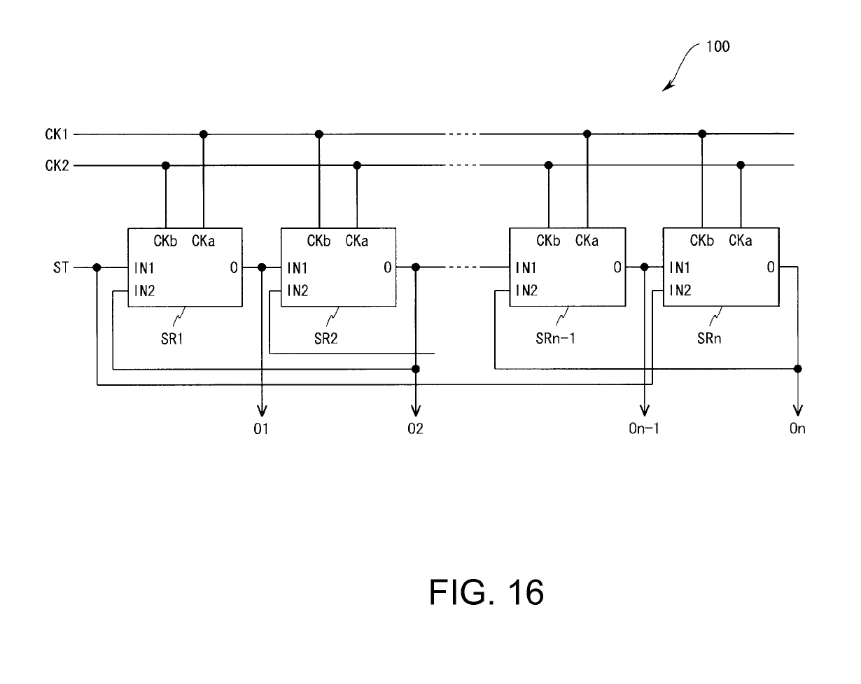

FIG. 16 is a block diagram illustrating a configuration of a shift register 100 according to Modification Example 10 of the aforementioned Embodiment 1. The supply clock signals supplied to each bistable circuit SR are the same as in the aforementioned Embodiment 1. Note that first and second switching signals UD and UDB (not illustrated) are supplied to each bistable circuit SR. The first and second switching signals UD and UDB are signals for switching between driving that sequentially sets the output signals O1 to On of the first stage SR1 to the nth stage SRn to high level in a forward direction (ascending order) and driving that sequentially sets the output signals O1 to On of the first stage SR1 to the nth stage SRn to high level in a reverse direction (descending order). The first and second switching signals UD and UDB are at high level and low level, respectively, when the shift direction is the forward direction, and are at low level and high level, respectively, when the shift direction is the reverse direction. In other words, the second switching signal UDB is a signal obtained by inverting a potential of the first switching signal UD. In the present variation, the forward direction and the reverse direction correspond to a first direction and a second direction, respectively.

The first stage SR1 takes the start pulse signal ST as a first set signal IN1 (referring to a signal that functions as the set signal IN when the shift direction is the forward direction), whereas the second stage SR2 to the nth stage SRn each takes, as the first set signal IN1, the output signal O from the previous stage, in the case of the forward direction (the following stage, in the case of the reverse direction). The nth stage SRn takes the start pulse signal ST as a second set signal IN2 (referring to a signal that functions as the set signal IN when the shift direction is the reverse direction), whereas the first stage to an n-lth stage SRn−1 each takes, as the second set signal IN2, the output signal O from the previous stage, in the case of the reverse direction (the following stage, in the case of the forward direction).

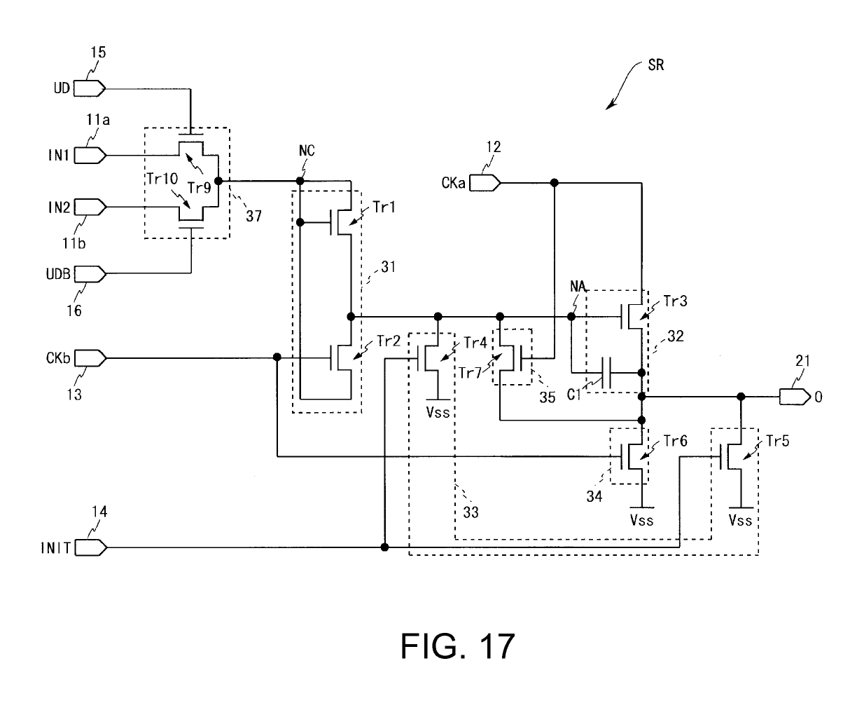

FIG. 17 is a circuit diagram illustrating a configuration of the bistable circuit SR illustrated in FIG. 16. The bistable circuit SR according to the present variation corresponds to the bistable circuit SR in the aforementioned Modification Example 6 of Embodiment 1, with a switching circuit 37 and fifth and sixth input terminals 15 and 16 being added to the bistable circuit SR and the first input terminal 11 being constituted of first and second first input terminals 11a and 11b. The first and second first input terminals 11a and 11b correspond to first and second set input terminals, respectively. The fifth and sixth input terminals 15 and 16 correspond to first and second switching input terminals, respectively. The first first input terminal 11a is a terminal for receiving the first set signal IN1. The second first input terminal 11b is a terminal for receiving the second set signal IN2. The fifth input terminal 15 is a terminal for receiving the first switching signal UD. The sixth input terminal 16 is a terminal for receiving the second switching signal UDB.

The switching circuit 37 switches the signals to be supplied to the first and second transistors Tr1 and Tr2 as the set signals IN between the first and second set signals IN1 and IN2 in response to the first and second switching input signals UD and UDB. Specifically, the switching circuit 37 includes ninth and tenth transistors Tr9 and Tr10. The ninth and tenth transistors Tr9 and Tr10 correspond to first and second switching transistors, respectively. In the ninth transistor Tr9, a gate terminal is connected to the fifth input terminal 15, a first conduction terminal is connected to the first first input terminal 11a, and a second conduction terminal is connected to the gate terminal of the first transistor Tr1, the first conduction terminal of the first transistor Tr1, and the first conduction terminal of the second transistor, respectively. In the tenth transistor Tr10, a gate terminal is connected to the sixth input terminal 16, a first conduction terminal is connected to the second first input terminal 11b, and a second conduction terminal is connected to the gate terminal of the first transistor Tr1, the first conduction terminal of the first transistor Tr1, and the first conduction terminal of the second transistor, respectively. In the present variation, a connection point between the respective second conduction terminals of the ninth and tenth transistors Tr9 and Tr10, the gate terminal and first conduction terminal of the first transistor Tr1, and the first conduction terminal of the second transistor Tr2 will be called a “third node NC”.

The ninth transistor Tr9 supplies the first set signal IN1 to the third node NC as the set signal IN when the first switching signal UD is at high level. The tenth transistor Tr10 supplies the second set signal IN2 to the third node NC as the set signal IN when the second switching signal UDB is at high level.

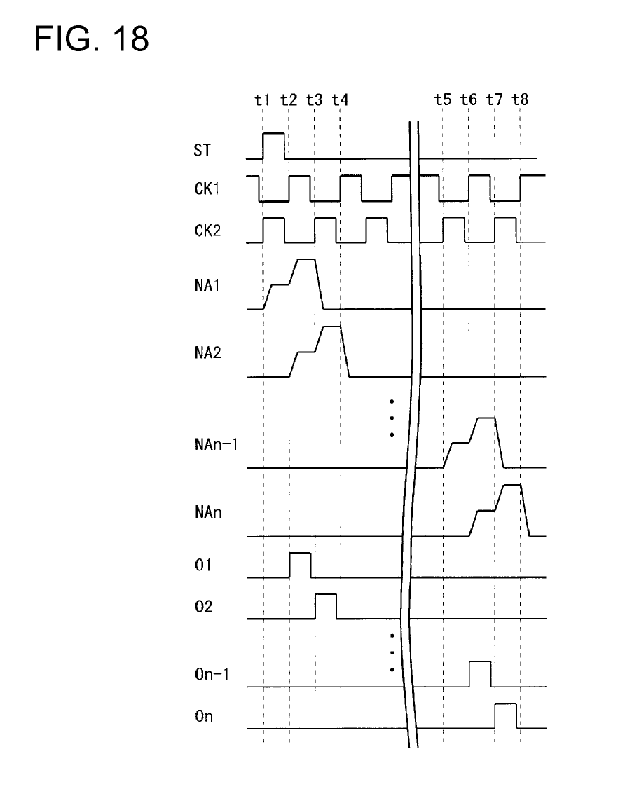

FIG. 18 is a timing chart illustrating operations of the shift register 100 illustrated in FIG. 17 during forward shifting (referring to when the shift direction is the forward direction). During forward shifting, the first switching signal UD rises to high level and the ninth transistor Tr9 is on. Accordingly, by taking the first set signal IN1 supplied to the third node NC via the ninth transistor Tr9 as the set signal IN, the same operations as those indicated by the timing chart in FIG. 5 are carried out.

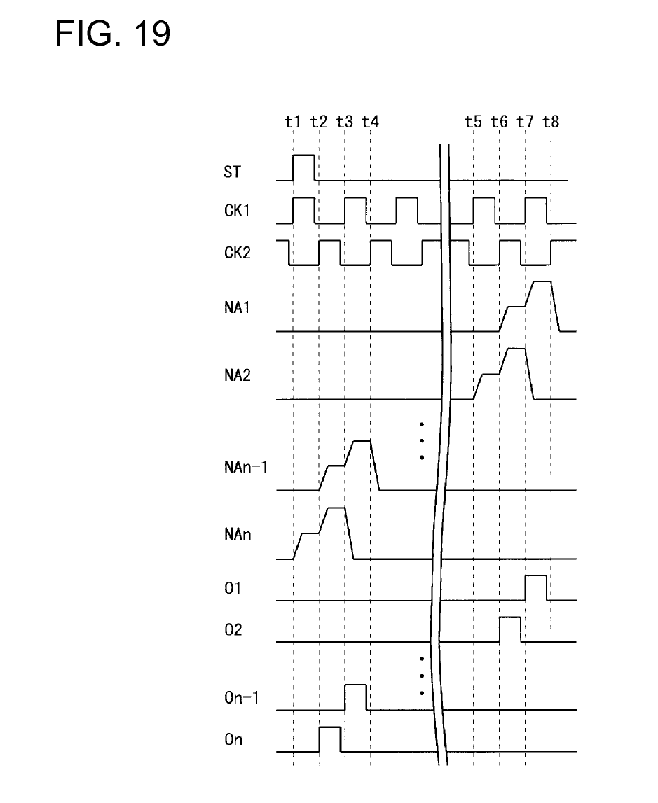

FIG. 19 is a timing chart illustrating operations of the shift register 100 illustrated in FIG. 17 during reverse shifting (referring to when the shift direction is the reverse direction). During reverse shifting, the second switching signal UDB rises to high level and the tenth transistor Tr10 is on. Accordingly, by taking the second set signal IN2 supplied to the third node NC via the tenth transistor Tr10 as the set signal IN, the operations for the first stage to the nth stage SR1 to SRn are carried out in the opposite order as during forward shifting.

According to the present variation, the output signal O from the previous stage, in the case of the forward direction, is supplied to the first and second transistors Tr1 and Tr2 as the set signal IN when the first switching signal UD is at high level, whereas the output signal O from the previous stage, in the case of the reverse direction, is supplied to the first and second transistors Tr1 and Tr2 as the set signal IN when the second switching signal UDB is at high level. Accordingly, the shift direction can be switched between the forward direction and the reverse direction.

Although the duty cycles of the first and second supply clock signals CK1 and CK2 are indicated as being less than ½ in FIG. 18 and FIG. 19, the duty cycles of the first and second supply clock signals CK1 and CK2 may be ½.

### 1.15 Modification Example 11

In the aforementioned Modification Example 10 of Embodiment 1, the high-level potential drops by the threshold voltage Vth when the first set signal IN1 is supplied to the third node NC via the ninth transistor Tr9. In other words, the potential at the third node NC becomes Vdd−Vth. As such, a gate potential of the first transistor Tr1 cannot be sufficiently increased and the first node NA is insufficiently precharged, leading to a drop in the operating margin, malfunctions, and so on in the shift register 100 during forward shifting. Likewise, the high-level potential drops by the threshold voltage Vth when the second set signal IN2 is supplied to the third node NC via the tenth transistor Tr10. In other words, the potential at the third node NC becomes Vdd−Vth. As such, the gate potential of the first transistor Tr1 cannot be sufficiently increased and the first node NA is insufficiently precharged, leading to a drop in the operating margin, malfunctions, and so on in the shift register 100 during reverse shifting.

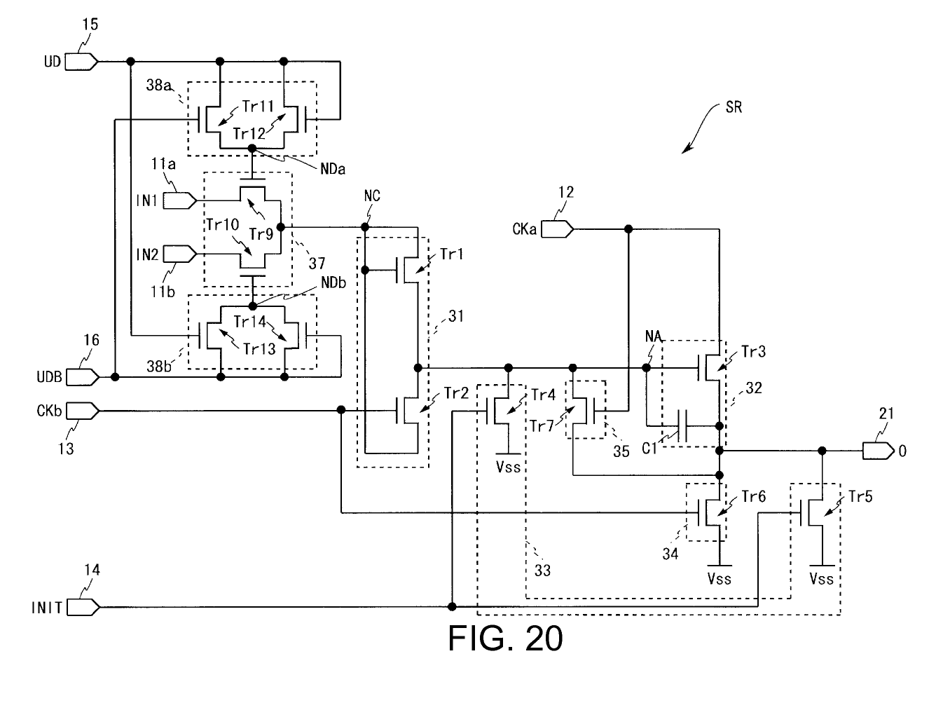

Accordingly, a bistable circuit SR according to Modification Example 11 of the aforementioned Embodiment 1 has the following configuration. FIG. 20 is a circuit diagram illustrating a configuration of the bistable circuit SR according to Modification Example 11 of the aforementioned Embodiment 1. The bistable circuit SR according to the present variation corresponds to the bistable circuit SR in the aforementioned Modification Example 10 of Embodiment 1, with first and second switching control circuits 38a and 38b being added to the bistable circuit SR.

The first switching control circuit 38a electrically connects the fifth input terminal 15 and the gate terminal of the ninth transistor Tr9 to each other via a twelfth transistor Tr12, which will be mentioned later, when the first switching signal UD is at high level. In addition, the first switching control circuit 38a changes a gate potential of the ninth transistor Tr9 toward low level when the second switching signal UDB is at high level. Specifically, the first switching control circuit 38a includes eleventh and twelfth transistors Tr11 and Tr12. The eleventh and twelfth transistors Tr11 and Tr12 correspond to a first switch-off control transistor and a first switch-on control transistor, respectively. In the eleventh transistor Tr11, a gate terminal is connected to the sixth input terminal 16, a first conduction terminal is connected to the gate terminal of the ninth transistor Tr9, and a second conduction terminal is connected to the fifth input terminal 15. In the twelfth transistor Tr12, a gate terminal and a first conduction terminal are connected to the fifth input terminal 15, and a second conduction terminal is connected to the gate terminal of the ninth transistor Tr9. In this manner, the twelfth transistor Tr12 is diode-connected, and forms a first rectifier circuit. In the present variation, a connection point between the gate terminal of the ninth transistor Tr9, the first conduction terminal of the eleventh transistor Tr11, and the second conduction terminal of the twelfth transistor Tr12 will be called a “first fourth node NDa”.

The second switching control circuit 38b electrically connects the sixth input terminal 16 and the gate terminal of the tenth transistor Tr10 to each other via a fourteenth transistor Tr14, which will be mentioned later, when the second switching signal UDB is at high level. In addition, the second switching control circuit 38b changes a gate potential of the tenth transistor Tr10 toward low level when the first switching signal UD is at high level. Specifically, the second switching control circuit 38b includes thirteenth and fourteenth transistors Tr13 and Tr14. The thirteenth and fourteenth transistors Tr13 and Tr14 correspond to a second switch-off control transistor and a second switch-on control transistor, respectively. In the fourteenth transistor Tr14, a gate terminal and a first conduction terminal are connected to the sixth input terminal 16, and a second conduction terminal is connected to the gate terminal of the tenth transistor Tr10. In this manner, the fourteenth transistor Tr14 is diode-connected, and forms a second rectifier circuit. In the thirteenth transistor Tr13, a gate terminal is connected to the fifth input terminal 15, a first conduction terminal is connected to the gate terminal of the tenth transistor Tr10, and a second conduction terminal is connected to the sixth input terminal 16. In the present variation, a connection point between the gate terminal of the tenth transistor Tr10, the first conduction terminal of the thirteenth transistor Tr13, and the second conduction terminal of the fourteenth transistor Tr14 will be called a “second fourth node NDb”.

When the first and second switching signals UD and UDB are at high level and low level, respectively, the eleventh to fourteenth transistors Tr11 to Tr14 are off, on, on, and off, respectively. However, because the twelfth transistor Tr12 is diode-connected, when a potential at the first fourth node NDa becomes Vdd−Vth, the twelfth transistor Tr12 turns off. Accordingly, the first fourth node NDa is in a floating state. In this state, when the first set signal IN1 changes from low level to high level, the first conduction terminal of the ninth transistor Tr9 and the first fourth node NDa are connected via parasitic capacitance (the gate capacitance of the ninth transistor Tr9), and thus the potential at the first fourth node NDa is pushed up to Vdd−Vth+α in response to a rise in a potential at the first first input terminal 11a. In other words, a bootstrapping operation is performed at the first fourth node NDa. In this manner, the potential at the first fourth node NDa rises to a sufficiently high potential. Accordingly, a drop in potential equivalent to the threshold voltage Vth of the ninth transistor Tr9 can be prevented and the high-level first set signal IN1 can be supplied to the first and second transistors Tr1 and Tr2. Note that the second fourth node NDb is electrically connected to the sixth input terminal 16 via the thirteenth transistor Tr13, which is on, and thus the potential at the second fourth node NDb is low level. Accordingly, the tenth transistor Tr10 can be held in an off state.

When the first and second switching signals UD and UDB are at low level and high level, respectively, the eleventh to fourteenth transistors Tr11 to Tr14 are on, off, off, and on, respectively. However, because the fourteenth transistor Tr14 is diode-connected, when a potential at the second fourth node NDb becomes Vdd−Vth, the fourteenth transistor Tr14 turns off. Accordingly, the second fourth node NDb is in a floating state. In this state, when the second set signal IN2 changes from low level to high level, the first conduction terminal of the tenth transistor Tr10 and the second fourth node NDb are connected via parasitic capacitance (the gate capacitance of the tenth transistor Tr10), and thus the potential at the second fourth node NDb is pushed up to Vdd−Vth+α in response to a rise in a potential at the second first input terminal 11b. In other words, a bootstrapping operation is performed at the second fourth node NDb. In this manner, the potential at the second fourth node NDb rises to a sufficiently high potential. Accordingly, a drop in potential equivalent to the threshold voltage Vth of the tenth transistor Tr10 can be prevented and the high-level second set signal IN2 can be supplied to the first and second transistors Tr1 and Tr2. Note that the first fourth node NDa is electrically connected to the fifth input terminal 15 via the eleventh transistor Tr11, which is on, and thus the potential at the first fourth node NDa is low level. Accordingly, the ninth transistor Tr9 can be held in an off state.

### 1.16 Modification Example 12

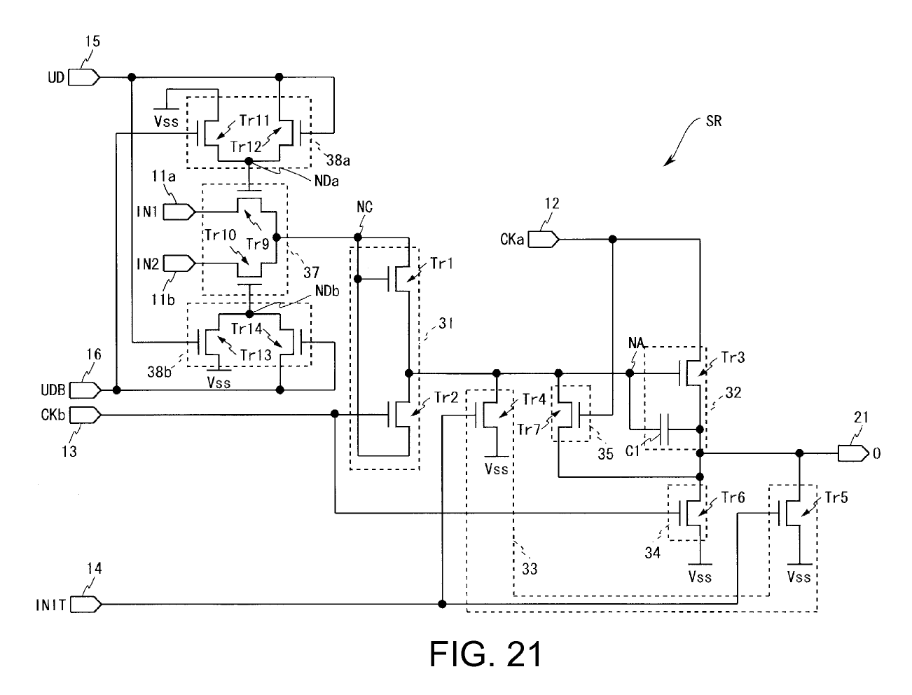

FIG. 21 is a circuit diagram illustrating a configuration of a bistable circuit SR according to Modification Example 12 of the aforementioned Embodiment 1. The present variation corresponds to the aforementioned Modification Example 11 of Embodiment 1, except that the second conduction terminal of the eleventh transistor Tr11 is connected to the low-level power line Vss instead of the fifth input terminal 15, and the second conduction terminal of the thirteenth transistor Tr13 is connected to the low-level power line Vss instead of the sixth input terminal 16. The same effects as the aforementioned Modification Example 11 of Embodiment 1 can be achieved by the present variation as well.

### 1.17 Modification Example 13

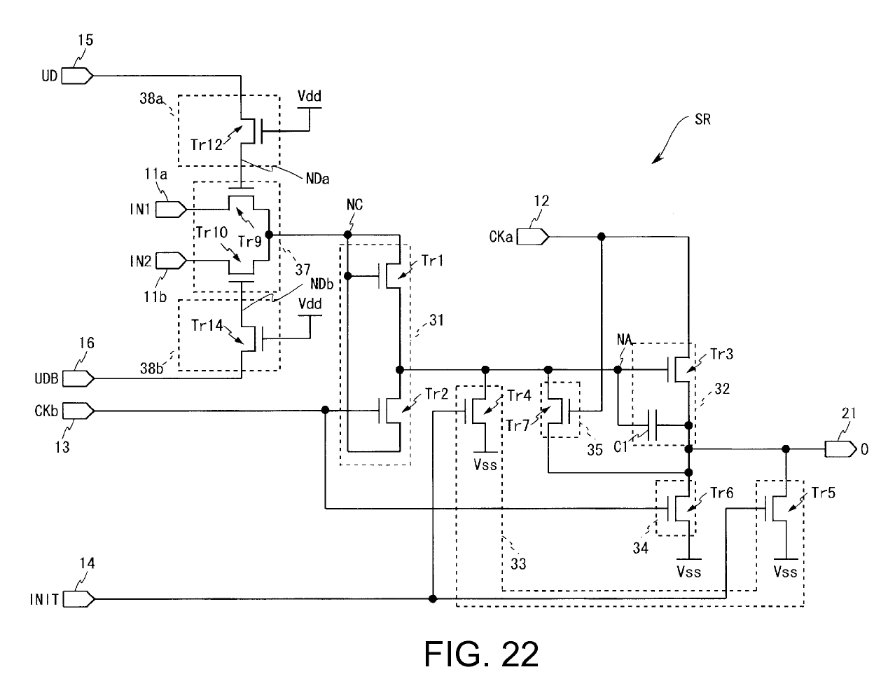

FIG. 22 is a circuit diagram illustrating a configuration of a bistable circuit SR according to Modification Example 13 of the aforementioned Embodiment 1. The present variation corresponds to the aforementioned Modification Example 11 of Embodiment 1, except that the eleventh and thirteenth transistors Tr11 and Tr13 are omitted and the respective gate terminals of the twelfth and fourteenth transistors Tr12 and Tr14 are connected to the high-level power line Vdd Like the aforementioned Modification Example 11 of Embodiment 1, according to the present variation, a drop in potential equivalent to the threshold voltage Vth of the ninth transistor Tr9 can be prevented and the high-level first set signal IN1 can be supplied to the first and second transistors Tr1 and Tr2 when the first and second switching signals UD and UDB are at high level and low level, respectively, and a drop in potential equivalent to the threshold voltage Vth of the tenth transistor Tr10 can be prevented and the high-level second set signal IN2 can be supplied to the first and second transistors Tr1 and Tr2 when the first and second switching signals UD and UDB are at low level and high level, respectively. Meanwhile, because the twelfth transistor Tr12 is not diode-connected, the potential at the first fourth node NDa can be set to low level without using the eleventh transistor Tr11 when the first and second switching signals UD and UDB are at low level and high level, respectively. Likewise, because the fourteenth transistor Tr14 is not diode-connected, the potential at the second fourth node NDb can be set to low level without using the thirteenth transistor Tr13 when the first and second switching signals UD and UDB are at high level and low level, respectively.

### 1.18 Modification Example 14

In the bistable circuit SR illustrated in FIG. 20 or in FIG. 21, when the bootstrapping operation is performed at the first fourth node NDa while the first and second switching signals UD and UDB are at high level and low level, respectively, the potential at the first fourth node NDa becomes Vdd−Vth+α, as described earlier. The potential at the gate terminal of the eleventh transistor Tr11 is low level (Vss) at this time. In the bistable circuit SR illustrated in FIG. 21, the potential at the second conduction terminal of the eleventh transistor Tr11 is low level as well. As such, in the bistable circuit SR illustrated in FIG. 20 or in FIG. 21, a high voltage, specifically Vdd−Vth+α−Vss, is applied between the first conduction terminal and the gate terminal of the eleventh transistor Tr11. The same high voltage is applied between the first conduction terminal and the second conduction terminal of the eleventh transistor Tr11 in the bistable circuit SR illustrated in FIG. 21 as well. The reliability of the eleventh transistor Tr11 drops as a result.

Meanwhile, in the bistable circuit SR illustrated in FIG. 20 or in FIG. 21, when the bootstrapping operation is performed at the second fourth node NDb while the first and second switching signals UD and UDB are at low level and high level, respectively, the potential at the second fourth node NDb becomes Vdd−Vth+α, as described earlier. The potential at the gate terminal of the thirteenth transistor Tr13 is low level (Vss) at this time. In the bistable circuit SR illustrated in FIG. 21, the potential at the second conduction terminal of the thirteenth transistor Tr13 is low level as well. As such, in the bistable circuit SR illustrated in FIG. 20 or in FIG. 21, a high voltage, specifically Vdd−Vth+α−Vss, is applied between the first conduction terminal and the gate terminal of the thirteenth transistor Tr13. The same high voltage is applied between the first conduction terminal and the second conduction terminal of the thirteenth transistor Tr13 in the bistable circuit SR illustrated in FIG. 21 as well. The reliability of the thirteenth transistor Tr13 drops as a result.

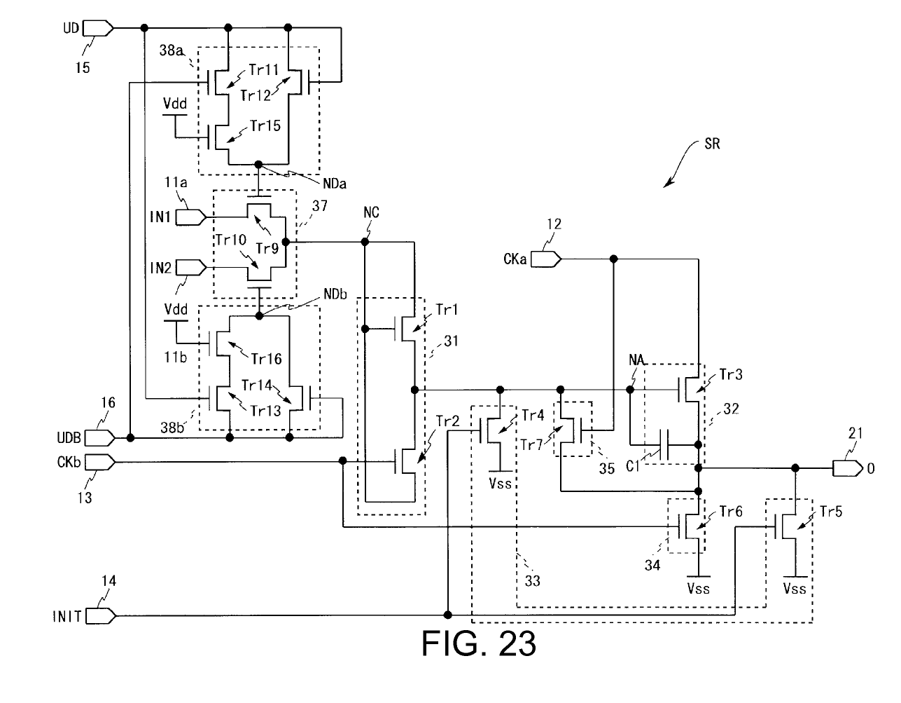

Accordingly, the bistable circuit SR according to Modification Example 14 of the aforementioned Embodiment 1 has the following configuration. FIG. 23 is a circuit diagram illustrating a configuration of the bistable circuit SR according to Modification Example 14 of the aforementioned Embodiment 1. The present variation corresponds to the aforementioned Modification Example 11 of Embodiment 1, with a fifteenth transistor Tr15 being added to the first switching control circuit 38a and a sixteenth transistor Tr16 being added to the second switching control circuit 38b. The fifteenth and sixteenth transistors Tr15 and Tr16 correspond to a first switching breakdown voltage transistor and a second switching breakdown voltage transistor, respectively. In the fifteenth transistor Tr15, a gate terminal is connected to the high-level power line Vdd, a first conduction terminal is connected to the first fourth node NDa, and a second conduction terminal is connected to the first conduction terminal of the eleventh transistor Tr11. In the sixteenth transistor Tr16, a gate terminal is connected to the high-level power line Vdd, a first conduction terminal is connected to the second fourth node NDb, and a second conduction terminal is connected to the first conduction terminal of the thirteenth transistor Tr13.

When the first and second switching signals UD and UDB are at high level and low level, respectively, the potential at the first fourth node NDa rises until a potential difference between the gate terminal and the first conduction terminal of the fifteenth transistor Tr15 reaches Vth, and the fifteenth transistor Tr15 turns off. In this manner, when the potential at the first fourth node NDa (the first conduction terminal of the fifteenth transistor Tr15) reaches a required value of Vdd−Vth, the fifteenth transistor Tr15 electrically disconnects the first fourth node NDa and the first conduction terminal of the eleventh transistor Tr11. Accordingly, the potential at the first conduction terminal of the eleventh transistor Tr11 will not rise even when a bootstrapping operation is performed at the first fourth node NDa, and thus the voltage applied between the terminals in the eleventh transistor Tr11 is reduced.

When the first and second switching signals UD and UDB are at low level and high level, respectively, the potential at the second fourth node NDb rises until a potential difference between the gate terminal and the first conduction terminal of the sixteenth transistor Tr16 reaches Vth, and the sixteenth transistor Tr16 turns off. In this manner, when the potential at the second fourth node NDb (the first conduction terminal of the sixteenth transistor Tr16) reaches the required value of Vdd−Vth, the sixteenth transistor Tr16 electrically disconnects the second fourth node NDb and the first conduction terminal of the thirteenth transistor Tr13. Accordingly, the potential at the first conduction terminal of the thirteenth transistor Tr13 will not rise even when a bootstrapping operation is performed at the second fourth node NDb, and thus the voltage applied between the terminals in the thirteenth transistor Tr13 is reduced.

### 1.19 Modification Example 15

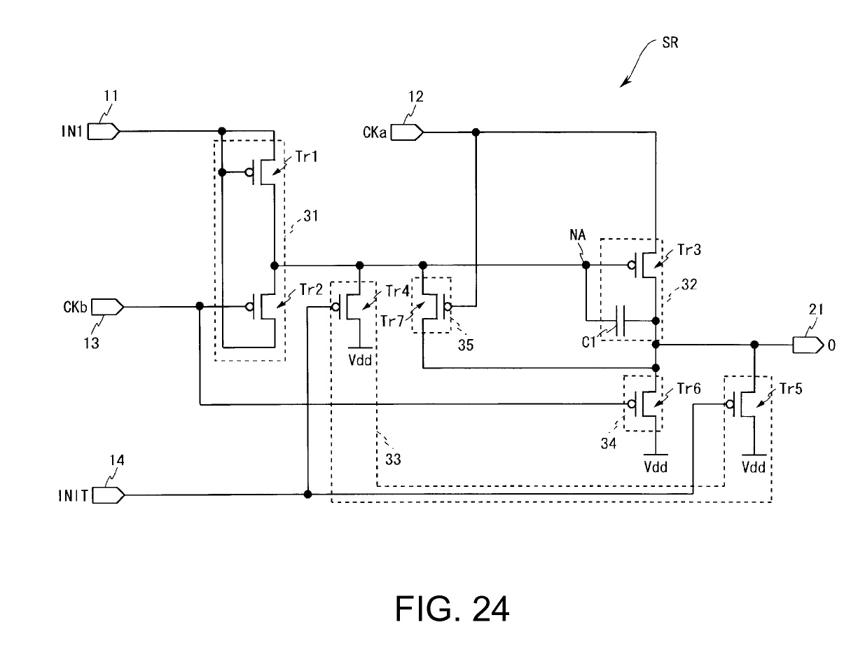

FIG. 24 is a circuit diagram illustrating a configuration of a bistable circuit SR according to Modification Example 15 of the aforementioned Embodiment 1. The present variation corresponds to the aforementioned Modification Example 6 of Embodiment 1, except that the conductivity types of the respective transistors have been changed to p-channel types. Connection relationships between the respective elements in the bistable circuit SR are the same as in the aforementioned Modification Example 6 of Embodiment 1. Note that the conductivity types of the transistors may be changed to p-channel types in the aforementioned Embodiment 1 or other variations thereon as well.

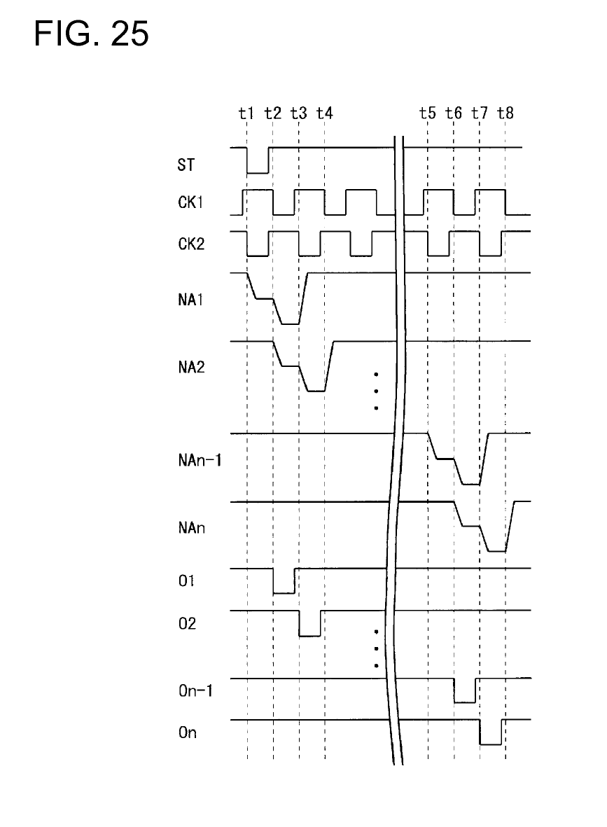

FIG. 25 is a timing chart (times t1 to t8) illustrating operations of the shift register 100 according to the present variation. In the present variation, low level and high level correspond to on level and off level, respectively. The timing chart illustrated in FIG. 25 corresponds to the timing chart illustrated in FIG. 5, with potential levels reversed. Note that the potential levels are reversed for the initializing signal INIT as well. Descriptions of operations according to the present variation are the same as the descriptions of operations according to Embodiment 1 and so on, with the exception of the potential levels being reversed, and thus detailed descriptions will be omitted here. Although the duty cycles of the first and second supply clock signals CK1 and CK2 are indicated as being less than ½ in FIG. 25, the duty cycles of the first and second supply clock signals CK1 and CK2 may be ½.

### 1.20 Modification Example 16

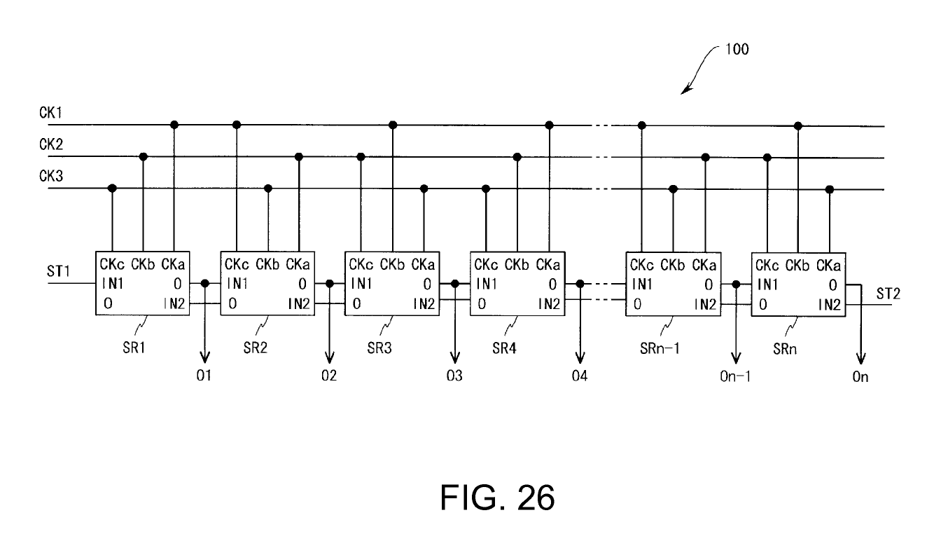

FIG. 26 is a block diagram illustrating a configuration of a shift register 100 according to Modification Example 16 of the aforementioned Embodiment 1. The shift register 100 according to the present variation sequentially sets output signals O1 to On of n-stage bistable circuits SR1 to SRn to high level in the forward direction or the reverse direction based on three-phase first to third supply clock signals CK1 to CK3 that cyclically repeat high level and low level. The phases of the first to third supply clock signals CK1 to CK3 are shifted every one horizontal period, and all rise to high level for one horizontal period every three horizontal periods. The first to third supply clock signals CK1 to CK3 sequentially rise to high level in ascending order during forward shifting and sequentially rise to high level in descending order during reverse shifting. As such, duty cycles of the first to third supply clock signals CK1 to CK3 are an inverse of the number of input clock signals received by each bistable circuit SR, or in other words, are ⅓. However, the duty cycles of the first to third supply clock signals CK1 to CK3 may be less than an inverse of the number of input clock signals received by each bistable circuit SR, or in other words, may be less than ⅓ (but not 0).

The bistable circuit SR according to the present variation receives a third input clock signal CKc in addition to first and second input clock signals CKa and CKb. The first stage SR1, the fourth stage SR4, the seventh stage SR7, and so on take the first to third supply clock signals CK1 to CK3 as the first to third input clock signals CKa to CKc, respectively. The second stage SR2, the fifth stage SR5, the eighth stage SR8, and so on take the second, third, and first supply clock signals CK2, CK3, and CK1 as the first to third input clock signals CKa to CKc, respectively. The third stage SR3, the sixth stage SR6, the ninth stage SR9, and so on take the third, first, and second supply clock signals CK3, CK1, and CK2 as the first to third input clock signals CKa to CKc, respectively. In the present variation, the first to third input clock signals CKa to CKc correspond to a first clock signal, a second second clock signal, and a first second clock signal, respectively.

The first stage SR1 takes a first start pulse signal ST1 for forward shifting as a first set signal IN1, and the second stage SR2 to the nth stage SRn each takes, as the first set signal IN1, the output signal O from the previous stage, in the case of the forward direction. Note that the first start pulse signal ST1 corresponds to the start pulse signal ST in the aforementioned Embodiment 1 or the variations thereon. The nth stage SRn takes a second start pulse signal ST2 for reverse shifting as the second set signal IN2, whereas the first stage to an n-lth stage SRn−1 each takes, as the second set signal IN2, the output signal O from the previous stage, in the case of the reverse direction. As such, by varying the start pulse signals ST received by the first stage SR1 and the nth stage SRn, the nth stage SRn can be prevented from malfunctioning during forward shifting and the first stage SR1 can be prevented from malfunctioning during reverse shifting.

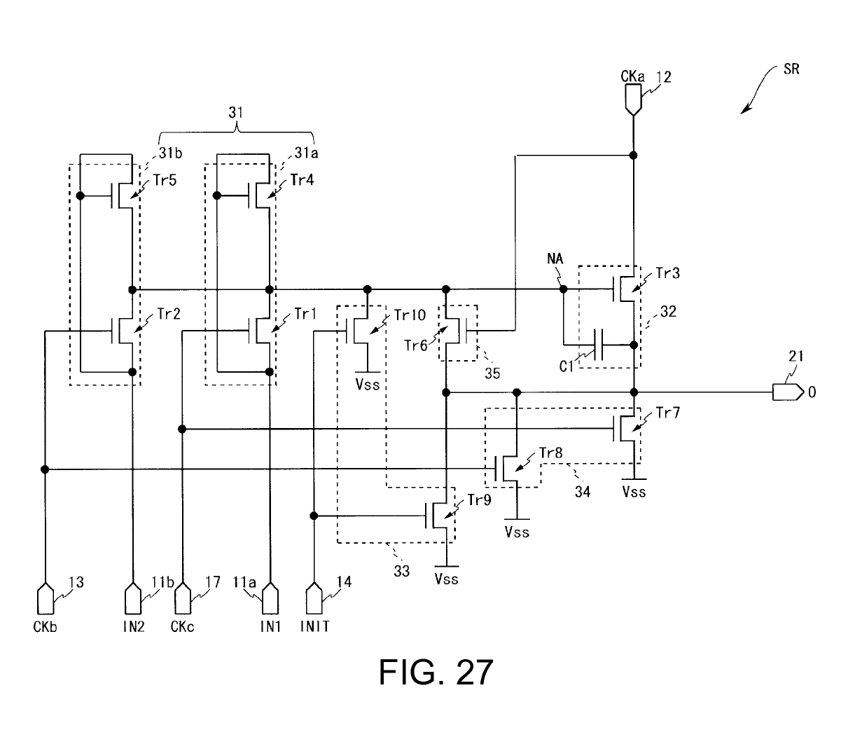

FIG. 27 is a circuit diagram illustrating a configuration of the bistable circuit SR illustrated in FIG. 26. The bistable circuit SR according to the present variation corresponds to the bistable circuit SR according to the aforementioned Modification Example 6 of Embodiment 1, with the control circuit 31 being constituted of first and second control circuits 31a and 31b, a seventh input terminal 17 being added, and the first input terminal 11 being constituted of the first and second first input terminals 11a and 11b. However, in the present variation, correspondence relationships of the transistors (with the exception of the third transistor Tr3) differ from those in the aforementioned Embodiment 1 or the variations thereon. The sixth, seventh, ninth, and tenth transistors Tr6, Tr7, Tr9, and Tr10 according to the present variation respectively correspond to the seventh, sixth, fifth, and fourth transistors Tr7, Tr6, Tr5, and Tr4 according to the aforementioned Embodiment 1 or the variations thereon. In the present variation, the third and seventh input terminals 13 and 17 correspond to second and first second clock input terminals, respectively. The seventh input terminal is a terminal for taking one of the three-phase first to third supply clock signals CK1 to CK3 as the third input clock signal CKc.

The first control circuit 31a changes the potential at the first node NA (the gate terminal of the third transistor) in response to the first set signal IN1 or the third input clock signal CKc. The first control circuit 31a is a circuit for changing the potential at the first node NA during forward shifting. However, the first control circuit 31a also has a function for resetting the potential at the first node NA to low level during reverse shifting. Specifically, the first control circuit 31a includes the first and fourth transistors Tr1 and Tr4. The first and fourth transistors Tr1 and Tr4 according to the present variation correspond to a first second control transistor and a first first control transistor, respectively. Meanwhile, the first and fourth transistors Tr1 and Tr4 according to the present variation respectively correspond to the second and first transistors Tr2 and Tr1 according to the aforementioned Embodiment 1 or the variations thereon. With respect to connections of the first and fourth transistors Tr1 and Tr4, if the first input terminal 11 and the third input terminal 13 are replaced by the first first input terminal 11a and the seventh input terminal 17, respectively, in the connections of the second and first transistors Tr2 and Tr1 according to the aforementioned Embodiment 1 or the variations thereon, the same descriptions apply.

The second control circuit 31b changes the potential at the first node NA in response to the second set signal IN2 or the second input clock signal CKb. The second control circuit 31b is a circuit for changing the potential at the first node NA during reverse shifting. However, the second control circuit 31b also has a function for resetting the potential at the first node NA to low level during forward shifting. Specifically, the second control circuit 31b includes the second and fifth transistors Tr2 and Tr5. The second and fifth transistors Tr2 and Tr5 according to the present variation correspond to a second second control transistor and a second first control transistor, respectively. In the second transistor Tr2, a gate terminal is connected to the third input terminal 13, a first conduction terminal is connected to the second first input terminal 11b, and a second conduction terminal is connected to the first node NA. In the fifth transistor Tr5, a gate terminal and a first conduction terminal are connected to the second first input terminal 11b. As such, like the fourth transistor Tr4, the fifth transistor Tr5 has a diode connection.

In the present variation, a first control transistor is constituted of the fourth and fifth transistors Tr4 and Tr5, and a second control transistor is constituted of the first and second transistors Tr1 and Tr2.

The first transistor Tr1 changes the potential at the first node NA toward a potential of the first set signal IN1 when the third input clock signal CKc is at high level. The second transistor Tr2 changes the potential at the first node NA toward a potential of the second set signal IN2 when the second input clock signal CKb is at high level. The fourth transistor Tr4 changes the potential at the first node NA toward high level when the first set signal IN1 is at high level. The fifth transistor Tr5 changes the potential at the first node NA toward high level when the second set signal IN2 is at high level.

The output potential holding circuit 34 changes the potential at an output terminal 21 toward low level in response to the second input clock signal CKb or the third input clock signal CKc. Specifically, the output potential holding circuit 34 includes the seventh and eighth transistors Tr7 and Tr8. In the seventh transistor Tr7, a gate terminal is connected to the seventh input terminal, a first conduction terminal is connected to the output terminal 21, and a second conduction terminal is connected to a low-level power line Vss. In the eighth transistor Tr8, a gate terminal is connected to the third input terminal 13, a first conduction terminal is connected to the output terminal 21, and a second conduction terminal is connected to the low-level power line Vss. When the third input clock signal CKc is at high level, the seventh transistor Tr7 turns on and changes the potential at the output terminal 21 toward low level. When the second input clock signal CKb is at high level, the eighth transistor Tr8 turns on and changes the potential at the output terminal 21 toward low level. In the reset period and thereafter, the seventh and eighth transistors Tr7 and Tr8 turn on each time the third and second input clock signals CKc and CKb rise to high level, respectively. Accordingly, even if there has been a fluctuation in the potential at the output terminal 21, the potential at the output terminal 21 is periodically pulled back to low level. Note that it is sufficient for the low-level potential to be applied to the second conduction terminal of the seventh transistor Tr7 at least when the third input clock signal CKc is at high level. Likewise, it is sufficient for the low-level potential to be applied to the second conduction terminal of the eighth transistor Tr8 at least when the second input clock signal CKb is at high level. Furthermore, the configuration may be such that only one of the seventh and eighth transistors Tr7 and Tr8 is provided.

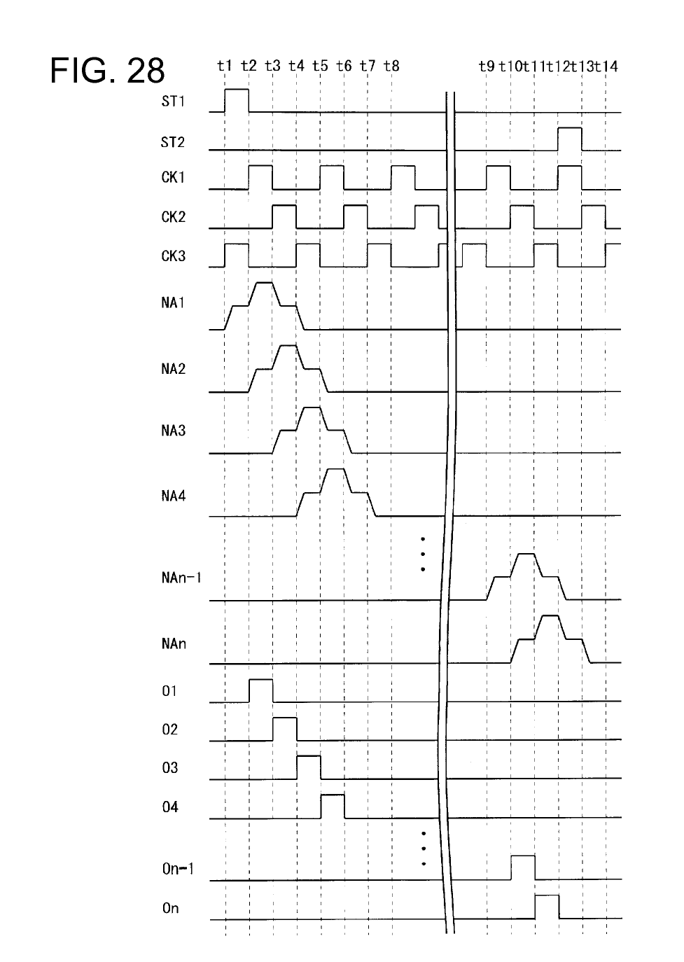

FIG. 28 is a timing chart (times t1 to t14) illustrating operations of the shift register 100 illustrated in FIG. 26 during forward shifting. As described above, the three-phase first to third supply clock signals CK1 to CK3 sequentially rise to high level in ascending order during forward shifting. As illustrated in FIG. 28, when the first start pulse signal ST1 is at high level, the third supply clock signal CK3 is at high level. The second start pulse signal ST2 rises to high level after, for example, the output signal On from the nth stage SRn has risen to high level. Time t1 to t2, time t2 to t3, and time t3 to t5 are the set period, the selection period, and the reset period, respectively, for the first stage SR1. Hereinafter, operations according to the present variation will be described focusing on the first and second control circuits 31a and 31b, and descriptions related to other circuits will be omitted for the same of simplicity.

In the set period (time t1 to t2), the first set signal IN1 (the first start pulse signal ST1, in the case of the first stage SR1) rises to high level and the fourth transistor Tr4 turns on, and the third input clock signal CKc (the third supply clock signal CK3, in the case of the first stage SR1) rises to high level and the first transistor Tr1 turns on. At this time, the second set signal IN2 (the output signal O2 from the second stage SR2, in the case of the first stage SR1) and the second input clock signal CKb (the second supply clock signal CK2, in the case of the first stage SR1) are at low level, and thus the second and fifth transistors Tr2 and Tr5 are off. Accordingly, the first node NA is charged (precharged, here) in the same manner as in the set period according to the aforementioned Embodiment 1 or the variations thereon.

In the selection period (time t2 to t3), the first set signal IN1 falls to low level and the fourth transistor Tr4 turns off, the third input clock signal CKc falls to low level and the first transistor Tr1 turns off, and the first input clock signal CKa (the first supply clock signal CK1, in the case of the first stage SR1) rises to high level and the aforementioned bootstrapping operation is performed. For this reason, the high-level output signal O is outputted by the third transistor Tr3 at a low impedance.

In the former half of the reset period (time t3 to t4), the first input clock signal CKa falls to low level, and thus the output signal O falls to low level. In addition, the second input clock signal CKb rises to high level and the second transistor Tr2 turns on. At this time, the second set signal IN2 is at high level, and thus the first node NA holds its precharge potential.

In the latter half of the reset period (time t4 to t5), the second input clock signal CKb falls to low level and the second transistor Tr2 turns off, and the third input clock signal CKc rises to high level and the first transistor Tr1 turns on. At this time, the first set signal IN1 is at low level, and thus the first transistor Tr1 changes the potential at the first node NA toward low level. In this manner, a reset is carried out using the first transistor Tr1 during forward shifting.

After the reset period, the second and first transistors Tr2 and Tr1 respectively turn on in response to the second and third input clock signals CKb and CKc periodically (and more specifically, each time the second and third input clock signals CKb and CKc rise to high level). Accordingly, the potential at the first node NA can be pulled back to low level with certainty, using the second and first transistors Tr1 and Tr2.

As described above, the first to third input clock signals CKa to CKc are varied between the first stage SR1, fourth stage SR4, seventh stage SR7, and so on, the second stage SR2, fifth stage SR5, eighth stage SR8, and so on, and the third stage SR3, sixth stage SR6, ninth stage SR9, and so on, and thus the same operations as for the first stage SR1 are carried out for the second stage SR2 and on, while being shifted by one horizontal period each. In this manner, the shift register 100 sequentially transfers the start pulse signal ST1 in the forward direction based on the three-phase first to third supply clock signals CK1 to CK3. In other words, the shift register 100 can sequentially set the output signals O1 to On of the n-stage bistable circuits SR1 to SRn to high level in ascending order based on the three-phase first to third supply clock signals CK1 to CK3.

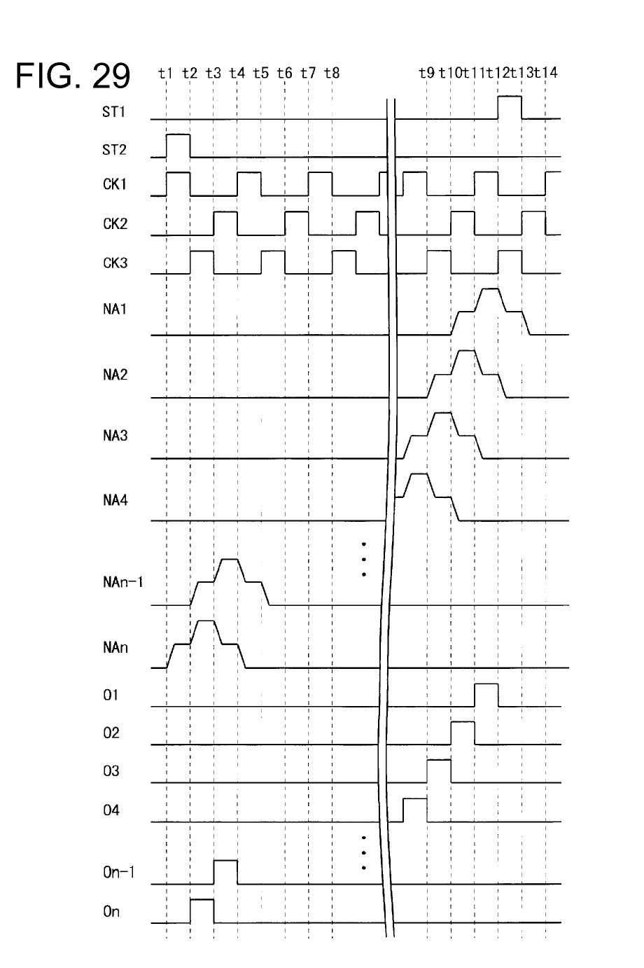

FIG. 29 is a timing chart (times t1 to t14) illustrating operations of the shift register 100 illustrated in FIG. 26 during reverse shifting. As described above, the three-phase first to third supply clock signals CK1 to CK3 sequentially rise to high level in descending order during reverse shifting. As illustrated in FIG. 29, when the second start pulse signal ST2 is at high level, the first supply clock signal CK1 is at high level. The first start pulse signal ST1 rises to high level after, for example, the output signal O1 from the first stage has risen to high level. Here, the descriptions will focus on the nth stage SRn instead of the first stage SR1. Time t1 to t2, time t2 to t3, and time t3 to t5 are the set period, the selection period, and the reset period, respectively, for the nth stage SRn.

In the set period (time t1 to t2), the second set signal IN2 (the second start pulse signal ST2, in the case of the nth stage SRn) rises to high level and the fifth transistor Tr5 turns on, and the second clock input signal CKb (the first supply clock signal CK1, in the case of the nth stage SRn) rises to high level and the second transistor Tr2 turns on. At this time, the first set signal IN1 (an output signal On−1 of the n−1th stage SRn−1, in the case of the nth stage SRn) is at low level, and thus the first and fourth transistors Tr1 and Tr4 are off. Accordingly, the first node NA is charged (precharged, here) in the same manner as in the set period during forward shifting.

In the selection period (time t2 to t3), the second set signal IN2 falls to low level and the fifth transistor Tr5 turns off, the second input clock signal CKb falls to low level and the second transistor Tr2 turns off, and the first input clock signal CKa (the third supply clock signal CK3, in the case of the nth stage SRn) rises to high level and the aforementioned bootstrapping operation is performed. For this reason, the high-level output signal O is outputted by the third transistor Tr3 at a low impedance.

In the former half of the reset period (time t3 to t4), the first input clock signal CKa falls to low level, and thus the output signal O falls to low level. Meanwhile, the third input clock signal CKc (the second supply clock signal CK2, in the case of the nth stage SRn) rises to high level and the first transistor Tr1 turns on. At this time, the first set signal IN1 is at high level, and thus the first node NA holds its precharge potential.

In the latter half of the reset period (time t4 to t5), the third input clock signal CKc falls to low level and the first transistor Tr1 turns off, and the second input clock signal CKb (the first supply clock signal CK1, in the case of the nth stage SRn) rises to high level and the second transistor Tr2 turns on. At this time, the second set signal IN2 is at low level, and thus the second transistor Tr2 changes the potential at the first node NA toward low level. In this manner, a reset is carried out using the second transistor Tr2 during reverse shifting.

As during forward shifting, after the reset period, the second and first transistors Tr2 and Tr1 respectively turn on in response to the second and third input clock signals CKb and CKc periodically (and more specifically, each time the second and third input clock signals CKb and CKc rise to high level). Accordingly, the potential at the first node NA can be pulled back to low level with certainty, using the second and first transistors Tr1 and Tr2.

As described above, the first to third input clock signals CKa to CKc are varied between the first stage SR1, fourth stage SR4, seventh stage SR7, and so on, the second stage SR2, fifth stage SR5, eighth stage SR8, and so on, and the third stage SR3, sixth stage SR6, ninth stage SR9, and so on, and thus the same operations as for the nth stage SRn are carried out for the n−1th stage SRn−1 and on, while being shifted by one horizontal period each. In this manner, the shift register 100 sequentially transfers the start pulse signal ST2 in the reverse direction based on the three-phase first to third supply clock signals CK1 to CK3. In other words, the shift register 100 can sequentially set the output signals O1 to On of the n-stage bistable circuits SR1 to SRn to high level in descending order based on the three-phase first to third supply clock signals CK1 to CK3.

As described above, the potential at the first node NA is controlled by the first control circuit 31a using the fourth transistor Tr4 that changes the potential at the first node NA toward high level when the first set signal IN1 is at high level and the first transistor Tr1 that changes the potential at the first node NA toward the potential of the first set signal IN1 when the third input clock signal CKc is at high level. Likewise, the potential at the first node NA is controlled by the second control circuit 31b using the fifth transistor Tr5 that changes the potential at the first node NA toward high level when the second set signal IN2 is at high level and the second transistor Tr2 that changes the potential at the first node NA toward the potential of the second set signal IN2 when the second input clock signal CKb is at high level. According to this configuration, potential changes in the three-phase first to third supply clock signals CK1 to CK3 that are inputted to the second, third, and seventh input terminals 12, 13, and 17 are varied between the case where the shift direction is the forward direction and the case where the shift direction is the reverse direction, and thus the shift direction can be switched between the forward direction and the reverse direction without using the aforementioned first and second switching signals UD and UDB.

Incidentally, in a case such as the present variation where the aforementioned first and second switching signals UD and UDB are not used, it is not necessary to use the ninth and tenth transistors Tr9 and Tr10 according to the aforementioned Modification Example 10 of Embodiment 1 (see FIG. 17). Accordingly, a drop in the potential of the first set signal IN1 equivalent to the threshold voltage Vth of the ninth transistor Tr9 and a drop in the potential of the second set signal IN2 equivalent to the threshold voltage Vth of the tenth transistor Tr10 do not occur. It is thus not necessary to use the eleventh to fourteenth transistors Tr11 to Tr14 as in the aforementioned Modification Example 11 of Embodiment 1 (see FIG. 20). Therefore, according to the present variation, drops in the potentials of the first and second set signals IN1 and IN2 can be prevented while suppressing the number of transistors.

### 1.21 Modification Example 17

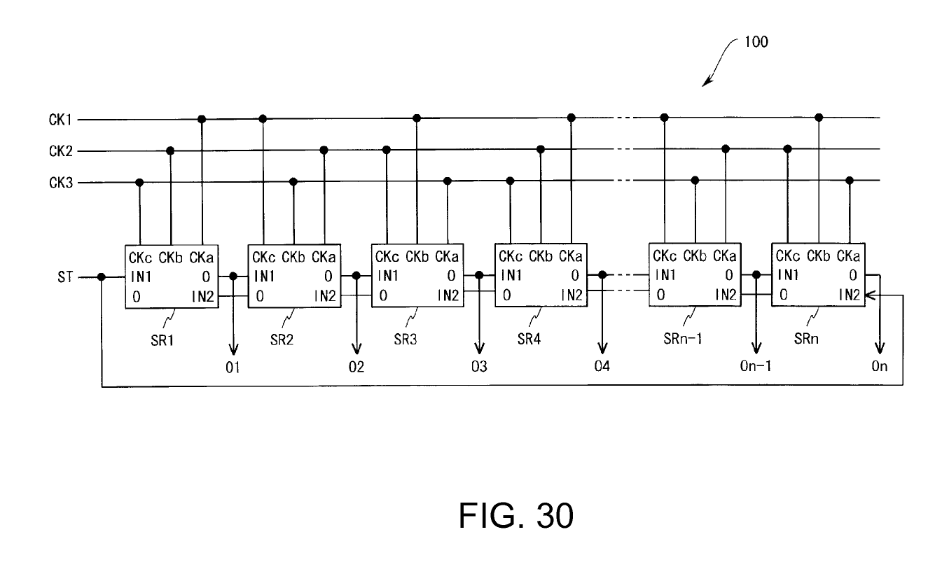

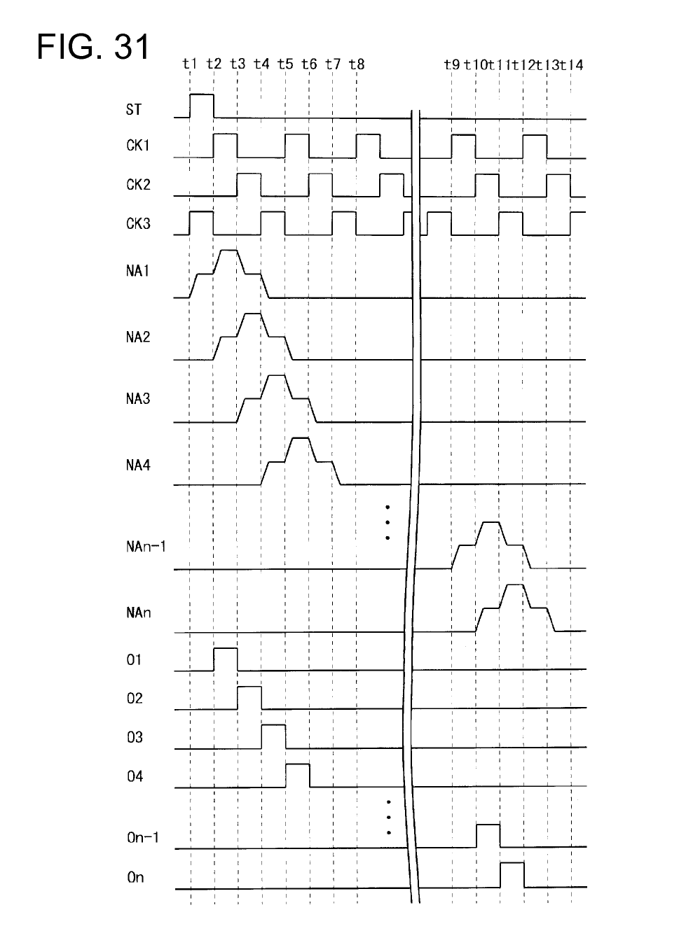

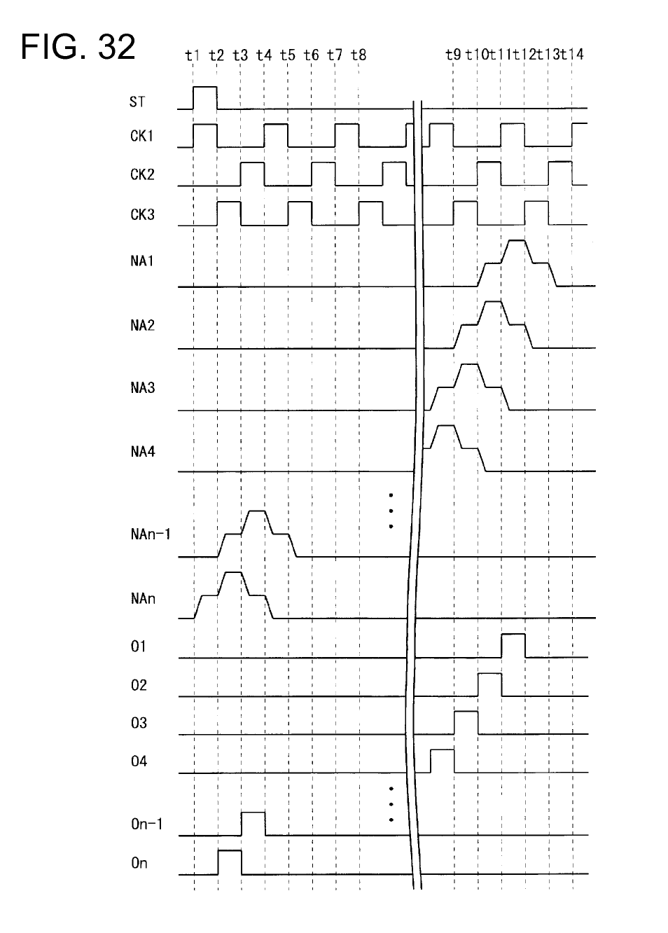

FIG. 30 is a block diagram illustrating a configuration of a shift register 100 according to Modification Example 17 of the aforementioned Embodiment 1. FIG. 31 is a timing chart illustrating operations of the shift register 100 illustrated in FIG. 30 during forward shifting. FIG. 32 is a timing chart illustrating operations of the shift register 100 illustrated in FIG. 30 during reverse shifting. As illustrated in FIG. 30 to FIG. 32, the present variation corresponds to the aforementioned Modification Example 16 of Embodiment 1, except that a single start pulse signal ST, as in the aforementioned Embodiment 1 or the variations thereon aside from Modification Example 16, is used instead of the first and second start pulse signals ST1 and ST2. Accordingly, the first stage SR1 takes the start pulse signal ST as the first set signal IN1, and the nth stage SRn takes the start pulse signal ST as the second set signal IN2.

Incidentally, in the configuration of the aforementioned Modification Example 16 of Embodiment 1, the following problem arises when the start pulse signal ST is used in common for the first stage SR1 and the nth stage SRn. That is, during forward shifting, when a set operation is carried out by the first and fourth transistors Tr1 and Tr4 in the first stage SR1, a set operation will also be carried out by the fifth transistor Tr5 in the nth stage SRn. There is thus a chance that a malfunction will occur in the nth stage SRn. Likewise, during reverse shifting, when a set operation is carried out by the second and fifth transistors Tr2 and Tr5 in the nth stage SRn, a set operation will also be carried out by the fourth transistor Tr4 in the first stage SR1. There is thus a chance that a malfunction will occur in the first stage SR1. Accordingly, in the present variation, the first stage and nth stage SR1 and SRn are given different configurations than the other stages. The configurations of the stages aside from the first stage and nth stage SR1 and SRn are the same as in the aforementioned Modification Example 16 of Embodiment 1.

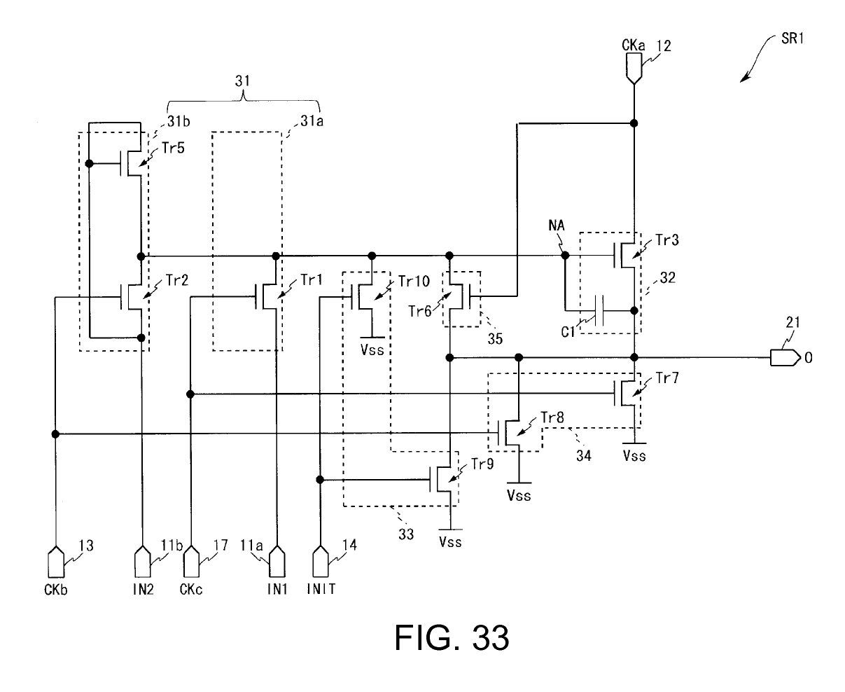

FIG. 33 is a circuit diagram illustrating the configuration of the first stage SR1 according to the present variation. As illustrated in FIG. 33, the first stage SR1 according to the present variation corresponds to the bistable circuit SR illustrated in FIG. 27, with the fourth transistor Tr4 being omitted from the first control circuit 31a. Accordingly, during reverse shifting, a set operation is not performed by the fourth transistor Tr4 in the first stage SR1 when a set operation is performed by the second and fifth transistors Tr2 and Tr5 in the nth stage SRn. As such, the first stage SR1 can be prevented from malfunctioning during reverse shifting.

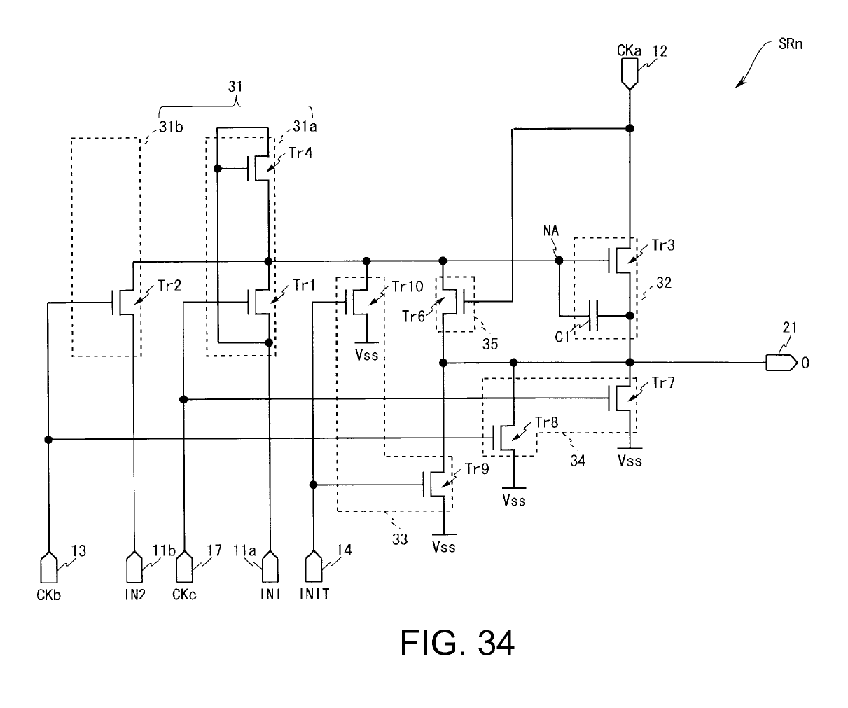

FIG. 34 is a circuit diagram illustrating the configuration of the nth stage SRn according to the present variation. As illustrated in FIG. 34, the nth stage SRn according to the present variation corresponds to the bistable circuit SR illustrated in FIG. 27, with the fifth transistor Tr5 being omitted from the second control circuit 31b. Accordingly, during forward shifting, a set operation is not performed by the fifth transistor Tr5 in the nth stage SRn when a set operation is performed by the first and fourth transistors Tr1 and Tr4 in the first stage SR1. As such, the nth stage SRn can be prevented from malfunctioning during forward shifting.

Note that in the case where dummy stages are provided before the first stage SR1, the first stage SR1 may have the same configuration as in the aforementioned Modification Example 16 of Embodiment 1, and the frontmost stage of the dummy stages provided before the first stage SR1 may have the configuration illustrated in FIG. 33. Likewise, in the case where dummy stages are provided after the nth stage SRn, the nth stage SRn may have the same configuration as in the aforementioned Modification Example 16 of Embodiment 1, and the rearmost stage of the dummy stages provided after the nth stage SRn may have the configuration illustrated in FIG. 34. In addition, the configuration illustrated in FIG. 33 or FIG. 34 may be applied to a stage partway through the shift register 100 (referring to a stage aside from the frontmost stage and the rearmost stage), or to all stages.

### 2. Embodiment 2

### 2.1 Overall Configuration

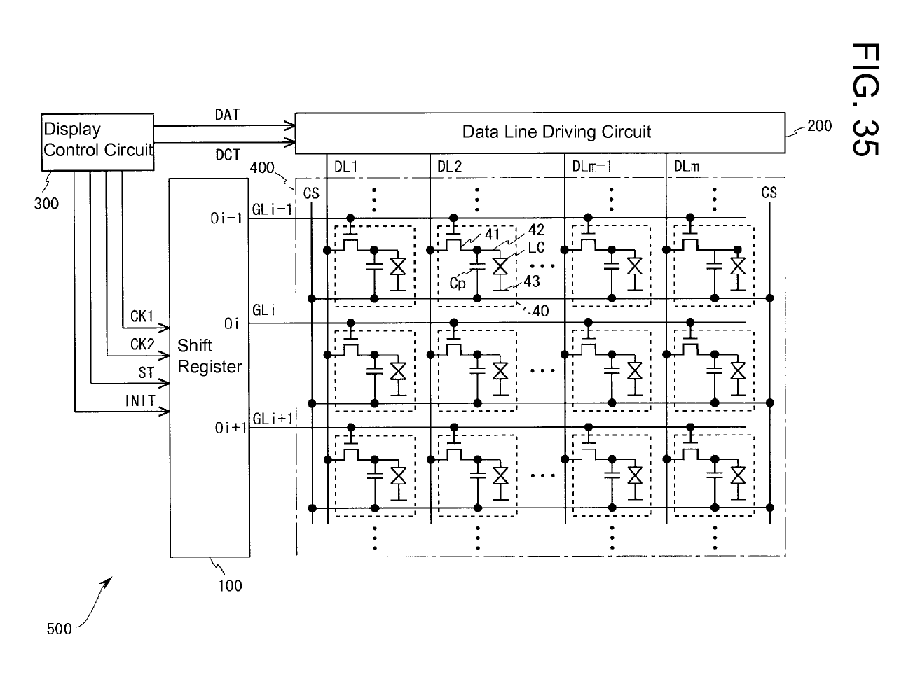

FIG. 35 is a block diagram illustrating a configuration of a display device 500 according to Embodiment 2 of the present invention. Constituent elements in the present embodiment that are the same as in the aforementioned Embodiment 1 will be given the same reference numerals, and descriptions thereof will be omitted for the sake of simplicity. The display device 500 is a liquid crystal display device, and includes a shift register 100, a data line driving circuit 200, a display control circuit 300, and a display unit 400. The shift register 100 has the same configuration as the shift register according to the aforementioned Embodiment 1 or the variations thereon. In the present embodiment, the shift register 100 functions as a scanning line driving circuit. One or both of the shift register 100 and the data line driving circuit 200 may be formed integrally with the display unit 400.

m data lines DL1 to DLm, n scanning lines GL1 to GLn, and m×n pixel forming units 40 provided so as to correspond with respective points of intersection between the m data lines DL1 to DLm and the n scanning lines GL1 to GLn, are provided in the display unit 400. Hereinafter, the m data lines DL1 to DLm will be referred to simply as “data lines DL” in the case where no distinction is to be made therebetween, and likewise, the n scanning lines GL1 to GLn will be referred to simply as “scanning lines GL” in the case where no distinction is to be made therebetween. The m×n pixel forming units 40 are formed in a matrix. The display unit 400 is also provided with an auxiliary capacitance line CS that is, for example, used in common for the m×n pixel forming units 40 or is used in common for each row of pixel forming units 40.

Each pixel forming unit 40 includes a thin-film transistor (abbreviated as “TFT” hereinafter) 41 whose gate terminal is connected to the scanning line GL that passes through the corresponding point of intersection and whose first conduction terminal is connected to the data line DL that passes through the stated point of intersection, a pixel electrode 42 connected to a second conduction terminal of the TFT 41, a common electrode 43 provided in common for the m×n pixel forming units 40, a liquid crystal capacitance LC formed by a liquid crystal layer interposed between the pixel electrode 42 and the common electrode 43, and an auxiliary capacitance Cp formed between the pixel electrode 42 and the auxiliary capacitance line CS. The auxiliary capacitance Cp is provided in order to hold a potential of the pixel electrode 42 with certainty, but is not absolutely necessary. When a TFT in which a channel layer is formed of InGaZnOx, which is an oxide semiconductor whose primary components are indium (In), gallium (Ga), zinc (Zn), and oxygen (O), is employed as the TFT 41, the pixel electrode 42 can be written to at high speed, and the potential of the pixel electrode 42 can be held with more certainty.

The display control circuit 300 supplies image data DAT and a data control signal DCT to the data line driving circuit 200, and supplies the first and second supply clock signals CK1 and CK2, the start pulse signal ST, and the initializing signal INIT to the shift register 100. Note that depending on the configuration of the shift register 100, there are cases where the display control circuit 300 does not supply the initializing signal INIT to the shift register 100, or cases where the display control circuit 300 further supplies the third and fourth supply clock signals CK3 and CK4, the first and second switching signals UD and UDB, or the like to the shift register 100.

The data line driving circuit 200 generates and outputs data signals to be supplied to the data lines DL in response to the image data DAT and the data control signal DCT. The data control signal DCT includes, for example, a data start pulse signal, a data clock signal, and a latch strobe signal. The data line driving circuit 200 operates a shift register, a sampling latch circuit, and so on (not shown) within the data line driving circuit 200 in response to the data start pulse signal, the data clock signal, and the latch strobe signal, and generates a data signal by converting a digital signal obtained based on the image data DAT into an analog signal using a digital/analog conversion circuit (not shown).

The n scanning lines GL1 to GLn are respectively connected to the output terminals 21 of the first stage SR1 to the nth stage SRn in the shift register 100. Note that the output terminals 21 and the scanning lines GL may be connected to each other via buffer amps. Meanwhile, in the case where dummy stages are provided as described above, scanning lines are not connected to the dummy stages or scanning lines that do not contribute to the display are connected to the dummy stages, for example. The shift register 100 supplies the output signals O1 to On that sequentially rise to on level (assumed here to be high level) to the n scanning lines GL1 to GLn, respectively, based on the first and second supply clock signals CK1 and CK2, the start pulse signal ST, and the initializing signal INIT.

Accordingly, the high-level output signal O is supplied to the scanning line GL and the TFT 41 turns on, the data signal supplied to the data line DL is written to the pixel electrode 42 via the TFT 41, and a screen based on the image data DAT is displayed in the display unit 400.

### 2.2 Effects

According to the present embodiment, a display device that drives the n scanning lines GL1 to GLn can be realized using the shift register 100 according to the aforementioned Embodiment 1 or the variations thereon. Note that the shift register 100 according to the aforementioned Embodiment 1 or the variations thereon may be employed as the shift register in the data line driving circuit 200.

### 2.3 Modification Example

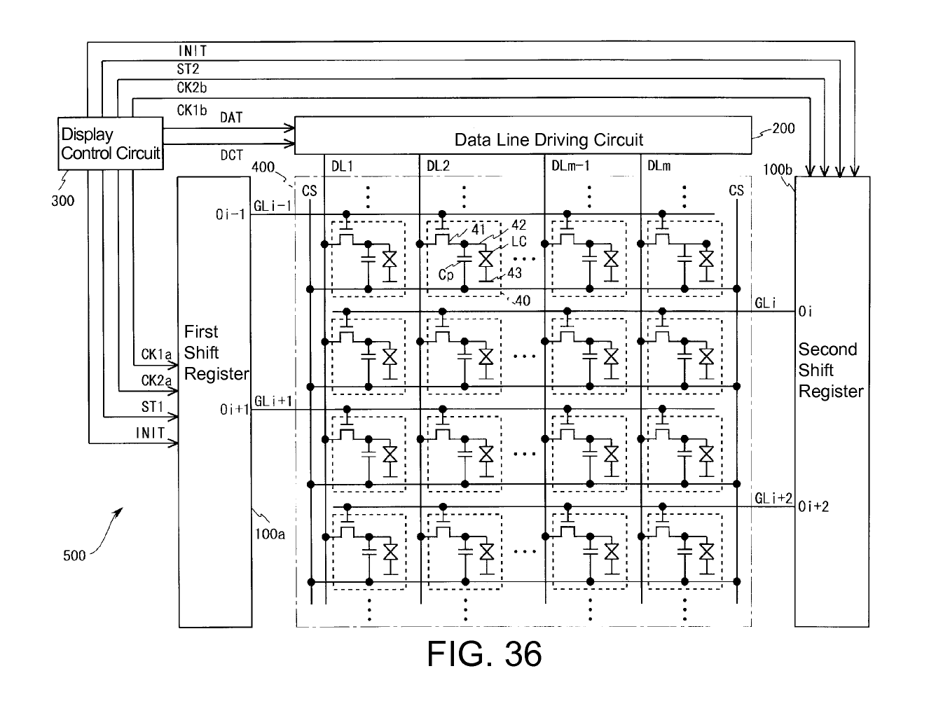

FIG. 36 is a block diagram illustrating a configuration of a display device 500 according to a variation of the aforementioned Embodiment 2. The display device 500 according to the present variation includes two of the shift registers 100 according to the aforementioned Embodiment 1 or the variations thereon. In the following, one of the two shift registers 100 will be called a “first shift register 100a”, and the other of the two shift registers 100 will be called a “second shift register 100b”. In the present variation, the number of stages in the bistable circuits SR provided in the first and second shift registers 100a and 100b, respectively, is n/2 stages.

The display control circuit 300 supplies a first first supply clock signal CK1a, a first second supply clock signal CK2a, the first start pulse signal ST1, and the initializing signal INIT to the first shift register 100a, and supplies a second first supply clock signal CK1b, a second second supply clock signal CK2b, the second start pulse signal ST2, and the initializing signal INIT to the second shift register 100b. With respect to the first shift register 100a, the first first supply clock signal CK1a and the first second supply clock signal CK2a correspond to the first and second supply clock signals CK1 and CK2, respectively, according to the aforementioned Embodiment 1 or the variations thereon, and the first start pulse signal ST1 corresponds to the start pulse signal ST according to the aforementioned Embodiment 1 or the variations thereon (the first and second start pulse signals ST1 and ST2, in the case of Modification Example 16). With respect to the second shift register 100b, the second first supply clock signal CK1b and the second second supply clock signal CK2b correspond to the first and second supply clock signals CK1 and CK2, respectively, according to the aforementioned Embodiment 1 or the variations thereon, and the second start pulse signal ST2 corresponds to the start pulse signal ST according to the aforementioned Embodiment 1 or the variations thereon (the first and second start pulse signals ST1 and ST2, in the case of Modification Example 16).

The first shift register 100a is provided at one end of the display unit 400 in an extension direction of the scanning lines GL (called simply “one end” hereinafter), and odd-numbered scanning lines GL from the side of the extension direction of the data lines DL on which the data line driving circuit 200 is located (called simply “odd-numbered” hereinafter) are respectively connected to the output terminals 21 of the first to n/2th stages SR1 to SRn/2. In the present variation, output signals of the first to n/2th stages SR1 to SRn/2 connected to the odd-numbered scanning lines GL are expressed as O1, O3, and so on up to On−1, respectively. Based on the first first supply clock signal CKla, the first second supply clock signal CK2a, the first start pulse signal ST1, and the initializing signal INIT, the first shift register 100a supplies the output signals O1, O3, and so on up to On−1, which sequentially rise to high level, to the odd-numbered scanning lines GL, respectively.

The second shift register 100b is provided at another end of the display unit 400 in an extension direction of the scanning lines GL (called simply “another end” hereinafter), and even-numbered scanning lines GL from the side of the extension direction of the data lines DL on which the data line driving circuit 200 is located (called simply “even-numbered” hereinafter) are respectively connected to the output terminals 21 of the first to n/2th stages SR1 to SRn/2. In the present variation, output signals of the first to n/2th stages SR1 to SRn/2 connected to the even-numbered scanning lines GL are expressed as O2, O4, and so on up to On, respectively. Based on the second first supply clock signal CK1b, the second second supply clock signal CK2b, the second start pulse signal ST2, and the initializing signal INIT, the second shift register 100b supplies the output signals O2, O4, and so on up to On, which sequentially rise to high level, to the even-numbered scanning lines GL, respectively.

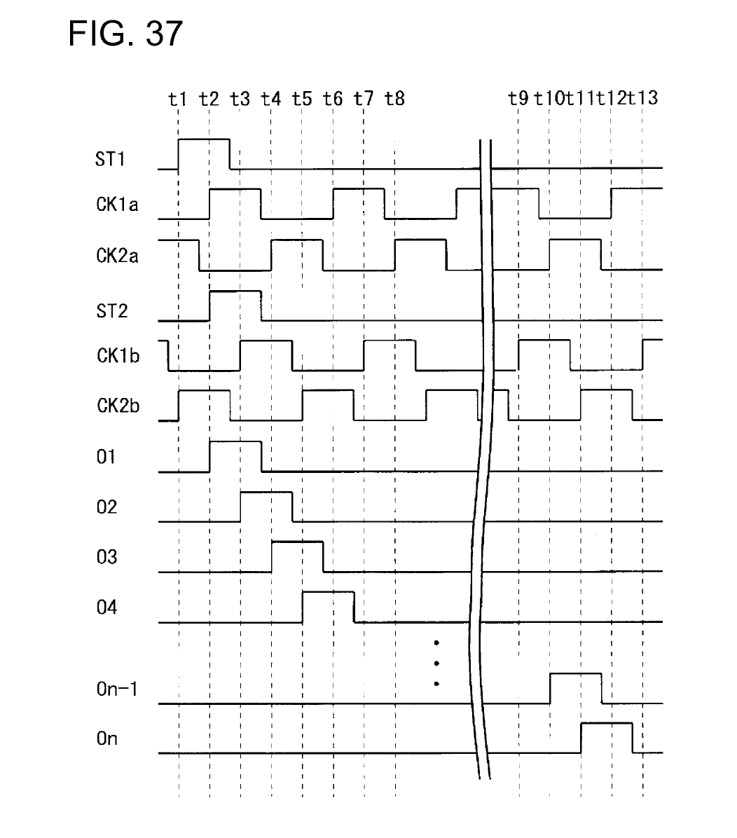

FIG. 37 is a timing chart (times t1 to t13) illustrating operations of the first and second shift registers 100a and 100b illustrated in FIG. 36. As illustrated in the chart, the phases of the first first supply clock signal CK1a and the first second supply clock signal CK2a are shifted from each other by two horizontal periods, and both signals rise to high level for a period longer than a single horizontal period and shorter than two horizontal periods every four horizontal periods. The second first supply clock signal CK1b and the second second supply clock signal CK2b are signals obtained by delaying the first first supply clock signal CK1a and the first second supply clock signal CK2a by a single horizontal period each. The first start pulse signal ST1 contains a pulse that rises to high level for a period that is longer than a single horizontal period but shorter than two horizontal periods. The second start pulse signal ST2 is a signal obtained by delaying the first start pulse signal ST1 by one horizontal period.

As illustrated in FIG. 37, based on the first first supply clock signal CK1a and the first second supply clock signal CK2a, the first shift register 100a sequentially sets the output signals O1, O3, and so on up to On−1 supplied to the odd-numbered scanning lines GL to high level by sequentially transferring the pulses contained in the first start pulse signal ST1. Based on the second first supply clock signal CKlb and the second second supply clock signal CK2b, the second shift register 100b sequentially sets the output signals O2, O4, and so on up to On supplied to the even-numbered scanning lines GL to high level by sequentially transferring the pulses contained in the second start pulse signal ST2. As described above, the second start pulse signal ST2, the second first supply clock signal CK1b, and the second second supply clock signal CK2b are signals obtained by delaying the first start pulse signal ST1, the first first supply clock signal CK1a, and the first second supply clock signal CK2a, respectively, by one horizontal period, and thus in the first and second shift registers 100a and 100b overall, the output signals O1 to On sequentially rise to high level while overlapping by a period shorter than a single horizontal period (but not 0).

According to the present variation, in the display device 500 that uses two of the shift registers 100 according to the aforementioned Embodiment 1 or the variations thereon, the first and second shift registers 100a and 100b are provided on one end and another end of the display unit 400 and connect the scanning lines GL in an alternating manner, and thus the circuit scale of the shift register 100 can be reduced on each side of the display unit 400. Although the duty cycles of the respective supply clock signals are described as being less than ½ (but not 0) in the present variation, the duty cycles may be ½. In addition, at this time, the respective pulses contained in the first and second start pulse signals ST1 and St2 may be pulses that rise to high level for two horizontal periods.

### 3. Other

The present invention is not intended to be limited to the aforementioned embodiments, and many variations can be carried out thereon without departing from the essential spirit of the present invention. For example, the aforementioned Embodiment 1 and the variations thereon can be combined in a variety of ways aside from the aforementioned examples.

Furthermore, although the display device 500 is described as being a liquid crystal display device in the aforementioned Embodiment 2, the present invention is not intended to be limited thereto. The present invention can be applied in various types of display devices, such as organic electroluminescence display devices, in addition to liquid crystal display devices.

### 4. Supplementary Notes

### Supplementary Note 1

A shift register, including a plurality of bistable circuits cascade-connected to each other and constituted by transistors having the same conductivity type, that sequentially changes levels of output signals from the plurality of bistable circuits based on clock signals having a plurality of phases that are inputted from an exterior and cyclically repeat an on level and an off level,

the bistable circuit including:
an output terminal for outputting the output signal;
a first clock input terminal for taking one of the clock signals having a plurality of phases as a first clock signal;

a second clock input terminal for taking one of the clock signals having a plurality of phases aside from the first clock signal as a second clock signal;

a set input terminal for taking an output signal from a previous-stage bistable circuit as a set signal;

an output transistor in which a first conduction terminal is connected to the first clock input terminal and a second conduction terminal is connected to the output terminal;

a first control transistor in which a control terminal is connected to the set input terminal, an on level potential is applied at a first conduction terminal when the set signal is at an on level, and a second conduction terminal is connected to a control terminal of the output transistor; and

a second control transistor in which a control terminal is connected to the second clock input terminal, a first conduction terminal is connected to the set input terminal, and a second conduction terminal is connected to the control terminal of the output transistor.

According to the shift register of supplementary note 1, the second control transistor changes a potential at the control terminal of the output transistor toward the potential of the set signal when the second clock signal is at on level. Accordingly, even if the first and second control transistors are on at the same time, potentials at a the first conduction terminal of the first control transistor and the first conduction terminal of the second control transistor are both at on level at this time. As a result, no feedthrough current arises in the first and second control transistors. Accordingly, it is possible to realize driving using various clock signals, with low power consumption. In addition, the second control transistor periodically changes the potential at the control terminal of the output transistor toward the potential of the set signal in response to the second clock signal, and thus malfunctions caused by fluctuations in the potential at the control terminal of the output transistor can be prevented.

### Supplementary Note 2

The shift register according to supplementary note 1,

wherein the bistable circuit further includes:

an initializing input terminal for receiving an initializing signal that rises to the on level at

a required timing; and

a control potential initializing transistor in which a control terminal is connected to the initializing input terminal, a first conduction terminal is connected to the control terminal of the output transistor, and an off level potential is applied at a second conduction terminal.

According to the shift register of supplementary note 2, the potential at the control terminal of the output transistor can be initialized to the off level when the initializing signal is at the on level.

### Supplementary Note 3

The shift register according to supplementary note 1,

wherein the bistable circuit further includes:

an initializing input terminal for receiving an initializing signal that rises to the on level at a required timing; and

an output potential initializing transistor in which a control terminal is connected to the initializing input terminal, a first conduction terminal is connected to the output terminal, and an off level potential is applied at a second conduction terminal.

According to the shift register of supplementary note 3, the potential at the output terminal can be initialized to the off level when the initializing signal is at the on level.

### Supplementary Note 4

The shift register according to supplementary note 1, wherein the bistable circuit further includes an output potential holding transistor in which a control terminal is connected to the second clock input terminal, a first conduction terminal is connected to the output terminal, and an off level potential is applied at a second conduction terminal.

According to the shift register of supplementary note 4, the potential at the output terminal periodically changes toward the off level in response to the second clock signal, and thus the potential at the output terminal is stabilized. Accordingly, a drop in an operating margin, malfunctions, and so on can be prevented.

### Supplementary Note 5

The shift register according to supplementary note 1, wherein the bistable circuit further includes a connecting transistor in which a control terminal is connected to the first clock input terminal, a first conduction terminal is connected to the control terminal of the output transistor, and a second conduction terminal is connected to the output terminal.

According to the shift register of supplementary note 5, the control terminal of the output transistor and the output terminal are electrically connected to each other by the connecting transistor when the first clock signal is at the on level. Generally, a large capacity load is connected to the output terminal, and thus electrically connecting the control terminal of the output transistor to the output terminal reduces the influence of fluctuations in the potential of the first clock signal that are transmitted to the control terminal of the output transistor due to parasitic capacitance present between the conduction terminal of the output transistor on the first clock input terminal side and the control terminal. Accordingly, malfunctions caused by fluctuations in the potential at the control terminal of the output transistor can be prevented.

### Supplementary Note 6

The shift register according to supplementary note 1, wherein the bistable circuit further includes a breakdown voltage transistor in which an on level potential is applied at a control terminal, a first conduction terminal is connected to the control terminal of the output transistor, and a second conduction terminal is connected to the respective second conduction terminals of the first control transistor and the second control transistor.

According to the shift register of supplementary note 6, the breakdown voltage transistor turns off when potentials at the respective second conduction terminals of the first and second control transistors and the potential at the control terminal of the output transistor reach a value obtained by subtracting a threshold voltage of the breakdown voltage transistor from the on level. Accordingly, the respective second conduction terminals of the first and second control transistors are electrically disconnected from the control terminal of the output transistor by the breakdown voltage transistor. Through this, when the first clock signal changes from the off level to the on level, the potentials at the respective second conduction terminals of the first and second control transistors will not rise even if the potential at the control terminal of the output transistor rises (the bootstrapping operation) due to the presence of the capacitance present in the output transistor. As a result, a voltage applied between the terminals of the first control transistor and between the terminals of the second control transistor when the respective potentials at the control terminal and the first conduction terminal of the first control transistor and the respective potentials at the control terminal and the first conduction terminal of the second control transistor are at the off level is reduced. Accordingly, the reliability of the first and second control transistors can be improved.

### Supplementary Note 7

The shift register according to supplementary note 1,

wherein the set input terminal has:

a first set input terminal for taking the output signal from a previous-stage bistable circuit in the case where the levels of the output signals from the plurality of bistable circuits are sequentially changed in a first direction as the set signal; and

a second set input terminal for taking the output signal from a previous-stage bistable circuit in the case where the levels of the output signals from the plurality of bistable circuits are sequentially changed in a second direction as the set signal; and

the bistable circuit further includes:

a first switching input terminal for receiving a first switching signal that rises to the on level in the case where the levels of the output signals from the plurality of bistable circuits are sequentially changed in the first direction and falls to the off level in the case where the levels of the output signals from the plurality of bistable circuits are sequentially changed in the second direction;

a second switching input terminal for receiving a second switching signal whose potential is inverted relative to the first switching signal;

a first switching transistor in which a control terminal is connected to the first switching input terminal, a first conduction terminal is connected to the first set input terminal, and a second conduction terminal is connected to the control terminal of the first control transistor and the first conduction terminal of the second control transistor; and

a second switching transistor in which a control terminal is connected to the second switching input terminal, a first conduction terminal is connected to the second set input terminal, and a second conduction terminal is connected to the control terminal of the first control transistor and the first conduction terminal of the second control transistor.

According to the shift register of supplementary note 7, the output signal of the previous-stage bistable circuit in the case where the levels of the output signals from the plurality of bistable circuits are sequentially changed in the first direction is supplied to the first and second control transistors as the set signal when the first switching signal is at the on level, and the output signal of the previous-stage bistable circuit in the case where the levels of the output signals from the plurality of bistable circuits are sequentially changed in the second direction is supplied to the first and second control transistors as the set signal when the second switching signal is at the on level. Accordingly, the shift direction can be switched between the first direction and the second direction.

### Supplementary Note 8

The shift register according to supplementary note 7,

wherein the bistable circuit further includes:

a first switching control circuit that electrically connects the first switching input terminal and the control terminal of the first switching transistor to each other via a first rectifier circuit when the first switching signal is at the on level; and

a second switching control circuit that electrically connects the second switching input terminal and the control terminal of the second switching transistor to each other via a second rectifier circuit when the second switching signal is at the on level.

According to the shift register of supplementary note 8, the control terminal of the first switching transistor is in a floating state when the first switching signal is at the on level. At this time, when the set signal changes from the off level to the on level, a potential at the control terminal of the first switching transistor is pushed up due to the presence of a gate capacitance in the first switching transistor. In other words, a bootstrapping operation is performed at the control terminal of the first switching transistor. Accordingly, a drop in the potential of the set signal equivalent to a threshold voltage of the first switching transistor can be prevented, and the set signal can be supplied to the first and second control transistors. Likewise, the control terminal of the second switching transistor is in a floating state when the second switching signal is at the on level. At this time, when the set signal changes from the off level to the on level, a potential at the control terminal of the second switching transistor is pushed up due to the presence of a gate capacitance in the second switching transistor. In other words, a bootstrapping operation is performed at the control terminal of the second switching transistor. Accordingly, a drop in the potential of the set signal equivalent to a threshold voltage of the second switching transistor can be prevented, and the set signal can be supplied to the first and second control transistors.

### Supplementary Note 9

The shift register according to supplementary note 8,

wherein the first rectifier circuit has a first switch-on control transistor in which the on level potential is applied at a control terminal when the first switching signal is at the on level, a first conduction terminal is connected to the first switching input terminal, and a second conduction terminal is connected to the control terminal of the first switching transistor; and

the second rectifier circuit has a second switch-on control transistor in which the on level potential is applied at a control terminal when the second switching signal is at the on level, a first conduction terminal is connected to the second switching input terminal, and a second conduction terminal is connected to the control terminal of the second switching transistor.

According to the shift register of supplementary note 9, the same effects as in the shift register according to supplementary note 8 can be achieved by using the first switch-on control transistor and the second switch-on control transistor.

### Supplementary Note 10

The shift register according to supplementary note 9,

wherein the control terminal of the first switch-on control transistor is connected to the first switching input terminal; and

the control terminal of the second switch-on control transistor is connected to the second switching input terminal.

According to the shift register of supplementary note 10, the same effects as in the shift register according to supplementary note 8 can be achieved by using the first switch-on control transistor that is diode-connected and the second switch-on control transistor that is diode-connected.

### Supplementary Note 11

The shift register according to supplementary note 9,

wherein the control terminal of the first switch-on control transistor is connected to a power line that supplies on level power; and

the control terminal of the second switch-on control transistor is connected to the power line that supplies on level power.

According to the shift register of supplementary note 11, as opposed to the case where a diode-connected first switch-on control transistor and a diode-connected second switch-on control transistor are used, the potential at the control terminal of the first switching transistor can be set to the off level and the potential at the control terminal of the second switching transistor can be set to the off level without using an element for setting the potential at the control terminal of the first switching transistor to the off level and an element for setting the potential at the control terminal of the second switching transistor to the off level.

### Supplementary Note 12

The shift register according to supplementary note 8,

wherein the first switching control circuit further has a first switch-off control transistor in which a control terminal is connected to the second switching input terminal, a first conduction terminal is connected to the control terminal of the first switching transistor, and an off level potential is applied at a second conduction terminal when the second switching signal is at the on level; and

the second switching control circuit further has a second switch-off control transistor in which a control terminal is connected to the first switching input terminal, a first conduction terminal is connected to the control terminal of the second switching transistor, and an off level potential is applied at a second conduction terminal when the first switching signal is at the on level.

According to the shift register of supplementary note 12, the potential at the control terminal of the first switching transistor can be set to the off level by the first switch-off control transistor and the potential at the control terminal of the second switching transistor can be set to the off level by the second switch-off control transistor.

### Supplementary Note 13

The shift register according to supplementary note 12,

wherein the first switching control circuit further has a first switching breakdown voltage transistor in which an on level potential is applied at a control terminal, a first conduction terminal is connected to the control terminal of the first switching transistor, and a second conduction terminal is connected to the first conduction terminal of the first switch-off control transistor; and

the second switching control circuit further has a second switching breakdown voltage transistor in which an on level potential is applied at a control terminal, a first conduction terminal is connected to the control terminal of the second switching transistor, and a second conduction terminal is connected to the first conduction terminal of the second switch-off control transistor.

According to the shift register of supplementary note 13, the first switching breakdown voltage transistor turns off when a potential at the first conduction terminal of the first switching breakdown voltage transistor reaches a value obtained by subtracting a threshold voltage of the first switching breakdown voltage transistor from the on level. Accordingly, the control terminal of the first switching transistor is electrically disconnected from the first conduction terminal of the first switch-off control transistor by the first switching breakdown voltage transistor. Accordingly, the potential at the first conduction terminal of the first switch-off control transistor does not rise even if a bootstrapping operation is performed at the control terminal of the first switching transistor, and thus a voltage applied between terminals in the first switch-off control transistor is reduced. As a result, the reliability of the first switch-off control transistor can be improved. Likewise, the second switching breakdown voltage transistor turns off when a potential at the first conduction terminal of the second switching breakdown voltage transistor reaches a value obtained by subtracting a threshold voltage of the second switching breakdown voltage transistor from the on level. Accordingly, the control terminal of the second switching transistor is electrically disconnected from the first conduction terminal of the second switch-off control transistor by the second switching breakdown voltage transistor. Accordingly, the potential at the first conduction terminal of the second switch-off control transistor does not rise even if a bootstrapping operation is performed at the control terminal of the second switching transistor, and thus a voltage applied between terminals in the second switch-off control transistor is reduced. As a result, the reliability of the second switch-off control transistor can be improved.

### Supplementary Note 14

The shift register according to supplementary note 1,

wherein the set signal has a first set signal and a second set signal; and

the second clock signal has a first second clock signal and a second second clock signal that are mutually different clock signals,

the set input terminal has:

a first set input terminal for taking the output signal from a previous-stage bistable circuit in the case where the levels of the output signals from the plurality of bistable circuits are sequentially changed in a first direction as the first set signal; and

a second set input terminal for taking the output signal from a previous-stage bistable circuit in the case where the levels of the output signals from the plurality of bistable circuits are sequentially changed in a second direction as the second set signal,

the second clock input terminal has:

a first second clock input terminal for receiving the first second clock signal; and

a second second clock input terminal for receiving the second second clock signal,

the first control transistor has at least one of:

a first first control transistor in which a control terminal is connected to the first set input terminal, an on level potential is applied at a first conduction terminal when the first set signal is at the on level, and a second conduction terminal is connected to the control terminal of the output transistor; and

a second first control transistor in which a control terminal is connected to the second set input terminal, an on level potential is applied at the first conduction terminal when the second set signal is at the on level, and a second conduction terminal is connected to the control terminal of the output transistor, and

the second control transistor has:

a first second control transistor in which a control terminal is connected to the first second clock input terminal, a first conduction terminal is connected to the first set input terminal, and a second conduction terminal is connected to the control terminal of the output transistor; and

a second second control transistor in which a control terminal is connected to the second second clock input terminal, a first conduction terminal is connected to the second set input terminal, and a second conduction terminal is connected to the control terminal of the output transistor.

According to the shift register of supplementary note 14, the potential at the control terminal of the output transistor is controlled by at least one of the first first control transistor that changes the potential at the control terminal of the output transistor toward the on level when the first set signal is at the on level and the first second control transistor that changes the potential at the control terminal of the output transistor toward the potential of the set signal when the first second clock signal is at the on level. Likewise, the potential at the control terminal of the output transistor is controlled by the second first control transistor that changes the potential at the control terminal of the output transistor toward the on level when the second set signal is at the on level and the second second control transistor that changes the potential at the control terminal of the output transistor toward the potential of the set signal when the second second clock signal is at the on level. In such a configuration, by varying fluctuations in the potential of the clock signals inputted into the clock input terminals between when the shift direction is the first direction and when the shift direction is the second direction, the shift direction can be switched between the first direction and the second direction without using a switching signal for switching the shift direction (the first and second switching signals in the shift register according to supplementary note 7, for example).

### INDUSTRIAL APPLICABILITY

The present invention can be applied in a shift register including a plurality of bistable circuits, a display device including the shift register, and a driving method for the shift register.

### DESCRIPTION OF REFERENCE CHARACTERS

11-17 first-seventh input terminals
21 output terminal
31 control circuit
32 output circuit
33 initializing circuit
34 output potential holding circuit
35 connection circuit
36 breakdown voltage circuit
37 switching circuit
38a, 38b first and second switching control circuits
100 shift register
200 data line driving circuit
300 display control circuit
400 display unit
C1 capacitor
CK1-CK4 first-fourth supply clock signals
CKa CKc first-third input clock signals
IN set signal
INIT initializing signal
NA first node NA
output signal
SR bistable circuit
ST start pulse signal
Tr1-Tr16 first-sixteenth transistors
UD, UDB first and second switching signals

1. A shift register, comprising a plurality of bistable circuits cascade-connected to each other and constituted by transistors having the same conductivity type, the shift register sequentially changing levels of output signals from said plurality of bistable circuits in accordance with clock signals received from outside, said clock signals cyclically repeating an ON level and an OFF level and having a plurality of mutually differing phases,
wherein each of said bistable circuits comprises:
first and second clock terminals for respectively receiving said clock signals;
an output terminal for outputting said output signal;
an output circuit, connected to said output terminal, that generates said output signal in accordance with a clock signal received at the first clock terminal; and
a control circuit that generates a control potential for controlling said output circuit in accordance with a set signal that is an output signal from a previous-stage bistable circuit or in accordance with a clock signal received at the second clock terminal, the clock signal received at the first clock terminal and the clock signal received at the second clock terminal having mutually different phases,
wherein said control circuit comprises:
a first control transistor that changes said control potential toward an ON level when said set signal is at an ON level; and
a second control transistor that changes said control potential toward a potential of said set signal when said clock signal received at the second clock terminal is at an ON level.

2. The shift register according to claim 1, wherein said clock signal received at the second clock terminal rises to an ON level when said set signal is at an ON level.

3. The shift register according to claim 1,
wherein said output circuit has an output transistor in which said input signal terminal is connected to a first conduction terminal and a second conduction terminal is connected to said output terminal, and
wherein said control potential is a potential at a control terminal of said output transistor.

4. The shift register according to claim 3, wherein said output circuit further comprises a capacitance element provided between said control terminal of said output transistor and said output terminal.

5. The shift register according to claim 3, wherein each of said bistable circuits further comprises a connection circuit that electrically connects said control terminal of said output transistor and said output terminal to each other when said clock signal received at the first clock terminal is at an ON level.

6. The shift register according to claim 1, wherein each of said bistable circuits further comprises an initializing circuit for initializing a potential related to said output signal in accordance with an initializing signal that rises to an ON level at a prescribed timing.

7. The shift register according to claim 1, wherein each of said bistable circuits further comprises an output potential holding circuit that changes a potential at said output terminal toward an OFF level when said clock signal received at the second clock terminal is at an ON level.

8. The shift register according to claim 1, wherein each of said bistable circuits further comprises a breakdown voltage circuit, provided between said output circuit and said control circuit, that electrically disconnects said output circuit from said control circuit when said control potential reaches a prescribed value.

9. The shift register according to claim 1,
wherein each of said bistable circuits further comprises:
a first switching transistor that, when a first switching signal that rises to an ON level in a case that the levels of the output signals from said plurality of bistable circuits are sequentially driven in a first direction and that falls to an OFF level in a case that the levels of the output signals from said plurality of bistable circuits are sequentially driven in a second direction is at an ON level, supplies the output signal from the previous-stage bistable circuit to said first control transistor and said second control transistor as said set signal; and
a second switching transistor that, when a second switching signal having a potential inverted relative to said first switching signal is at an ON level, supplies the output signal from the previous-stage bistable circuit to said first control transistor and said second control transistor as said set signal.

10. The shift register according to claim 9,
wherein each of said bistable circuits further comprises:
a first switching control circuit that supplies an ON level potential to a control terminal of said first switching transistor via a first rectifier circuit when said first switching signal is at an ON level; and
a second switching control circuit that supplies an ON level potential to a control terminal of said second switching transistor via a second rectifier circuit when said second switching signal is at an ON level.

11. The shift register according to claim 1,
wherein said set signal is a first set signal that is the output signal from the previous-stage bistable circuit in a case that the levels of the output signals from said plurality of bistable circuits are sequentially driven in a first direction, and the control circuit is configured to receive a second set signal that is the output signal from a previous-stage bistable circuit in a case that the levels of the output signals from said plurality of bistable circuits are sequentially driven in a second direction that is opposite to the second direction,
wherein each of said bistable circuits further comprises a third clock terminal,
wherein the control circuit further comprises a third control transistor that changes said control potential toward an ON level when said second set signal is at an ON level,
wherein the control circuit further comprises a fourth control transistor that changes said control potential toward a potential of said second set signal when a clock signal received at the third clock terminal is at an ON level, and
wherein the clock signal received at the first clock terminal, the clock signal received at the second clock terminal, and the clock signal received at the third clock terminal have mutually different phases.

12. The shift register according to claim 1, wherein said clock signals include clock signals having four phases that are different from one another.

13. The shift register according to claim 1, wherein a duty ratio of each of said clock signals is less than an inverse of a number of clock signals received by each bistable circuit.

14. A display device, comprising:
a display unit including a plurality of data lines, a plurality of scanning lines, and a plurality of pixel forming units provided so as to correspond with said plurality of data lines and said plurality of scanning lines;
a data line driving circuit that drives said plurality of data lines; and
the shift register according to claim 1, said output terminals of said plurality of bistable circuits being respectively connected to said plurality of scanning lines.

15. A display device having a display unit including a plurality of data lines, a plurality of scanning lines, and a plurality of pixel forming units provided so as to correspond with said plurality of data lines and said plurality of scanning lines, and a data line driving circuit that drives said plurality of data lines, the display device comprising:
two of the shift registers according to claim 1,
wherein one of said two shift registers is provided at one end of said display unit, said output terminals of said plurality of bistable circuits in said shift register being respectively connected to odd-numbered scanning lines of said plurality of scanning lines, and
wherein another of said two shift registers is provided at another end of said display unit, said output terminals of said plurality of bistable circuits in said shift register being respectively connected to even-numbered scanning lines of said plurality of scanning lines.

16. A method of driving a shift register that has a plurality of bistable circuits cascade-connected to each other and constituted by transistors having the same conductivity type, the shift register sequentially changing levels of output signals from said plurality of bistable circuits in accordance with clock signals received from outside, said clock signals cyclically repeating an ON level and an OFF level and having a plurality of mutually differing phases, each of the bistable circuits including a first clock terminal; a second clock terminal; and an output circuit, the method comprising at each of the bistable circuits:
generating and outputting said output signal in accordance with a clock signal received at the first clock terminal thereof, said clock signal being one of said clock signals; and
generating a control potential for controlling said output circuit in accordance with a set signal that is an output signal from a previous-stage bistable circuit or a clock signal received at the second clock terminal, the clock signal received at the first clock terminal and the clock signal received at the second clock terminal having mutually different phases,
wherein the step of changing said control potential includes:
changing said control potential toward an ON level when said set signal is at an ON level; and
changing said control potential toward a potential of said set signal when said clock signal received at the second clock terminal is at an ON level.
